(19) United States
(12) Patent Application Publication
(10) Pub. No.: US 2025/0081600 A1
(43) Pub. Date: Mar. 6, 2025

(54) IC Chip Comprising Backside Power Delivery Network and 3D Stacked N-type and P-type MOSFETs

(71) Applicant: iCometrue Company Ltd., Zhubei City (TW)

(72) Inventors: Jin-Yuan Lee, Miaoli County (TW); Mou-Shiung Lin, Hsinchu City (TW)

(21) Appl. No.: 18/823,678

(22) Filed: Sep. 4, 2024

Related U.S. Application Data
(60) Provisional application No. 63/536,689, filed on Sep. 5, 2023.

(51) Int. Cl. H01L 27/088; H01L 23/00; H01L 23/528; H01L 23/532; H01L 29/06; H01L 29/423; H01L 29/49; H01L 29/775; H01L 29/786

(52) U.S. Cl. CPC H10D 84/83; H01L 23/528; H01L 23/53238; H01L 24/05; H01L 24/13; H01L 23/5329; H01L 2224/0401; H01L 2224/05624; H01L 2224/13082; H01L 2224/13111; H01L 2224/13147; H10D 30/43; H10D 30/6735; H10D 30/6757; H10D 62/121; H10D 64/667

(57) ABSTRACT

A semiconductor integrated-circuit (IC) chip includes: a first transistor, a second transistor at a same horizontal level as the first transistor, a first oxide layer at the same horizontal level as the first and second transistors, horizontally around the first and second transistors and having a portion horizontally between the first and second transistors; a frontside interconnection scheme under the first and second transistors and first oxide layer, a backside interconnection scheme over the first and second transistor and first oxide layer, and a metal interconnect vertically in the portion of the first oxide layer and coupling the frontside interconnection scheme to the backside interconnection scheme.

### PRIORITY CLAIM

This application claims priority benefits from U.S. provisional application No. 63/536,689, filed on Sep. 5, 2023 and entitled “IC CHIP COMPRISING BACKSIDE POWER DELIVERY NETWORK AND 3D STACKED N-TYPE AND P-TYPE MOSFETS”. The present application incorporates the foregoing disclosures herein by reference.

### FIELD OF THE DISCLOSURE

The present invention relates to an integrated-circuit (IC) chip, and more particularly to an integrated-circuit (IC) chip embedded with a backside interconnection scheme for a power delivery network and with 3D stacked N-type and P-type metal-oxide-semiconductor field-effect transistors (MOSFETs).

### BRIEF DESCRIPTION OF THE RELATED ART

A semiconductor integrated circuit (IC) has been used for development of new or innovated applications, or for small volume applications or business demands. When an application or business demand expands to a certain volume and extends to a certain time period, the semiconductor IC supplier may usually implement the application in an Application Specific IC (ASIC) chip, or a Customer-Owned Tooling (COT) IC chip. A new approach or technology is needed to inspire the continuing innovation for implementing the innovation in the semiconductor IC chip using the advanced and powerful semiconductor technology.

### SUMMARY OF THE DISCLOSURE

A semiconductor integrated-circuit (IC) chip includes: a first transistor; a second transistor at a same horizontal level as the first transistor; a first oxide layer at the same horizontal level as the first and second transistors, horizontally around the first and second transistors and having a portion horizontally between the first and second transistors; a frontside interconnection scheme under the first and second transistors and first oxide layer; a backside interconnection scheme over the first and second transistor and first oxide layer; and a metal interconnect vertically in the portion of the first oxide layer and coupling the frontside interconnection scheme to the backside interconnection scheme.

These, as well as other components, steps, features, benefits, and advantages of the present application, will now become clear from a review of the following detailed description of illustrative embodiments, the accompanying drawings, and the claims.

### BRIEF DESCRIPTION OF THE DRAWINGS

The drawings disclose illustrative embodiments of the present application. They do not set forth all embodiments. Other embodiments may be used in addition or instead. Details that may be apparent or unnecessary may be omitted to save space or for more effective illustration. Conversely, some embodiments may be practiced without all of the details that are disclosed. When the same reference number or reference indicator appears in different drawings, it may refer to the same or like components or steps.

Aspects of the disclosure may be more fully understood from the following description when read together with the accompanying drawings, which are to be regarded as illustrative in nature, and not as limiting. The drawings are not necessarily to scale, emphasis instead being placed on the principles of the disclosure. In the drawings:

FIGS. 1A-1F and 1H-1L are schematically cross-sectional views showing a process for fabricating a backside interconnection scheme of a semiconductor integrated-circuit chip in accordance with an embodiment of the present application.

FIGS. 1G-1 through 1G-8 shows various scenarios of coupling of a transistor to frontside and backside contacts in accordance with an embodiment of the present application.

FIGS. 2A, 2B-2 through 2J-2 and 2B-3 through 2J-3 are schematically cross-sectional views showing a process for fabricating a first type of gate-all-around (GAA) transistor in accordance with an embodiment of the present application.

FIGS. 2B-1 through 2J-1 are schematically top views showing a process for fabricating a first type of gate-all-around (GAA) transistor in accordance with an embodiment of the present application.

FIGS. 3A, 3B-2 through 3T-2, 3B-3 through 3T-3, 3B-3 through 3T-3, 3Q-4 through 3T-4 and 3Q-5 through 3T-5 are schematically cross-sectional views showing a process for fabricating a second type of gate-all-around (GAA) transistor in accordance with an embodiment of the present application.

FIGS. 3B-1 through 3T-1 are schematically top views showing a process for fabricating a second type of gate-all-around (GAA) transistor in accordance with an embodiment of the present application.

FIGS. 4A-4C is a schematically cross-sectional view showing a structure of a second type of transistors incorporated in a semiconductor integrated-circuit chip in accordance with an embodiment of the present application.

FIGS. 4D and 4E are schematically cross-sectional views showing various structures for a second type of transistors incorporated in a semiconductor integrated-circuit chip in accordance with another embodiments of the present application.

FIG. 5 is a schematically cross-sectional view showing a structure for a semiconductor integrated-circuit (IC) chip in accordance with another embodiment of the present application.

FIG. 6A is a schematically cross-sectional view showing a seventh type of semiconductor integrated-circuit (IC) chip in accordance with an embodiment of the present application.

FIG. 6B is a schematically cross-sectional view showing an eighth type of semiconductor integrated-circuit (IC) chip in accordance with an embodiment of the present application.

FIG. 6C is a cross-sectional view showing a second kind of connection structure for through silicon vias (TSVs) and an interconnection scheme in accordance with an embodiment of the present application.

FIG. 6D is a cross-sectional view showing a third kind of connection structure for through silicon vias (TSVs) and an interconnection scheme in accordance with an embodiment of the present application.

FIG. 6E is a cross-sectional view showing a first kind of connection structure for through silicon vias (TSVs) and an interconnection scheme in accordance with another embodiment of the present application.

FIG. 6F is a cross-sectional view showing a second kind of connection structure for through silicon vias (TSVs) and an interconnection scheme in accordance with another embodiment of the present application.

FIG. 6G is a cross-sectional view showing a third kind of connection structure for through silicon vias (TSVs) and an interconnection scheme in accordance with another embodiment of the present application.

FIG. 6H is a schematically cross-sectional view showing a ninth type of semiconductor integrated-circuit (IC) chip in accordance with an embodiment of the present application.

FIG. 6I is a schematically cross-sectional view showing a tenth type of semiconductor integrated-circuit (IC) chip in accordance with an embodiment of the present application.

FIG. 7 is a schematically top view showing arrangement of semiconductor integrated-circuit (IC) chips for a first type of chip module in accordance with an embodiment of the present application.

FIGS. 7A-7G are schematically cross-sectional views showing a process for fabricating a first type of chip module in accordance with an embodiment of the present application.

FIG. 8 is a schematically cross-sectional views showing a second type of chip module in accordance with an embodiment of the present application.

FIG. 9 is a schematically cross-sectional views showing a third type of chip module in accordance with an embodiment of the present application.

FIG. 10 is a schematically cross-sectional views showing a fourth type of chip module in accordance with an embodiment of the present application.

FIG. 11 is a schematically cross-sectional view showing a first type of chip package in accordance with an embodiment of the present application.

FIG. 12 is a schematically cross-sectional view showing a second type of chip package in accordance with an embodiment of the present application.

FIG. 13 is a schematically cross-sectional view showing a third type of chip package in accordance with an embodiment of the present application.

While certain embodiments are depicted in the drawings, one skilled in the art will appreciate that the embodiments depicted are illustrative and that variations of those shown, as well as other embodiments described herein, may be envisioned and practiced within the scope of the present application.

### DETAILED DESCRIPTION OF THE DISCLOSURE

Illustrative embodiments are now described. Other embodiments may be used in addition or instead. Details that may be apparent or unnecessary may be omitted to save space or for a more effective presentation. Conversely, some embodiments may be practiced without all of the details that are disclosed.

### Process for Fabricating Backside Interconnection Scheme of Integrated-Circuit Chip

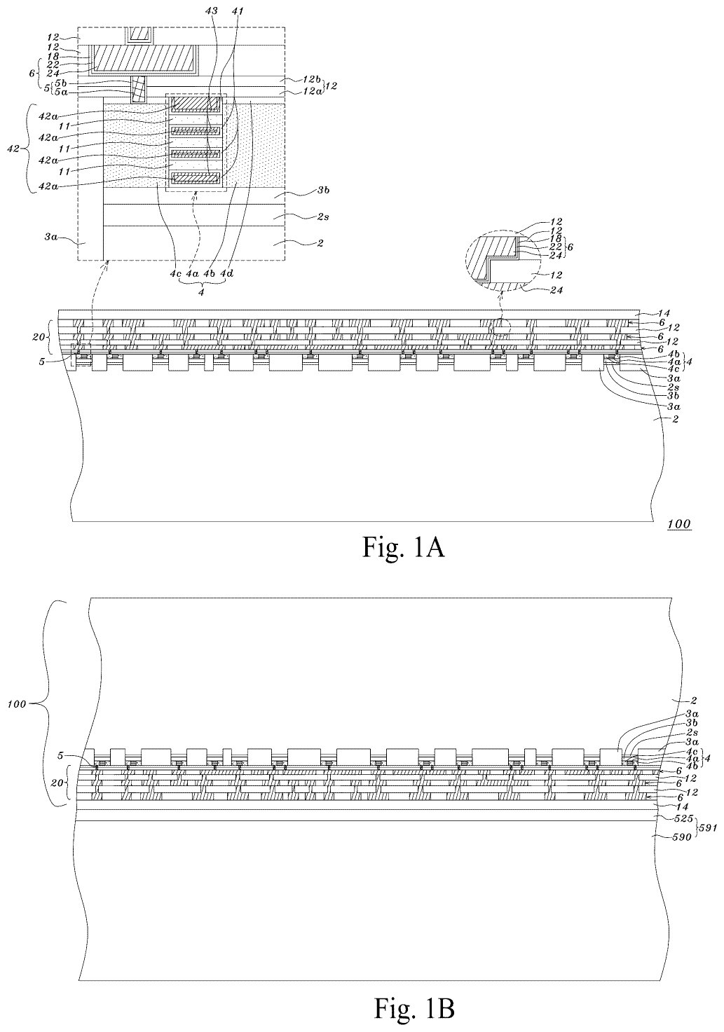

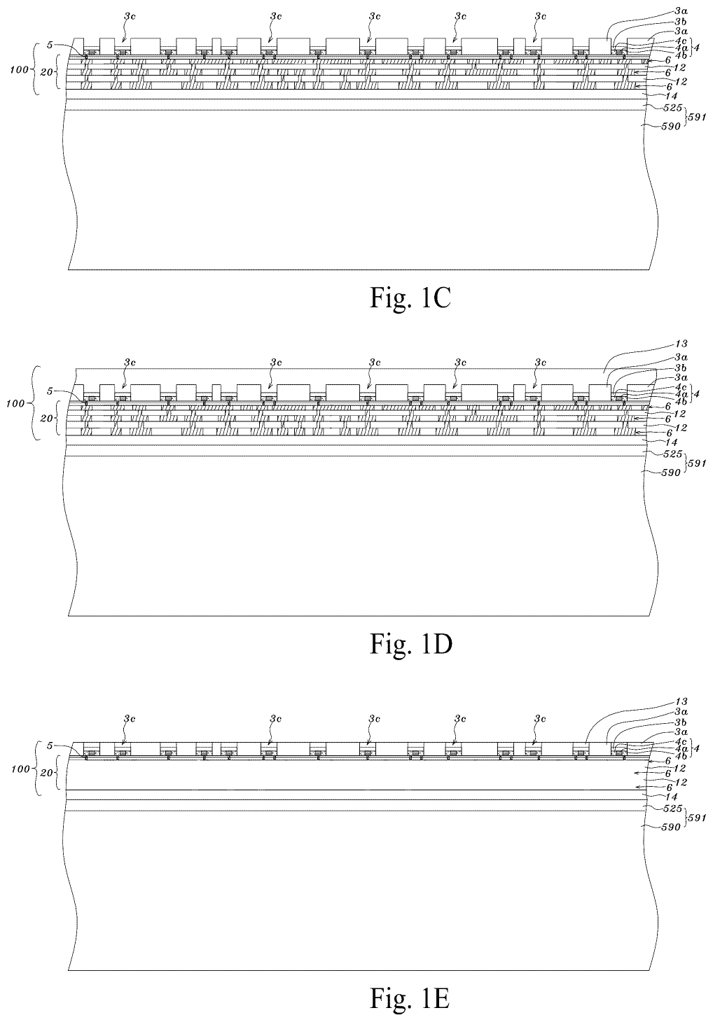

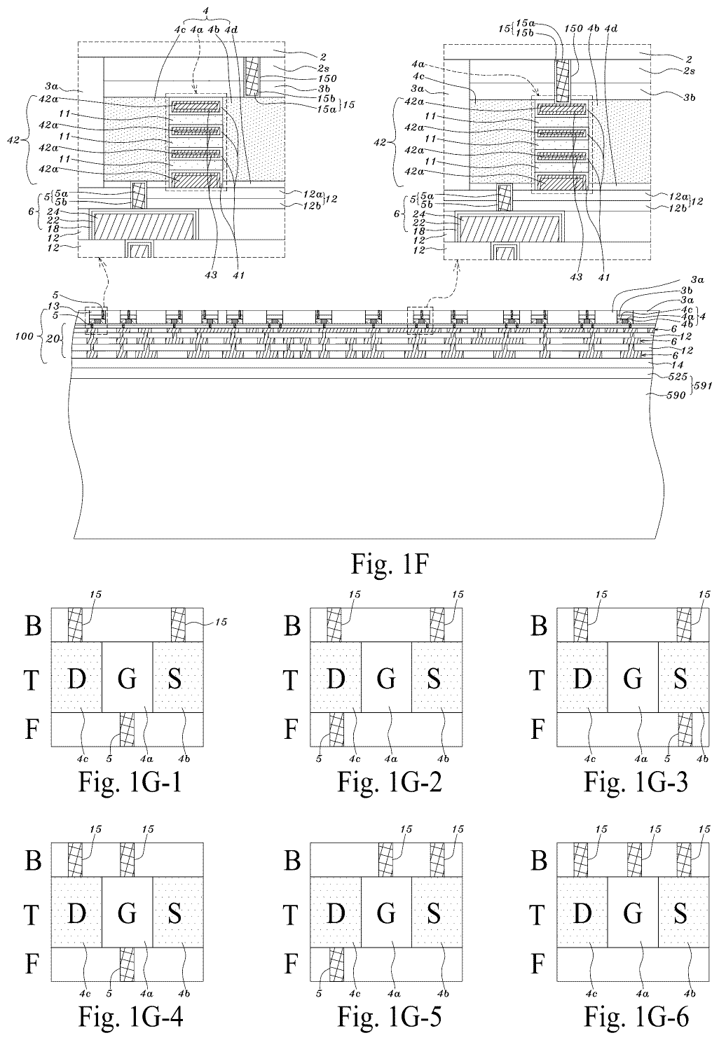

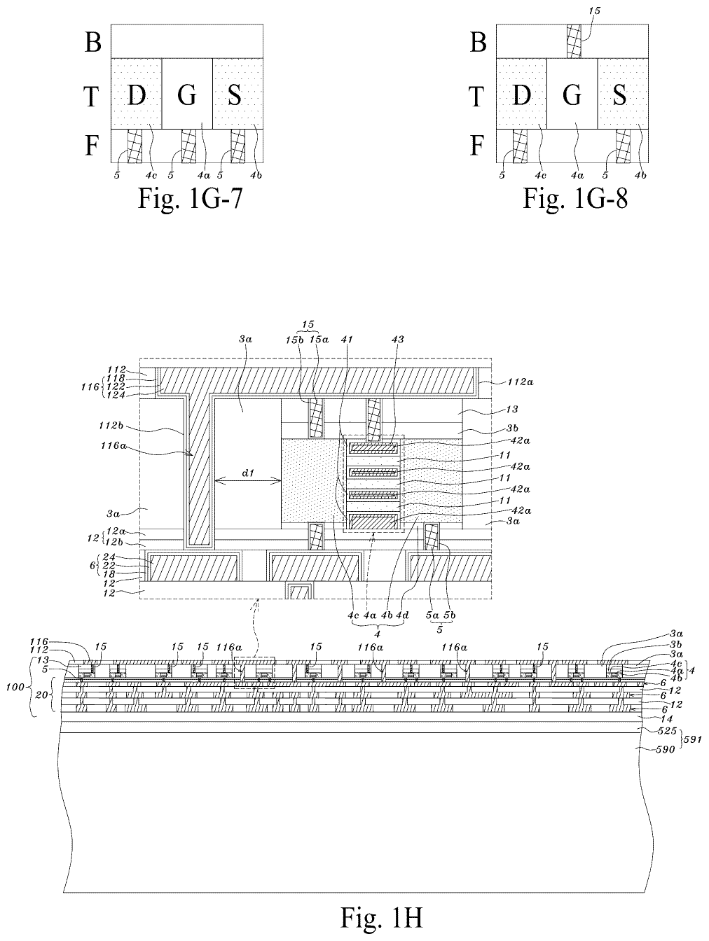

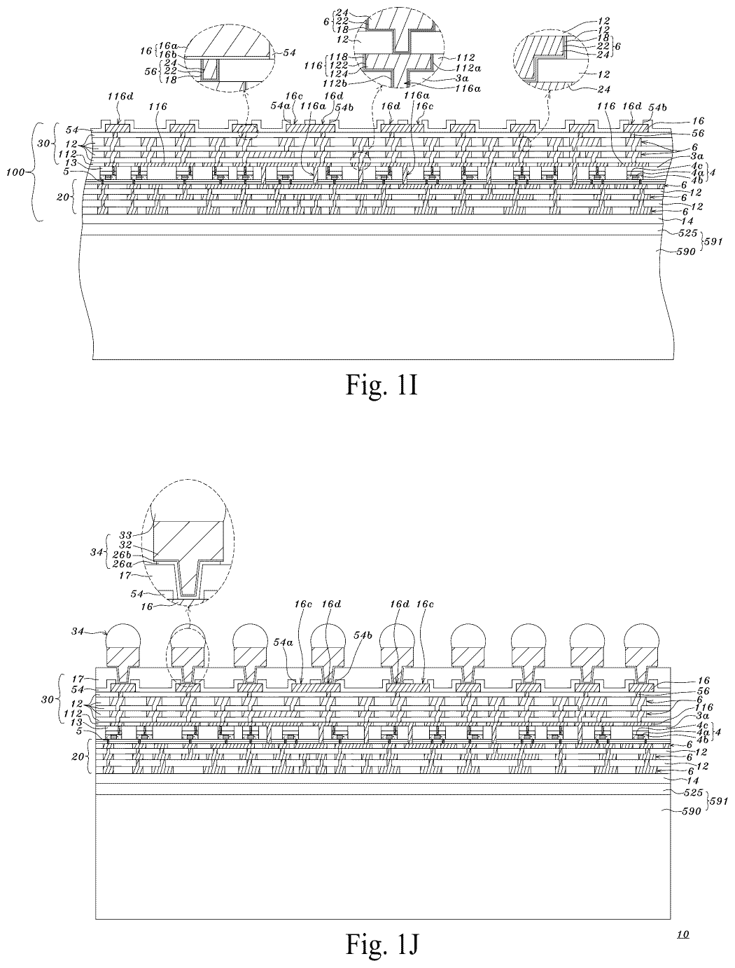

FIGS. 1A-1F and 1H-1L are schematically cross-sectional views showing a process for fabricating a backside interconnection scheme of a semiconductor integrated-circuit chip in accordance with an embodiment of the present application. Referring to FIG. 1A, a semiconductor integrated-circuit (IC) wafer 100 may be provided with (1) a semiconductor substrate 2, such as a semiconductor wafer made of single crystal silicon, (2) an insulating dielectric layer 2s on a front, i.e., top, surface of the semiconductor substrate 2, wherein the insulating dielectric layer 2s may be made of a layer of silicon germanium (SiGe) having a vertical thickness between 3 and 40 nanometers or between 6 and 20 nanometers, (3) an insulating dielectric layer 3b, i.e., silicon-on-insulator (SOI) dielectric layer on a front, i.e., top, surface of the insulating dielectric layer 2s, wherein the insulating dielectric layer 3b may be made of a layer of silicon oxide, silicon oxynitride or silicon nitride, multiple layers of silicon oxide and silicon oxynitride or multiple layers of silicon oxide and silicon nitride and may have a vertical thickness between 0.01 and 0.5 micrometers or between 0.02 and 0.3 micrometers, (4) multiple transistors 4 each at the front surface of the semiconductor substrate 2 and on the insulating dielectric layer 3b, wherein each of the transistors 4 may be formed with (i) two epitaxial portions 4b and 4c of silicon or silicon germanium (SiGe) doped with boron for a source and drain of an P-type metal-oxide-semiconductor (MOS) transistor respectively or with phosphorous for a source and drain of a N-type metal-oxide-semiconductor (MOS) transistor respectively, wherein each of the two epitaxial portions 4b and 4c of each of the transistors 4 may have a vertical thickness between 0.01 and 0.5 micrometers or between 0.02 and 0.3 micrometers, and wherein the two epitaxial portions 4b and 4c of each of the transistors 4 may be used as a source and drain of said each of the transistors 4 respectively, (ii) a gate-all-around (GAA) portion 4a between the two epitaxial portions 4b and 4c of said each of the transistors 4, and (iii) a layer 4d of filling oxide, i.e., insulating dielectric layer, on a front, i.e., top, surface of each of the two epitaxial portions 4b and 4c of said each of the transistors 4, wherein the layer 4d of filling oxide may be made of silicon oxide and have a vertical thickness between 1 and 10 nanometers or between 2 and 6 micrometers, and (5) a layer 3a of field oxide on the front surface of the semiconductor substrate 2 and horizontally surrounding each of its transistors 4, wherein the layer 3a of field oxide may have multiple portions each between neighboring two of its transistors 4, wherein its layer 3a of field oxide may be made of silicon oxide and have a vertical thickness between 0.05 and 5 micrometers, between 0.05 and 2 micrometers or between 0.1 and 0.5 micrometers, wherein its layer 3a of field oxide may have a front, i.e., top, surface coplanar with a front, i.e., top, surface of the layer 4d of filling oxide of each of its transistors 4 and a front, i.e., top, surface of the gate-all-around (GAA) portion 4a of each of its transistors 4. Each of its transistors 4 may be optionally formed with a layer of metal silicide (not shown), such as nickel silicide, cobalt silicide or titanium silicide, and on a front, i.e., top, surface of each of the two epitaxial portions 4b and 4c of said each of its transistors 4, wherein the layer 4d of filling oxide may be formed in case on the layer of metal silicide of said each of its transistors 4.

Referring to FIG. 1A, for each of the transistors 4 of the semiconductor integrated-circuit (IC) wafer 100, the gate-all-around (GAA) portion 4a of said each of the transistors 4 of the semiconductor integrated-circuit (IC) wafer 100 may include (1) multiple channels 11 each extending, in a first horizontal direction, between its two epitaxial portions 4b and 4c and having two opposite left and right ends joining its two epitaxial portions 4b and 4c respectively and between two opposite sidewalls of the layer 3a of field oxide of the semiconductor integrated-circuit (IC) wafer 100, wherein each of the channels 11 thereof may be an epitaxial layer of silicon having a channel length, i.e., a first horizontal dimension from one of its two epitaxial portions 4b and 4c of silicon or silicon germanium (SiGe) to the other of its two epitaxial portions 4b and 4c of silicon or silicon germanium (SiGe), between 8 and 15 nanometers and a vertical thickness between 1 and 20 nanometers, between 2 and 20 nanometers, between 1 and 6 nanometers or between 4 and 10 nanometers, (2) a metal gate 42 provided with (i) horizontal portions 42a each extending, in a second horizontal direction vertical to the first horizontal direction, between neighboring two of the channels 11 thereof, over the frontmost, i.e., topmost, one of the channels 11 thereof or between the backmost, i.e., bottommost, one of the channels 11 thereof and the top surface of the insulating dielectric layer 3b of the semiconductor integrated-circuit (IC) wafer 100, and (ii) two vertical portions (not shown in FIG. 1A) each vertically extending between each of the horizontal portions of the metal gate 42 thereof and one of the two opposite sidewalls of the layer 3a of field oxide of the semiconductor integrated-circuit (IC) wafer 100 and coupling to each other through any of the horizontal portions 42a of the metal gate 42 thereof, wherein the metal gate 42 thereof may be made of an aluminum alloy, such as an aluminum-copper alloy or aluminum-titanium alloy, wherein the frontmost, i.e., topmost, one of the horizontal portions 42a of the metal gate 42 thereof may have a front, i.e., top, surface coplanar with the front surface of the layer 4d of filling oxide of said each of the transistors 4 of the semiconductor integrated-circuit (IC) wafer 100 and the front surface of the layer 3a of field oxide of the semiconductor integrated-circuit (IC) wafer 100, (3) a layer 41 of gate oxide surrounding and in contact with each of the channels 11 thereof, surrounding each of the horizontal portions 42a and two vertical portions of the metal gate 42 thereof and on and in contact with a top surface and bottom surface and two opposite sidewalls of each of the channels 11 thereof, two opposite sidewalls of its two epitaxial portions 4b and 4c, the two opposite sidewalls of the layer 3a of field oxide of the semiconductor integrated-circuit (IC) wafer 100 and a front, i.e., top, surface of the insulating dielectric layer 3b of the semiconductor integrated-circuit (IC) wafer 100, wherein the layer 41 of gate oxide thereof may have a high dielectric constant, such as hafnium oxide (HfO₂) or tantalum oxide (Ta₂O₃), and (4) a layer 43 of work function metal between the metal gate 42 thereof and the layer 41 of gate oxide thereof and surrounding and in contact with each of the horizontal portions 42a and two vertical portions of the metal gate 42 thereof, wherein the layer 43 of work function metal thereof may be made of titanium nitride (TiN), tantalum nitride (TaN), a titanium-aluminum (TiAl) alloy or tungsten nitride (WN). For example, the layer 43 of work function metal thereof may be made of a titanium-aluminum (TiAl) alloy in case that said each of the transistors 4 of the semiconductor integrated-circuit (IC) wafer 100 is made for an N-type metal-oxide-semiconductor (MOS) transistor; the layer 43 of work function metal thereof may be made of titanium nitride (TiN) in case that said each of the transistors 4 of the semiconductor integrated-circuit (IC) wafer 100 is made for a P-type metal-oxide-semiconductor (MOS) transistor.

Referring to FIG. 1A, the semiconductor integrated-circuit (IC) wafer 100 may further include a frontside interconnection scheme 20 on a front, i.e., top, surface of its transistors 4 and the front surface of its layer 3a of field oxide, provided with one or more interconnection metal layers 6 coupling to its transistors 4 and one or more insulating dielectric layers 12 each covering a sidewall of one of its interconnection metal layers 6 or between neighboring two of its interconnection metal layers 6. For the semiconductor integrated-circuit (IC) wafer 100, each of the interconnection metal layers 6 of its frontside interconnection scheme 20 may include (1) a copper layer 24 having lower portions in openings in a lower one of the insulating dielectric layers 12, such as SiOC layers each having a vertical thickness of between 3 nm and 500 nm, of its frontside interconnection scheme 20 and upper portions having a vertical thickness of between 3 nm and 500 nm over the lower one of the insulating dielectric layers 12 and in openings in an upper one of the insulating dielectric layers 12 of its frontside interconnection scheme 20, (2) an adhesion metal layer 18, such as titanium or titanium nitride having a thickness of between 1 nm and 50 nm, at a bottom and sidewall of each of the lower portions of the copper layer 24 and at a bottom and sidewall of each of the upper portions of the copper layer 24, and (3) an electroplating seed layer 22, such as copper, between the copper layer 24 and the adhesion metal layer 18, wherein the copper layer 24 of said each of the interconnection metal layers 6 may have a front, i.e., top, surface coplanar with a front, i.e., top, surface of the upper one of the insulating dielectric layers 12. Alternatively, each of the interconnection metal layers 6 of its frontside interconnection scheme 20 may include a tungsten layer having lower portions in openings in a lower one of the insulating dielectric layers 12, such as SiOC layers each having a vertical thickness of between 3 nm and 500 nm, of its frontside interconnection scheme 20 and upper portions having a vertical thickness of between 3 nm and 500 nm over the lower one of the insulating dielectric layers 12 and in openings in an upper one of the insulating dielectric layers 12 of its frontside interconnection scheme 20, wherein the tungsten layer of said each of the interconnection metal layers 6 may have a front, i.e., top, surface coplanar with a front, i.e., top, surface of the upper one of the insulating dielectric layers 12.

Alternatively, referring to FIG. 1A, for the semiconductor integrated-circuit (IC) wafer 100, the innermost one of the interconnection metal layers 6 of its frontside interconnection scheme 20 may include multiple frontside contacts 5, each of a first group of which may be formed in an opening in the innermost one of the insulating dielectric layers 12 of its frontside interconnection scheme 20 and an opening in the layer 4d of filling oxide of one of its transistors 4 and with a bottom surface in contact with a front, i.e., top, surface of the source or drain of said one of its transistors 4, i.e., a front, i.e., top, surface of the epitaxial portion 4b or 4c thereof, or a front, i.e., top, surface of the layer of metal silicide in case formed on the top surface of the epitaxial portion 4b or 4c thereof, and each of a second group of which may be formed in an opening in the innermost one of the insulating dielectric layers 12 of its frontside interconnection scheme 20 and with a bottom surface in contact with a front, i.e., top, surface of the frontmost one of the horizontal portions 42a of the metal gate 42 of the gate-all-around (GAA) portion 4a of one of its transistors 4. Each of the first and second groups of the frontside contacts 5 of the innermost one of the interconnection metal layers 6 of its frontside interconnection scheme 20 may have a transverse dimension less than or equal to 0.1 micrometers and a vertical thickness less than or equal to 0.5 micrometers. Each of the first and second groups of the frontside contacts 5 of the innermost one of the interconnection metal layers 6 of its frontside interconnection scheme 20 may include (1) a metal plug 5a, such as tungsten plug, cobalt plug, nickel plug or tantalum plug, in an opening in the innermost one of the insulating dielectric layers 12 of its frontside interconnection scheme 20 and (2) an adhesion barrier layer 5b, such as titanium, titanium nitride (TiN), tantalum or tantalum nitride (TaN), having a thickness between 1 and 6 nanometers or between 2 and 5 nanometers at a sidewall and bottom of the metal plug 5a thereof; the adhesion barrier layer 5b of each of the first group of the frontside contacts 5 of the innermost one of the interconnection metal layers 6 of its frontside interconnection scheme 20 may be further between the metal plug 5a of said each of the first group of the frontside contacts 5 and a front, i.e., top, surface of one of the source and drain of one of its transistors 4 and in contact with the front surface of said one of the source and drain, and the adhesion barrier layer 5b of each of the second group of the frontside contacts 5 of the innermost one of the interconnection metal layers 6 of its frontside interconnection scheme 20 may be further between the metal plug 5a of said each of the second group of the frontside contacts 5 and a front, i.e., top, surface of the frontmost one of the horizontal portions 42a of the metal gate 42 of the gate-all-around (GAA) portion 4a of one of its transistors 4 and in contact with the front surface of the frontmost one of the horizontal portions 42a of the metal gate 42 of the gate-all-around (GAA) portion 4a of said one of its transistors 4. The innermost one of the interconnection metal layers 6 of its frontside interconnection scheme 20 may further include (1) a copper layer 24 having a vertical thickness between 3 and 500 nanometers over the innermost one of the insulating dielectric layers 12 and each of the first and second groups of the frontside contacts 5 and in openings in the second innermost one of the insulating dielectric layers 12 of its frontside interconnection scheme 20, (2) an adhesion metal layer 18, such as titanium or titanium nitride having a thickness of between 1 nm and 50 nm, at a bottom and sidewall of the copper layer 24 thereof, between the copper layer 24 thereof and each of the first and second groups of the frontside contacts 5 thereof and in contact with said each of the first and second groups of the frontside contacts 5 thereof, and (3) an electroplating seed layer 22, such as copper, between the copper layer 24 and adhesion metal layer 18 thereof, wherein the copper layer 24 thereof may have a front, i.e., top, surface coplanar with a front, i.e., top, surface of the second innermost one of the insulating dielectric layers 12 of its frontside interconnection scheme 20, wherein the copper layer 24 thereof may couple to one of the source and drain of one of its transistors 4 through one of the first group of the frontside contacts 5 thereof and couple to the metal gate 42 of the gate-all-around (GAA) portion 4a of one of its transistors 4 through one of the second group of the frontside contacts 5 thereof. Further, the innermost one of the insulating dielectric layers 12 of its frontside interconnection scheme 20 may include (1) a lower layer 12a, containing silicon carbon nitride (SiCN) and having a vertical thickness between 5 and 35 nanometers, between 10 and 25 nanometers or equal to or less than 100 or 50 nanometers, on the front surface of its transistors 4 and the front surface of its layer 3a of field oxide and (2) an upper layer 12b, containing silicon oxide and having a vertical thickness between 20 and 120 nanometers or between 30 and 100 nanometers, on a top surface of the lower layer 12a thereof. Alternatively, the lower layer 12a of the innermost one of the insulating dielectric layers 12 of its frontside interconnection scheme 20 may further include silicon oxide.

Referring to FIG. 1A, for the semiconductor integrated-circuit (IC) wafer 100, each of the interconnection metal layers 6 of its frontside interconnection scheme 20 may be patterned with multiple metal lines or traces each having a vertical thickness between 0.1 and 2 micrometers, between 3 nm and 1,000 nm or between 10 nm and 500 nm, or smaller than or equal to 5 nm, 10 nm, 30 nm, 50 nm, 100 nm, 200 nm, 300 nm, 500 nm or 1,000 nm and a horizontal width between 3 nm and 1,000 nm or between 10 nm and 500 nm, or smaller than 5 nm, 10 nm, 20 nm, 30 nm, 70 nm, 100 nm, 300 nm, 500 nm or 1,000 nm, for example. A pitch between neighboring two of the metal lines or traces of said each of the interconnection metal layers 6 may be less than or equal to 50 or 30 nanometers. Each of the insulating dielectric layers 12 of its frontside interconnection scheme 20 may be made of a layer of silicon oxide or silicon oxycarbide having a vertical thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm. Alternatively, each of the insulating dielectric layers 12 of its frontside interconnection scheme 20 may include a material having a low dielectric constant of lower than 3, for example. Alternatively, each of the insulating dielectric layers 12 of its frontside interconnection scheme 20 may be a composite layer including two silicon-oxynitride layers at a top and bottom thereof and a silicon-oxide layer between the two silicon-oxynitride layers thereof.

Referring to FIG. 1A, the semiconductor integrated-circuit (IC) wafer 100 may further include an insulating bonding layer 14 on a front, i.e., top, surface of the outermost one of the interconnection metal layers 6 of its frontside interconnection scheme 20 and a front, i.e., top, surface of the outermost one of the insulating dielectric layers 12 of its frontside interconnection scheme 20, wherein its insulating bonding layer 14 may (1) for a first case, be made of silicon oxide, or (2) for a second case, be made of silicon oxynitride or include a layer of silicon oxide on the front surface of the outermost one of the interconnection metal layers 6 of its frontside interconnection scheme 20 and the top surface of the outermost one of the insulating dielectric layers 12 of its frontside interconnection scheme 20 and a layer of silicon oxynitride on a front, i.e., top, surface of the layer of silicon oxide thereof, wherein its insulating bonding layer 14 may have a vertical thickness between 0.1 and 3 micrometers or between 0.1 and 1 micrometers.

Referring to FIG. 1B, a supporting substrate 591 may be provided with (1) a silicon substrate 590 made of single-crystal silicon or polycrystal silicon and having a vertical thickness between 30 and 400 micrometers, and (2) an insulating bonding layer 525 on a top surface of its silicon substrate 590, wherein its insulating bonding layer 525 may (1) for a first case, be made of silicon oxide, or (2) for a second case, be made of silicon oxynitride or include a layer of silicon oxide on the top surface of its silicon substrate 590 and a layer of silicon oxynitride on a top surface of the layer of silicon oxide thereof, wherein its insulating bonding layer 525 may have a vertical thickness between 0.001 and 1 micrometers or between 0.001 and 0.1 micrometers.

Next, referring to FIG. 1B, the semiconductor integrated-circuit (IC) wafer 100 as illustrated in FIG. 1A may be turned upside down to have a front, i.e., bottom, surface of the insulating bonding layer 14 of the semiconductor integrated-circuit (IC) wafer 100 bonded to a top surface of the insulating bonding layer 525 of the supporting substrate 591 via oxide-to-oxide bonding. For example, the insulating bonding layer 14 of the semiconductor integrated-circuit (IC) wafer 100 for the first case may be the layer of silicon oxide having a front, i.e., bottom, surface bonded to a top surface of the layer of silicon oxide of the insulating bonding layer 525 of the supporting substrate 591 for the first case or to a top surface of the layer of silicon oxynitride of the insulating bonding layer 525 of the supporting substrate 591 for the second case; alternatively, the insulating bonding layer 14 of the semiconductor integrated-circuit (IC) wafer 100 for the second case may be or include the layer of silicon oxynitride having a front, i.e., bottom, surface bonded to a top surface of the layer of silicon oxide of the insulating bonding layer 525 of the supporting substrate 591 for the first case or to a top surface of the layer of silicon oxynitride of the insulating bonding layer 525 of the supporting substrate 591 for the second case.

Next, the semiconductor substrate 2 and insulating dielectric layer 2s of the semiconductor integrated-circuit (IC) wafer 100 as seen in FIG. 1B may be removed using one or more processes of mechanical polishing, chemical-mechanical polishing (CMP) and/or dry or wet etching such that each of the layer 3a of field oxide and insulating dielectric layer 3b of the semiconductor integrated-circuit (IC) wafer 100 may have a back, i.e., top, surface to be exposed as seen in FIG. 1C, wherein the back surface of the insulating dielectric layer 3b of the semiconductor integrated-circuit (IC) wafer 100 may be recessed from the back surface of the layer 3a of field oxide of the semiconductor integrated-circuit (IC) wafer 100 to form multiple recessed spaces 3c over the back surface of the insulating dielectric layer 3b of the semiconductor integrated-circuit (IC) wafer 100 and horizontally surrounded by the layer 3a of field oxide of the semiconductor integrated-circuit (IC) wafer 100. Next, referring to FIG. 1D, the semiconductor integrated-circuit (IC) wafer 100 may be further formed with a layer 13 of filling oxide, such as silicon oxide, may be deposited on the back surface of each of its layer 3a of field oxide and its insulating dielectric layer 3b and in each of the recessed spaces 3c. Next, the layer 13 of filling oxide may have a top portion over the back surface of its layer 3a of field oxide and each of the recessed spaces 3c to be removed by a chemical-mechanical-polishing (CMP) process such that the back surface of its layer 3a of field oxide may be exposed to be coplanar with a back, i.e., top, surface of its layer 13 of filling oxide left in each of the recessed spaces 3c, as seen in FIG. 1E.

Next, referring to FIG. 1F, for the semiconductor integrated-circuit (IC) wafer 100, multiple backside contact holes 150 may be formed in and through its layer 13 of filling oxide and its insulating dielectric layer 3b. Each of a first group of the backside contact holes 150 may expose a back, i.e., top, surface of one of the two epitaxial portions 4b and 4c of one of its transistors 4. Each of a second group of the backside contact holes 150 may be formed further in and through the layer 41 of gate oxide of the gate-all-around (GAA) portion 4a of one of its transistors 4 to expose a back, i.e., top, surface of the layer 43 of work function metal of the gate-all-around (GAA) portion 4a of said one of its transistors 4, which surrounds and in contact with the backmost one of the horizontal portions 42a of the metal gate 42 of the gate-all-around (GAA) portion 4a of said one of its transistors. Next, an adhesion barrier layer 15b, such as titanium, titanium nitride (TiN), tantalum or tantalum nitride (TaN), having a thickness between 1 and 6 nanometers or between 2 and 5 nanometers may be formed, by one or more processes of physical vapor deposition (PVD), chemical vapor deposition (CVD) and/or atomic layer deposition (ALD), on the back surface of its layer 13 of filling oxide, the back surface of its layer 3a of field oxide, a sidewall of each of the first and second groups of the backside contact holes 150, the exposed back surface of the epitaxial portions 4b and 4c of its transistors 4 and the exposed back surface of the layers 43 of work function metal of the gate-all-around (GAA) portions 4a of its transistors 4. Next, a metal layer 15a, such as tungsten, cobalt, nickel or tantalum, may be formed, by one or more processes of physical vapor deposition (PVD), chemical vapor deposition (CVD) and/or atomic layer deposition (ALD), on the adhesion barrier layer 15b and in each of the first and second groups of the backside contact holes 150. Next, the metal layer 15a and adhesion barrier layer 15b over the back surface of its layer 13 of filling oxide and the back surface of its layer 3a of field oxide may be removed by one or more processes of chemical mechanical polishing (CMP) and/or reactive-ion etching (RIE) to expose the back surface of its layer 13 of filling oxide and the back surface of its layer 3a of field oxide and to form multiple backside contacts 15 in the backside contact holes 150 for the semiconductor integrated-circuit (IC) wafer 100. For the semiconductor integrated-circuit (IC) wafer 100, each of a first group of its backside contacts 15 may be formed in one of the first group of the backside contact holes 150 and each of a second group of its backside contacts 15 may be formed in one of the second group of the backside contact holes 150, wherein each of the first and second groups of its backside contacts 15 may have a back, i.e., top, surface coplanar with the back surface of its layer 13 of filling oxide and the back surface of its layer 3a of field oxide. The metal layer 15a may be formed for a metal plug of each of its first and second groups of the backside contacts 15. Thereby, each of the first group of its backside contacts 15 may include (1) one of the metal plugs 15a, such as tungsten plug, cobalt plug, nickel plug or tantalum plug, in one of the first group of the backside contact holes 150 and (2) the adhesion barrier layer 15b, such as titanium, titanium nitride (TiN), tantalum or tantalum nitride (TaN), having a thickness between 1 and 6 nanometers or between 2 and 5 nanometers at a sidewall and bottom of said one of the metal plugs 15a thereof, between said one of the metal plugs 15a thereof and the back surface of one of the two epitaxial portions 4b and 4c of one of its transistors 4 and in contact with the back surface of said one of the two epitaxial portions 4b and 4c. Each of the second group of its backside contacts 15 may include (1) one of the metal plugs 15a, such as tungsten plug, cobalt plug, nickel plug or tantalum plug, in one of the second group of the backside contact holes 150 and (2) the adhesion barrier layer 15b, such as titanium, titanium nitride (TiN), tantalum or tantalum nitride (TaN), having a thickness between 1 and 6 nanometers or between 2 and 5 nanometers at a sidewall and bottom of said one of the metal plugs 15a thereof, between said one of the metal plugs 15a thereof and the back surface of the layer 43 of work function metal of the gate-all-around (GAA) portion 4a of one of its transistors 4, which surrounds and in contact with the backmost one of the horizontal portions 42a of the metal gate 42 of the gate-all-around (GAA) portion 4a of said one of its transistors, and in contact with the back surface of the layer 43 of work function metal of the gate-all-around (GAA) portion 4a of said one of its transistors 4. Each of the first and second groups of the backside contacts 15 may have a horizontal dimension less than or equal to 0.1 micrometers.

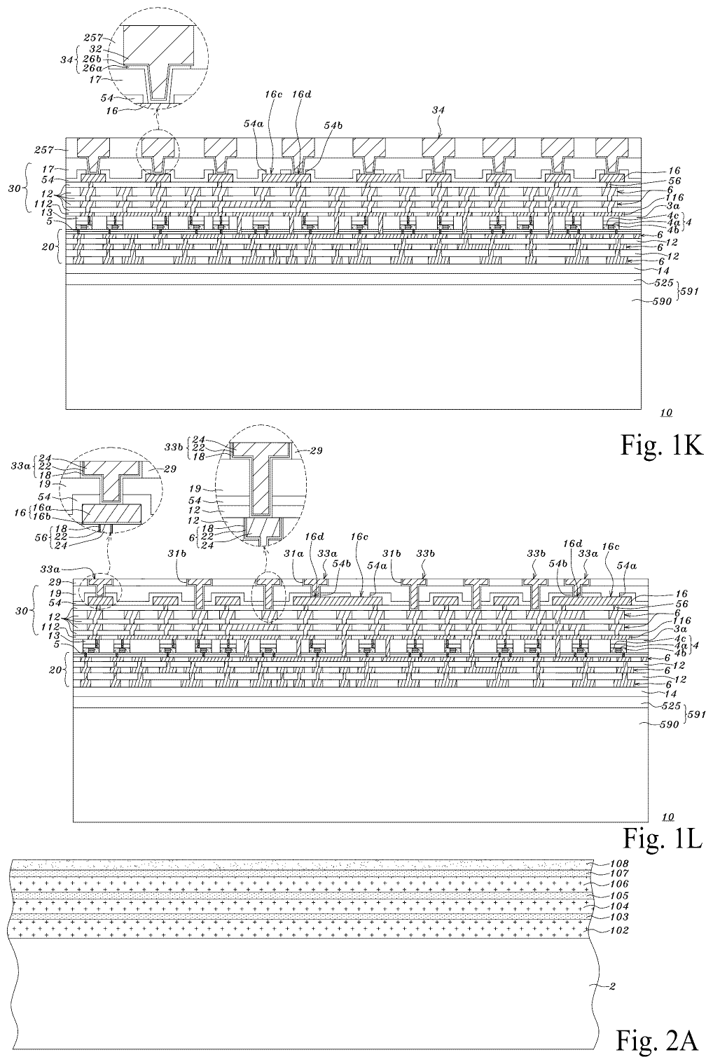

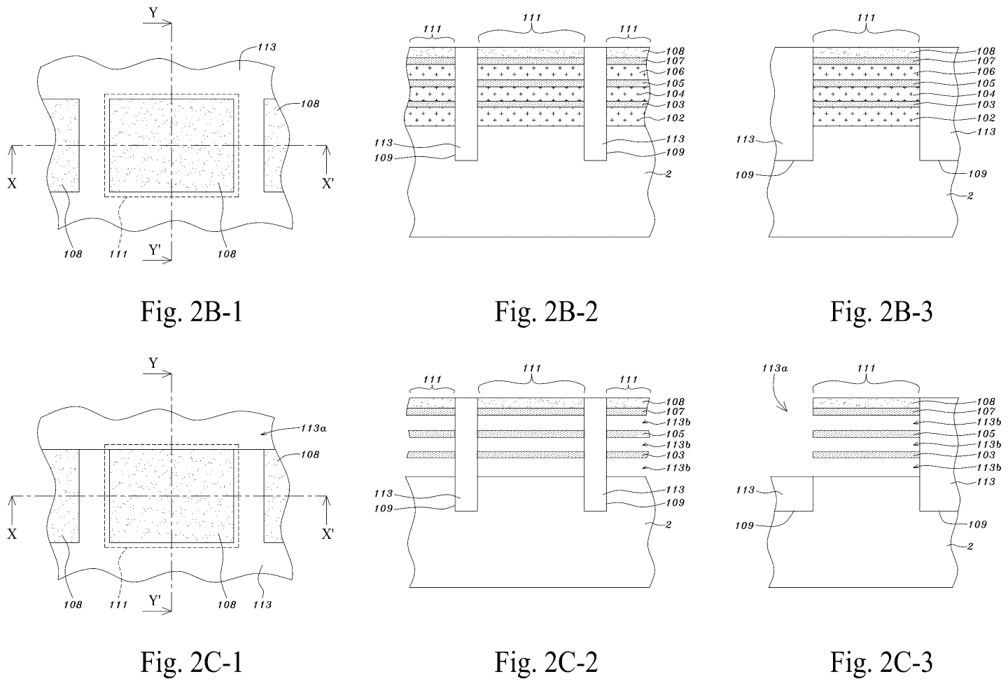

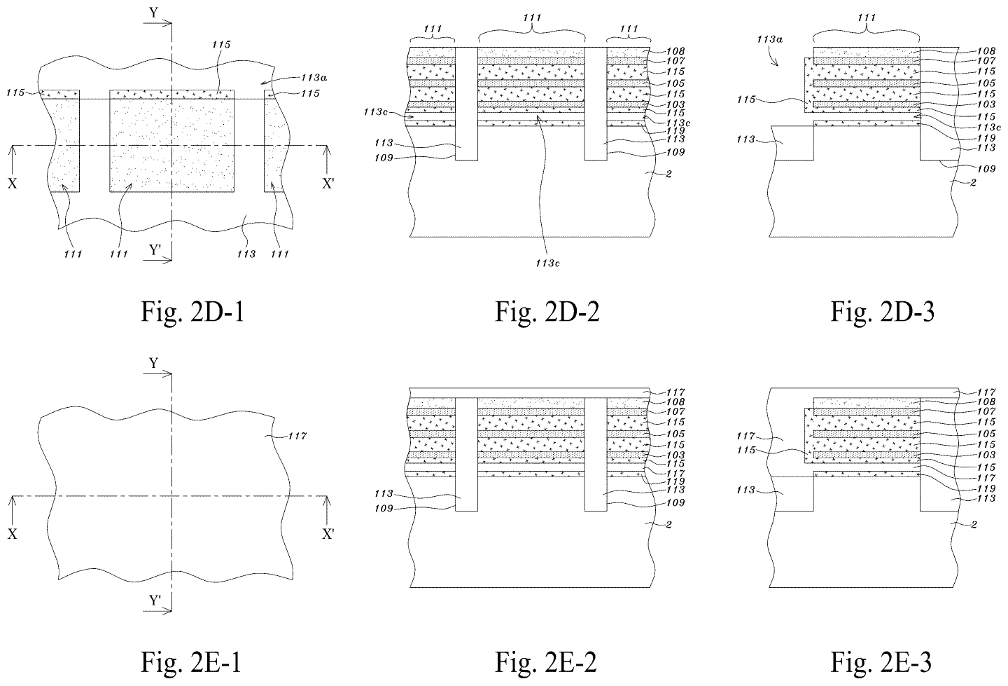

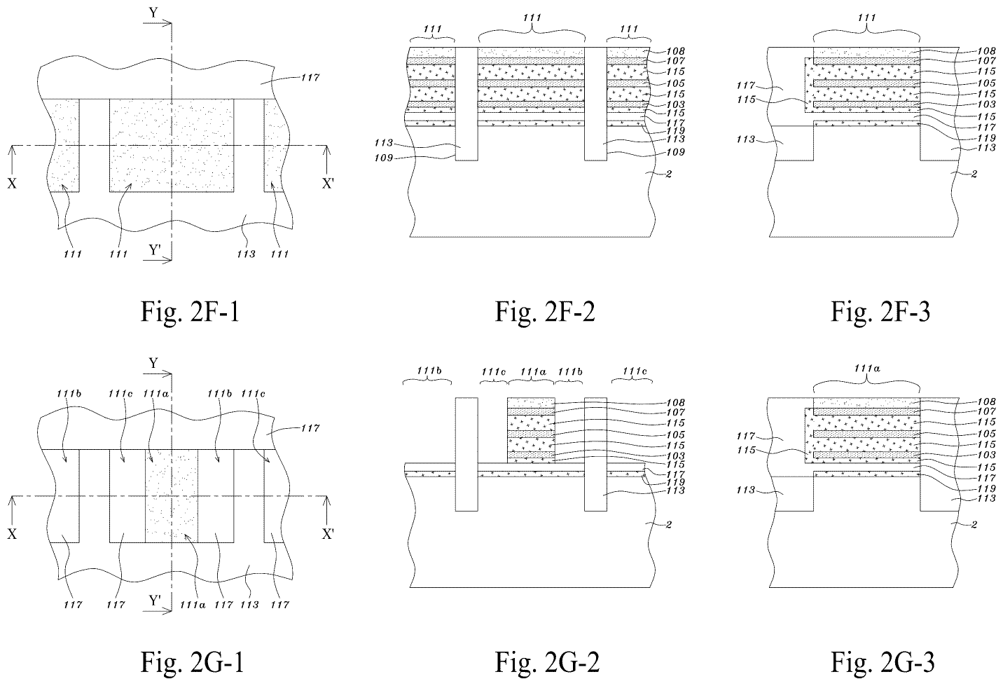

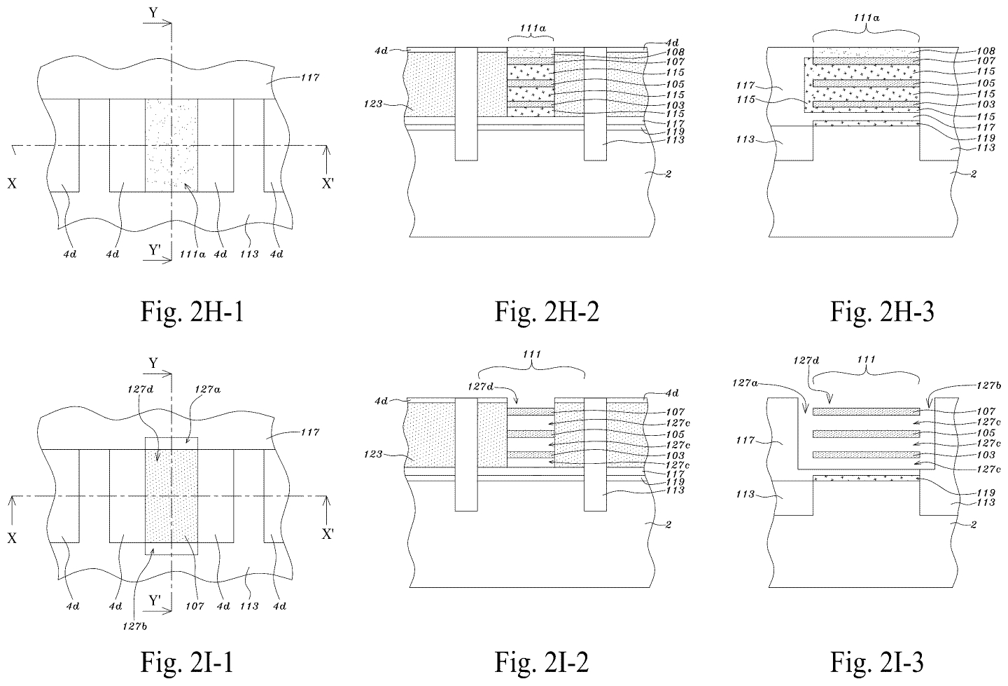

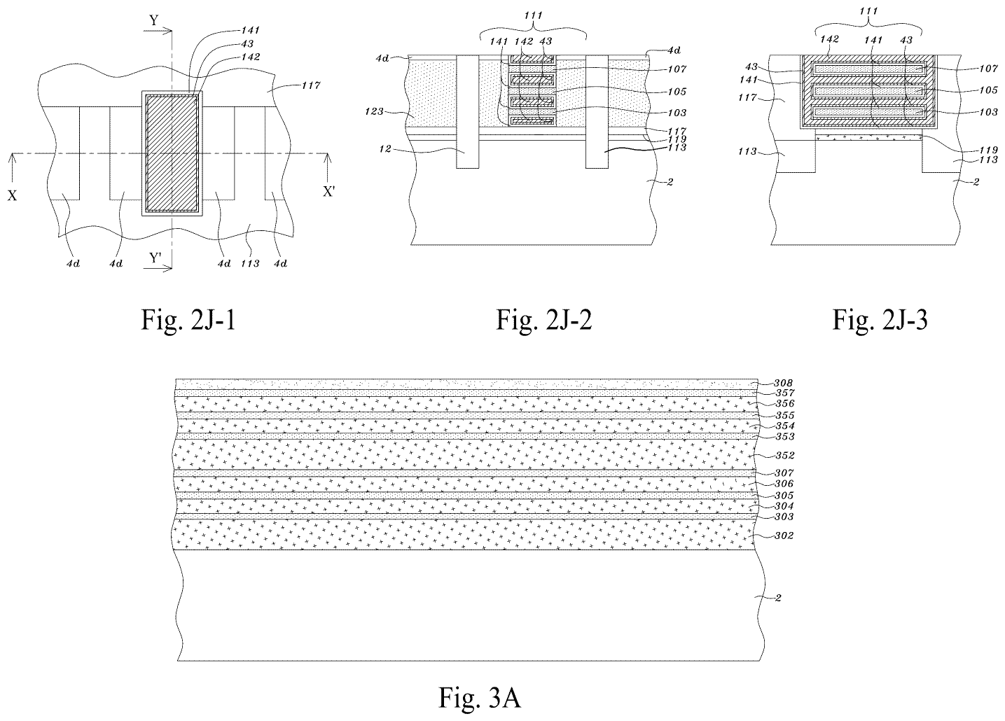

FIGS. 1G-1 through 1G-8 shows various scenarios of coupling of a transistor to frontside and backside contacts in accordance with an embodiment of the present application. Referring to FIG. 1G-1, for the semiconductor integrated-circuit (IC) wafer 100, a first one of its transistors 4 may include (1) the source 4b having the back surface in contact with a first one of its backside contacts 15, (2) the drain 4c having the back surface in contact with a second one of its backside contacts 15, and (3) the gate-all-around (GAA) portion 4a having the metal gate 42 having the horizontal portions 42a having the frontmost one having the front surface in contact with a first one of its frontside contacts 5; referring to FIG. 1G-2, a second one of its transistors 4 of the semiconductor integrated-circuit (IC) wafer 100 may include (1) the source 4b having the back surface in contact with a third one of its backside contacts 15, and (2) the drain 4c having the back surface in contact with a fourth one of its backside contacts 15 and the front surface in contact with a second one of its frontside contacts 5; referring to FIG. 1G-3, a second one of its transistors 4 may include (1) the source 4b having the back surface in contact with a fifth one of its backside contacts 15 and the front surface in contact with a third one of its frontside contacts 5, and (2) the drain 4c having the back surface in contact with a sixth one of its backside contacts 15; referring to FIG. 1G-4, a fourth one of its transistors 4 may include (1) the drain 4c having the back surface in contact with a seventh one of its backside contacts 15, and (2) the gate-all-around (GAA) portion 4a having (i) the metal gate 42 having the horizontal portions 42a having the frontmost one having the front surface in contact with a fourth one of its frontside contacts 5 and (ii) the layer 43 of work function metal, which surrounds and in contact with the backmost one of the horizontal portions 42a of the metal gate 42 thereof, having the back surface in contact with an eighth one of its backside contacts 15; referring to FIG. 1G-5, a fifth one of its transistors 4 may include (1) the source 4b having the back surface in contact with a ninth one of its backside contacts 15, (2) the drain 4c having the front surface in contact with a fifth one of its frontside contacts 5, and (3) the gate-all-around (GAA) portion 4a having the layer 43 of work function metal, which surrounds and in contact with the backmost one of the horizontal portions 42a of the metal gate 42 thereof, having the back surface in contact with a tenth one of its backside contacts 15; referring to FIG. 1G-6, a sixth one of its transistors 4 may include (1) the source 4b having the back surface in contact with an eleventh one of its backside contacts 15, (2) the drain 4c having the back surface in contact with a twelfth one of its backside contacts 15, and (3) the gate-all-around (GAA) portion 4a having the layer 43 of work function metal, which surrounds and in contact with the backmost one of the horizontal portions 42a of the metal gate 42 thereof, having the back surface in contact with a thirteenth one of its backside contacts 15; referring to FIG. 1G-7, a seventh one of its transistors 4 may include (1) the source 4b having the front surface in contact with an sixth one of its frontside contacts 5, (2) the drain 4c having the front surface in contact with a seventh one of its frontside contacts 5, and (3) the gate-all-around (GAA) portion 4a having the metal gate 42 having the horizontal portions 42a having the frontmost one having the front surface in contact with an eighth one of its frontside contacts 5; and referring to FIG. 1G-8, an eighth one of its transistors 4 may include (1) the source 4b having the front surface in contact with an ninth one of its frontside contacts 5, (2) the drain 4c having the front surface in contact with a tenth one of its frontside contacts 5, and (3) the gate-all-around (GAA) portion 4a having the layer 43 of work function metal, which surrounds and in contact with the backmost one of the horizontal portions 42a of the metal gate 42 thereof, having the back surface in contact with a fourteenth one of its backside contacts 15.

Next, referring to FIG. 1H, the semiconductor integrated-circuit (IC) wafer 100 may be further formed with an insulating dielectric layer 112, by a process of chemical vapor deposition (CVD), on the back surface of its layer 13 of filling oxide, the back surface of each of the first and second groups of its backside contacts 15 and the back surface of its layer 3a of field oxide, wherein its insulating dielectric layer 112 may be made of a layer of silicon oxide or silicon oxycarbide having a vertical thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm. Alternatively, its insulating dielectric layer 112 may include a material having a low dielectric constant of lower than 3, for example. Alternatively, its insulating dielectric layer 112 may be a composite layer including two silicon-oxynitride layers at a top and bottom thereof and a silicon-oxide layer between the two silicon-oxynitride layers thereof. Next, multiple openings 112a may be each formed, by processes of photolithography and etching, in and through its insulating dielectric layer 112, wherein each of the openings 112a may expose any, some or each of the back surface of its layer 13 of filling oxide, the back surfaces of the first and second groups of its backside contacts 15 and the back surface of its layer 3a of field oxide. Further, multiple openings 112b may be formed, by processes of photolithography and etching, in and through its layer 3a of field oxide and the innermost one of the insulating dielectric layers 12 of its frontside interconnection scheme 20, wherein each of the openings 112b may expose a back surface of the innermost one of the interconnection metal layers 6 of its frontside interconnection scheme 20.

Next, the semiconductor integrated-circuit (IC) wafer 100 may be further formed with an interconnection metal layer 116 in each of the openings 112a and 112b by forming, using one or more processes of physical vapor deposition (PVD), chemical vapor deposition (CVD) and/or atomic layer deposition (ALD), an adhesion metal layer 118, such as titanium or titanium nitride (TiN), having a thickness between 1 and 50 nanometers on a back, i.e., top, surface of its insulating dielectric layer 112, at a sidewall and bottom of each of the openings 112a and 112b and in contact with the back surfaces of the first and second groups of its backside contacts 15 and the back surface of the innermost one of the interconnection metal layers 6 of its frontside interconnection scheme 20, followed by forming, using one or more processes of physical vapor deposition (PVD), chemical vapor deposition (CVD) and/or atomic layer deposition (ALD), an electroplating seed layer 122, such as copper, on the adhesion metal layer 118, over the back surface of its insulating dielectric layer 112 and in each of the openings 112a and 112b, followed by electroplating a copper layer 124 on the electroplating seed layer 122, over the back surface of its insulating dielectric layer 112 and in each of the openings 112a and 112b, followed by removing, using one or more processes of chemical-mechanical-polishing (CMP) and/or reactive-ion etching (RIE), the adhesion metal layer 118, electroplating seed layer 122 and copper layer 124 over the back surface of its insulating dielectric layer 112 and each of the openings 112a to expose the back surface of its insulating dielectric layer 112, wherein the back surface of its insulating dielectric layer 112 may be coplanar with a back, i.e., top, surface of its interconnection metal layer 116, that is, a back, i.e., top, surface of the copper layer 124 thereof. Thereby, the interconnection metal layer 116 may include (1) the copper layer 124 having multiple first portions each in one of the openings 112a and multiple second portions each in one of the openings 112b, (2) the adhesion metal layer 118 having a first portion at a bottom and sidewall of each of the first portions of the copper layer 124 thereof, between each of the first portions of the copper layer 124 and the back surface of one of the first and second groups of its backside contacts 15 and in contact with said one of the first and second groups of its backside contacts 15 and a second portion at a bottom and sidewall of each of the second portions of the copper layer 124 thereof, between each of the second portions of the copper layer 124 and the back surface of the innermost one of the interconnection metal layers 6 of its frontside interconnection scheme 20 and in contact with the back surface of the innermost one of the interconnection metal layers 6 of its frontside interconnection scheme 20, and (3) the electroplating seed layer 122 between the copper layer 124 and adhesion metal layer 118 thereof. Alternatively, forming the electroplating seed layer 122 and electroplating the copper layer 124 may be replaced by forming, using one or more processes of physical vapor deposition (PVD), chemical vapor deposition (CVD) and/or atomic layer deposition (ALD), a tungsten layer (not shown) on the adhesion metal layer 118, over the back surface of its insulating dielectric layer 112 and in each of the openings 112a and 112b, followed by removing, using one or more processes of chemical-mechanical-polishing (CMP) and/or reactive-ion etching (RIE), the adhesion metal layer 118 and tungsten layer over the back surface of its insulating dielectric layer 112 and each of the openings 112a to expose the back surface of its insulating dielectric layer 112, wherein the back surface of its insulating dielectric layer 112 may be coplanar with a back, i.e., top, surface of its interconnection metal layer 116, that is, a back, i.e., top, surface of the tungsten layer thereof. Thereby, the interconnection metal layer 116 may include (1) the tungsten layer having multiple first portions each in one of the openings 112a and multiple second portions each in one of the openings 112b, and (2) the adhesion metal layer 118 having a first portion at a bottom and sidewall of each of the first portions of the tungsten layer thereof, between each of the first portions of the tungsten layer and the back surface of one of the first and second groups of its backside contacts 15 and in contact with said one of the first and second groups of its backside contacts 15 and a second portion at a bottom and sidewall of each of the second portions of the tungsten layer thereof, between each of the second portions of the tungsten layer and the back surface of the innermost one of the interconnection metal layers 6 of its frontside interconnection scheme 20 and in contact with the back surface of the innermost one of the interconnection metal layers 6 of its frontside interconnection scheme 20. Its interconnection metal layer 116 in the openings 112b may be formed as multiple through insulator vias (TIVs) 116a each having a horizontal dimension less than or equal to 0.5 or 0.1 micrometers. A ratio of a distance d1, which is from a sidewall of one of its through insulator vias (TIVs) 116a to one of its transistors 4 adjacent to said one of its through insulator vias (TIVs) 116a, to the horizontal dimension of said one of its through insulator vias (TIVs) 116a may be greater than or equal to 0.5, 1 or 2. The distance d1 may be greater than a thickness of a lining insulating layer of a conventional through silicon via (TSV). The distance d1 may be greater than or equal to a half of the horizontal dimension of said one of its through insulator vias (TIVs) 116a. For this embodiment, neither silicon substrate or layer nor epitaxial silicon crystal may be provided vertically over and under its layer 3a of field oxide.

Next, referring to FIG. 1I, the semiconductor integrated-circuit (IC) wafer 100 may be further formed with a backside interconnection scheme 30 on the back surface of its insulating dielectric layer 112 and the back surface of its interconnection metal layer 116. For the semiconductor integrated-circuit (IC) wafer 100, its backside interconnection scheme 30 may include one or more interconnection metal layers 6 coupling to its interconnection metal layer 116 and one or more insulating dielectric layers 12 each covering a sidewall of one of the interconnection metal layers 6 thereof, between neighboring two of the interconnection metal layers 6 thereof, between the innermost one of the interconnection metal layers 6 thereof and its interconnection metal layer 116 or over the outermost one of the interconnection metal layers 6 thereof. Each of the interconnection metal layers 6 of its backside interconnection scheme 30 may have the same specification as that of one of the interconnection metal layers 6 of its frontside interconnection scheme 20 as illustrated in FIG. 1A; each of the insulating dielectric layers 12 of its backside interconnection scheme 30 may have the same specification as that of one of the insulating dielectric layers 12 of its frontside interconnection scheme 20 as illustrated in FIG. 1A. Further, its backside interconnection scheme 30 may include multiple plug contacts 56 each in an opening in the outermost one of the insulating dielectric layers 12 thereof and in contact with a back, i.e., top, surface of the outermost one of the interconnection metal layers 6 thereof. Each of the plug contacts 56 of its backside interconnection scheme 30 may include (1) a copper layer 24 having a vertical thickness between 3 and 500 nanometers in one of the openings in the outermost one of the insulating dielectric layers 12 of its backside interconnection scheme 30, (2) an adhesion metal layer 18, such as titanium or titanium nitride having a thickness of between 1 nm and 50 nm, at a bottom and sidewall of the copper layer 24 thereof, between the copper layer 24 thereof and the back surface of the outermost one of the interconnection metal layers 6 of its backside interconnection scheme 30 and in contact with the back surface of the outermost one of the interconnection metal layers 6 of its backside interconnection scheme 30, and (3) an electroplating seed layer 22, such as copper, between the copper layer 24 and adhesion metal layer 18 thereof, wherein the copper layer 24 thereof may have a back, i.e., top, surface coplanar with a back, i.e., top, surface of the outermost one of the insulating dielectric layers 12 of its backside interconnection scheme 30. Alternatively, the electroplating seed layer 22 and copper layer 24 thereof may be replaced by a tungsten layer (not shown) for each of the plug contacts 56 of its backside interconnection scheme 30, wherein the adhesion metal layer 18, such as titanium or titanium nitride having a thickness of between 1 nm and 50 nm, may be provided at a bottom and sidewall of the tungsten layer thereof, between the tungsten layer thereof and the back surface of the outermost one of the interconnection metal layers 6 of its backside interconnection scheme 30, wherein the tungsten layer thereof may have a back, i.e., top, surface coplanar with the back surface of the outermost one of the insulating dielectric layers 12 of its backside interconnection scheme 30. Alternatively, each of the plug contacts 56 of its backside interconnection scheme 30 may be made of aluminum. Further, its backside interconnection scheme 30 may include an interconnection metal layer 16 formed, using processes of physical vapor deposition (PVD), photolithography and reactive-ion etching (RIE), on the back surface of the outermost one of the insulating dielectric layers 12 of its backside interconnection scheme 30 and a back surface of each of the plug contacts 56 of its backside interconnection scheme 30, i.e., the back surface of the copper layer 24 thereof, wherein the interconnection metal layer 16 of its backside interconnection scheme 30 may include (1) an aluminum layer 16a having a vertical thickness between 0.8 and 3 micrometers and (2) an adhesion metal layer 16b, such as titanium or titanium nitride having a thickness between 10 nm and 100 nm, at a bottom of the aluminum layer 16a thereof but not at any sidewall of the aluminum layer 16a thereof, wherein the adhesion metal layer 16b thereof may be between the aluminum layer 16a thereof and the back surface of each of the plug contacts 56 of its backside interconnection scheme 30, between the aluminum layer 16a thereof and the back surface of the outermost one of the insulating dielectric layers 12 of its backside interconnection scheme 30 and in contact with the back surface of each of the plug contacts 56 of its backside interconnection scheme 30 and the back surface of the outermost one of the insulating dielectric layers 12 of its backside interconnection scheme 30. Further, its backside interconnection scheme 30 may include a passivation layer 54, i.e., insulating dielectric layer, on a back, i.e., top, surface and sidewall of the interconnection metal layer 16 of its backside interconnection scheme 30, i.e., a back, i.e., top, surface and sidewall of the aluminum layer 16a thereof, and the back surface of the outermost one of the insulating dielectric layers 12 of its backside interconnection scheme 30, wherein the passivation layer 54 of its backside interconnection scheme 30 may be made of a layer of silicon oxide and a layer of silicon nitride or oxynitride on the layer of silicon oxide thereof and may have a thickness between 1 and 2 micrometers. Two openings 54a and 54b may be formed in the passivation layer 54 of its backside interconnection scheme 30 and over each terminal of the interconnection metal layer 16 of its backside interconnection scheme 30 to expose the back surface of the interconnection metal layer 16 of its backside interconnection scheme 30, i.e., the back surface of the aluminum layer 16a thereof, for a metal pad 16c for a chip probe (CP) test and/or for a metal pad 16d for external bonding connection respectively. Each of the openings 54a in the passivation layer 54 may have a horizontal dimension between 30 and 80 micrometers; each of the openings 54b in the passivation layer 54 may have a horizontal dimension between 30 and 80 micrometers.

Referring to FIG. 1J, for a first alternative for the semiconductor integrated-circuit (IC) wafer 100, after a chip probe (CP) test is performed, its backside interconnection scheme 30 may be further formed with a polymer layer 17, i.e., insulating dielectric layer, on a back, i.e., top, surface of the passivation layer 54 of its backside interconnection scheme 30 and the back surface of each of the metal pads 16c of its backside interconnection scheme 30 and completely covering the back surface of each of the metal pads 16c of its backside interconnection scheme 30, wherein the polymer layer 17 of its backside interconnection scheme 30 may be made of polyimide having a vertical thickness between 3 and 10 micrometers. Multiple openings may be formed each in the polymer layer 17 of its backside interconnection scheme 30 to expose the back surface of one of the metal pads 16d of its backside interconnection scheme 30, wherein the polymer layer 17 of its backside interconnection scheme 30 may be further formed in each of the openings 54b in the passivation layer 54 of its backside interconnection scheme 30 and on the back surface of each of the metal pads 16d of its backside interconnection scheme 30 at a bottom of said each of the openings 54b. Next, the semiconductor integrated-circuit (IC) wafer 100 may be further formed with multiple micro-bumps, micro-pillars or micro-pads 34 each on the back surface of one of the metal pads 16d of its backside interconnection scheme 30 and a back, i.e., top, surface of the polymer layer 17 of its backside interconnection scheme 30. Each of its micro-bumps, micro-pillars or micro-pads 34 may be of one type of various types, i.e., first and second types. Its first type of micro-bump, micro-pillar or micro-pad 34 may include (1) an electroplated copper layer 32 having a vertical thickness between 8 and 60 micrometers or between 10 and 50 micrometers, (2) an adhesion metal layer 26a, such as titanium (Ti) or titanium nitride (TiN) layer, having a thickness between 1 and 50 nanometers at a bottom of the electroplated copper layer 32 thereof but not at any sidewall of the electroplated copper layer 32 thereof over the back surface of the polymer layer 17 of its backside interconnection scheme 30, wherein the adhesion metal layer 26a thereof is between the electroplated copper layer 32 thereof and a profile surface composed of the back surface of one of the metal pads 16d of its backside interconnection scheme 30, a sidewall of one of the openings in the polymer layer 17 of its backside interconnection scheme 30 and the back surface of the polymer layer 17 of its backside interconnection scheme 30 and in contact with the profile surface, and (3) an electroplating seed layer 26b between the electroplated copper layer 32 and adhesion metal layer 26a thereof. Alternatively, its second type of micro-bump, micro-pillar or micro-pad 34 may include the adhesion metal layer 26a, electroplating seed layer 26b and electroplated copper layer 32 as mentioned for its first type of micro-bump, micro-pillar or micro-pad 34, and may further include a tin-containing solder cap 33, such as tin or a tin-silver alloy, having a vertical thickness between 1 and 50 micrometers or between 20 and 100 micrometers on a back, i.e., top, surface of the electroplated copper layer 32 thereof.

Referring to FIG. 1K, for a second alternative for the semiconductor integrated-circuit (IC) wafer 100, after a chip probe (CP) test is performed, its backside interconnection scheme 30 may be further formed with the polymer layer 17 having the same specification as illustrated in FIG. 1J. Next, the semiconductor integrated-circuit (IC) wafer 100 may be further formed with the first type of micro-bumps, micro-pillars or micro-pads 34 having the same specification as illustrated in FIG. 1J and a polymer layer 257, i.e., insulating dielectric layer, on the back surface of the polymer layer 17 of its backside interconnection scheme 30 and in contact with the sidewall of the electroplated copper layer 32 of each of its first type of micro-bumps, micro-pillars or micro-pads 34, wherein its polymer layer 257 may be made of polyimide and have a back, i.e., top, surface coplanar with a back, i.e., top, surface of each of its first type of micro-bumps, micro-pillars or micro-pads 34, i.e., a back, i.e., top, surface of the electroplated copper layer 32 thereof.

Referring to FIG. 1L, for a third alternative for the semiconductor integrated-circuit (IC) wafer 100, in the beginning multiple openings 54a may be formed each in the passivation layer 54 and over one of the terminals of the interconnection metal layer 16 of its backside interconnection scheme 30 to expose a back, i.e., top, surface of the interconnection metal layer 16 of its backside interconnection scheme 30, i.e., a back, i.e., top, surface of the aluminum layer 16a thereof, for a metal pad 16c for a chip probe (CP) test. After a chip probe (CP) test is performed, its backside interconnection scheme 30 may be further formed with an insulating dielectric layer 19 on a back, i.e., top, surface of the passivation layer 54 of its backside interconnection scheme 30 and the back surface of each of the metal pads 16c of its backside interconnection scheme 30 and completely covering the back surface of each of the metal pads 16c of its backside interconnection scheme 30, wherein the insulating dielectric layer 19 of its backside interconnection scheme 30 may be made of a layer of silicon oxide and a layer of silicon nitride or oxynitride on the layer of silicon oxide thereof and may have a vertical thickness between 1 and 2 micrometers. Next, its backside interconnection scheme 30 may be further formed with an insulating bonding layer 29 on a back, i.e., top, surface of the insulating dielectric layer 19 of its backside interconnection scheme 30, wherein the insulating bonding layer 29 of its backside interconnection scheme 30 may (1) for a first case, be made of silicon oxide, or (2) for a second case, be made of silicon oxynitride or include a layer of silicon oxide on the back surface of the insulating dielectric layer 19 of its backside interconnection scheme 30 and a layer of silicon oxynitride on a back, i.e., top, surface of the layer of silicon oxide thereof, wherein the insulating bonding layer 29 of its backside interconnection scheme 30 may have a vertical thickness between 0.5 and 5 micrometers or between 1 and 3 micrometers. Next, multiple first openings 31a may be each formed in the insulating bonding layer 29, insulating dielectric layer 19 and passivation layer 54 of its backside interconnection scheme 30 to expose the back surface of the interconnection metal layer 16 of its backside interconnection scheme 30, i.e., the back surface of the aluminum layer 16a thereof, for a metal pad 16d for external bonding connection, wherein each of the first openings 31a in the insulating bonding layer 29 of its backside interconnection scheme 30 may have a horizontal dimension greater than that of said each of the first openings 31a in the insulating dielectric layer 19 and passivation layer 54 of its backside interconnection scheme 30 and expose the back surface of the insulating dielectric layer 19 of its backside interconnection scheme 30; multiple second openings 31b may be each formed in the insulating bonding layer 29, insulating dielectric layer 19 and passivation layer 54 of its backside interconnection scheme 30 and the outermost one of the insulating dielectric layers 12 of its backside interconnection scheme 30 to expose the back surface of the outermost one of the interconnection metal layers 6 of its backside interconnection scheme 30, i.e., the back surface of the electroplated copper layer 24 thereof, for a metal pad 6a for external bonding connection, wherein each of the second openings 31b in the insulating bonding layer 29 of its backside interconnection scheme 30 may have a horizontal dimension greater than that of said each of the second openings 31b in the insulating dielectric layer 19 and passivation layer 54 of its backside interconnection scheme 30 and the outermost one of the insulating dielectric layers 12 of its backside interconnection scheme 30 and expose the back surface of the insulating dielectric layer 19 of its backside interconnection scheme 30. Next, its backside interconnection scheme 30 may be further formed with (1) multiple first bonding pads 33a each in one of the first openings 31a and in contact with the back surface of one of the metal pads 16d of the interconnection metal layer 16 of its backside interconnection scheme 30, i.e., the back surface of the aluminum layer 16a thereof, and (2) multiple second bonding pads 33b each in one of the second openings 31b and in contact with the back surface of one of the metal pads 6a of the outermost one of the interconnection metal layers 6 of its backside interconnection scheme 30, i.e., the back surface of the electroplated copper layer 24 thereof. Each of the first bonding pads 33a of its backside interconnection scheme 30 may include (1) a copper layer 24 in one of the first openings 31a, (2) an adhesion metal layer 18, such as titanium or titanium nitride having a thickness of between 1 nm and 50 nm, at a bottom and sidewall of the copper layer 24 thereof, between the copper layer 24 thereof and the back surface of one of the metal pads 16d of the interconnection metal layer 16 of its backside interconnection scheme 30 and in contact with the back surface of one of the metal pads 16d of the interconnection metal layer 16 of its backside interconnection scheme 30, i.e., the back surface of the aluminum layer 16a thereof, and (3) an electroplating seed layer 22, such as copper, between the copper layer 24 and adhesion metal layer 18 thereof, wherein the copper layer 24 thereof may have a back, i.e., top, surface coplanar with a back, i.e., top, surface of the insulating bonding layer 29 of its backside interconnection scheme 30 and wherein the copper layer 24 thereof in said one of the first openings 31a in the insulating bonding layer 29 of its backside interconnection scheme 30 may have a vertical thickness between 0.5 and 5 micrometers or between 1 and 3 micrometers and a horizontal dimension between 1 and 5 micrometers. Each of the first bonding pads 33a of its backside interconnection scheme 30 may include (1) a copper layer 24 in one of the first openings 31a, (2) an adhesion metal layer 18, such as titanium or titanium nitride having a thickness of between 1 nm and 50 nm, at a bottom and sidewall of the copper layer 24 thereof, between the copper layer 24 thereof and the back surface of one of the metal pads 16d of the interconnection metal layer 16 of its backside interconnection scheme 30 and in contact with the back surface of said one of the metal pads 16d of the interconnection metal layer 16 of its backside interconnection scheme 30, i.e., the back surface of the aluminum layer 16a thereof, and (3) an electroplating seed layer 22, such as copper, between the copper layer 24 and adhesion metal layer 18 thereof, wherein the copper layer 24 thereof may have a back, i.e., top, surface coplanar with a back, i.e., top, surface of the insulating bonding layer 29 of its backside interconnection scheme 30 and wherein the copper layer 24 thereof in said one of the first openings 31a in the insulating bonding layer 29 of its backside interconnection scheme 30 may have a vertical thickness between 0.5 and 5 micrometers or between 1 and 3 micrometers and a horizontal dimension between 1 and 5 micrometers. Each of the second bonding pads 33b of its backside interconnection scheme 30 may include (1) a copper layer 24 in one of the second openings 31b, (2) an adhesion metal layer 18, such as titanium or titanium nitride having a thickness of between 1 nm and 50 nm, at a bottom and sidewall of the copper layer 24 thereof, between the copper layer 24 thereof and the back surface of one of the metal pads 6a of the outermost one of the interconnection metal layers 6 of its backside interconnection scheme 30 and in contact with the back surface of said one of the metal pads 6a of the outermost one of the interconnection metal layers 6 of its backside interconnection scheme 30, i.e., the back surface of the electroplated copper layer 24 thereof, and (3) an electroplating seed layer 22, such as copper, between the copper layer 24 and adhesion metal layer 18 thereof, wherein the copper layer 24 thereof may have a back, i.e., top, surface coplanar with the back surface of the insulating bonding layer 29 of its backside interconnection scheme 30 and wherein the copper layer 24 thereof in said one of the second openings 31b in the insulating bonding layer 29 of its backside interconnection scheme 30 may have a vertical thickness between 0.5 and 5 micrometers or between 1 and 3 micrometers and a horizontal dimension between 1 and 5 micrometers.

Next, for the first alternative, the semiconductor integrated-circuit (IC) wafer 100 and supporting substrate 591 may be cut or diced into multiple first type of semiconductor integrated-circuit (IC) chips 10 as seen in FIG. 1J; for the second alternative, the semiconductor integrated-circuit (IC) wafer 100 and supporting substrate 591 may be cut or diced into multiple second type of semiconductor integrated-circuit (IC) chips 10 as seen in FIG. 1K; for the third alternative, the semiconductor integrated-circuit (IC) wafer 100 and supporting substrate 591 may be cut or diced into multiple third type of semiconductor integrated-circuit (IC) chips 10 as seen in FIG. 1L. Thereby, referring to FIGS. 1J-1L, for any type of the first, second and third types of semiconductor integrated-circuit (IC) chip 10, a first one of its transistors 4 may have the source or drain 4b or 4c coupling to either of the source and drain 4b and 4c of a second one of its transistors 4 through, in sequence, a first one of the first group of the frontside contacts 5 of its frontside interconnection scheme 20, one or more of the interconnection metal layers 6 of its frontside interconnection scheme 20 and a second one of the first group of the frontside contacts 5 of its frontside interconnection scheme 20 for delivery of power supply or ground reference or for signal transmission. A third one of its transistors 4 may have the source or drain 4b or 4c coupling to the metal gate 42 of a fourth one of its transistors 4 through, in sequence, a third one of the first group of the frontside contacts 5 of its frontside interconnection scheme 20, one or more of the interconnection metal layers 6 of its frontside interconnection scheme 20 and a first one of the second group of the frontside contacts 5 of its frontside interconnection scheme 20 for delivery of power supply or ground reference or for signal transmission. A fifth one of its transistors 4 may have the metal gate 42 coupling to either of the source and drain 4b and 4c of a sixth one of its transistors 4 through, in sequence, a second one of the second group of the frontside contacts 5 of its frontside interconnection scheme 20, one or more of the interconnection metal layers 6 of its frontside interconnection scheme 20 and a fourth one of the first group of the frontside contacts 5 of its frontside interconnection scheme 20 for delivery of power supply or ground reference or for signal transmission. A seventh one of its transistors 4 may have the metal gate 42 coupling to the metal gate 42 of an eighth one of its transistors 4 through, in sequence, a third one of the second group of the frontside contacts 5 of its frontside interconnection scheme 20, one or more of the interconnection metal layers 6 of its frontside interconnection scheme 20 and a fourth one of the second group of the frontside contacts 5 of its frontside interconnection scheme 20 for delivery of power supply or ground reference or for signal transmission. A ninth one of its transistors 4 may have the source or drain 4b or 4c coupling to either of the source and drain 4b and 4c of a tenth one of its transistors 4 through, in sequence, a first one of the first group of its backside contacts 15, its interconnection metal layer 116, optionally one or more of the interconnection metal layers 6 of its backside interconnection scheme 30, and a second one of the first group of its backside contacts 15 for delivery of power supply or ground reference or for signal transmission. A eleventh one of its transistors 4 may have the source or drain 4b or 4c coupling to the metal gate 42 of a twelfth one of its transistors 4 through, in sequence, a third one of the first group of its backside contacts 15, its interconnection metal layer 116, optionally one or more of the interconnection metal layers 6 of its backside interconnection scheme 30, and a first one of the second group of its backside contacts 15 for delivery of power supply or ground reference or for signal transmission. A thirteenth one of its transistors 4 may have the metal gate 42 coupling to either of the source and drain 4b and 4c of a fourteenth one of its transistors 4 through, in sequence, a second one of the second group of its backside contacts 15, its interconnection metal layer 116, optionally one or more of the interconnection metal layers 6 of its backside interconnection scheme 30, and a fourth one of the first group of its backside contacts 15 for delivery of power supply or ground reference or for signal transmission. A fifteenth one of its transistors 4 may have the metal gate 42 coupling to the metal gate 42 of a sixteenth one of its transistors 4 through, in sequence, a third one of the second group of its backside contacts 15, its interconnection metal layer 116, optionally one or more of the interconnection metal layers 6 of its backside interconnection scheme 30, and a fourth one of the second group of its backside contacts 15 for delivery of power supply or ground reference or for signal transmission. A seventeenth one of its transistors 4 may have the source or drain 4b or 4c coupling to either of the source and drain 4b and 4c of an eighteenth one of its transistors 4 through, in sequence, a fifth one of the first group of the frontside contacts 5 of its frontside interconnection scheme 20, one or more of the interconnection metal layers 6 of its frontside interconnection scheme 20, its interconnection metal layer 116, i.e., a first one of its through insulator vias (TIVs) 116a, optionally one or more of the interconnection metal layers 6 of its backside interconnection scheme 30, and a fifth one of the first group of its backside contacts 15 for delivery of power supply or ground reference or for signal transmission. A nineteenth one of its transistors 4 may have the source or drain 4b or 4c coupling to the metal gate 42 of a twentieth one of its transistors 4 through, in sequence, a sixth one of the first group of the frontside contacts 5 of its frontside interconnection scheme 20, one or more of the interconnection metal layers 6 of its frontside interconnection scheme 20, its interconnection metal layer 116, i.e., a second one of its through insulator vias (TIVs) 116a, optionally one or more of the interconnection metal layers 6 of its backside interconnection scheme 30, and a fifth one of the second group of its backside contacts 15 for delivery of power supply or ground reference or for signal transmission. A twenty-first one of its transistors 4 may have the metal gate 42 coupling to either of the source and drain 4b and 4c of a twenty-second one of its transistors 4 through, in sequence, a fifth one of the second group of the frontside contacts 5 of its frontside interconnection scheme 20, one or more of the interconnection metal layers 6 of its frontside interconnection scheme 20, its interconnection metal layer 116, i.e., a third one of its through insulator vias (TIVs) 116a, optionally one or more of the interconnection metal layers 6 of its backside interconnection scheme 30, and a sixth one of the first group of its backside contacts 15 for delivery of power supply or ground reference or for signal transmission. A twenty-third one of its transistors 4 may have the metal gate 42 coupling to the metal gate 42 of a twenty-fourth one of its transistors 4 through, in sequence, a sixth one of the second group of the frontside contacts 5 of its frontside interconnection scheme 20, one or more of the interconnection metal layers 6 of its frontside interconnection scheme 20, its interconnection metal layer 116, i.e., a fourth one of its through insulator vias (TIVs) 116a, optionally one or more of the interconnection metal layers 6 of its backside interconnection scheme 30, and a sixth one of the second group of its backside contacts 15 for delivery of power supply or ground reference or for signal transmission.

Referring to FIGS. 1J and 1K, for either type of the first and second types of semiconductor integrated-circuit (IC) chips 10, a first one of its micro-bumps, micro-pillars or micro-pads 34 may couple to either of the source and drain 4b and 4c of a twenty-fifth one of its transistors 4 through, in sequence, the interconnection metal layer 16 of its backside interconnection scheme 30, a first one of the plug contacts 56 of its backside interconnection scheme 30, each of the interconnection metal layers 6 of its backside interconnection scheme 30, its interconnection metal layer 116 and a seventh one of the first group of its backside contacts 15 for delivery of power supply or ground reference or for signal transmission. A second one of its micro-bumps, micro-pillars or micro-pads 34 may couple to the metal gate 42 of a twenty-sixth one of its transistors 4 through, in sequence, the interconnection metal layer 16 of its backside interconnection scheme 30, a second one of the plug contacts 56 of its backside interconnection scheme 30, each of the interconnection metal layers 6 of its backside interconnection scheme 30, its interconnection metal layer 116 and a seventh one of the second group of its backside contacts 15 for delivery of power supply or ground reference or for signal transmission. A third one of its micro-bumps, micro-pillars or micro-pads 34 may couple to either of the source and drain 4b and 4c of a twenty-seventh one of its transistors 4 through, in sequence, the interconnection metal layer 16 of its backside interconnection scheme 30, a third one of the plug contacts 56 of its backside interconnection scheme 30, each of the interconnection metal layers 6 of its backside interconnection scheme 30, its interconnection metal layer 116, i.e., a fifth one of its through insulator vias (TIVs) 116a, one or more of the interconnection metal layers 6 of its frontside interconnection scheme 20 and a seventh one of the first group of the frontside contacts 5 of its frontside interconnection scheme 20 for delivery of power supply or ground reference or for signal transmission. A fourth one of its micro-bumps, micro-pillars or micro-pads 34 may couple to the metal gate 42 of a twenty-eighth one of its transistors 4 through, in sequence, the interconnection metal layer 16 of its backside interconnection scheme 30, a fourth one of the plug contacts 56 of its backside interconnection scheme 30, each of the interconnection metal layers 6 of its backside interconnection scheme 30, its interconnection metal layer 116, i.e., a sixth one of its through insulator vias (TIVs) 116a, one or more of the interconnection metal layers 6 of its frontside interconnection scheme 20 and a seventh one of the second group of the frontside contacts 5 of its frontside interconnection scheme 20 for delivery of power supply or ground reference or for signal transmission.

Referring to FIG. 1L, for the third type of semiconductor integrated-circuit (IC) chip 10, a first one of its first bonding pads 33a may couple to either of the source and drain 4b and 4c of a twenty-fifth one of its transistors 4 through, in sequence, the interconnection metal layer 16 of its backside interconnection scheme 30, a first one of the plug contacts 56 of its backside interconnection scheme 30, each of the interconnection metal layers 6 of its backside interconnection scheme 30, its interconnection metal layer 116 and a seventh one of the first group of its backside contacts 15 for delivery of power supply or ground reference or for signal transmission. A second one of its first bonding pads 33a may couple to the metal gate 42 of a twenty-sixth one of its transistors 4 through, in sequence, the interconnection metal layer 16 of its backside interconnection scheme 30, a second one of the plug contacts 56 of its backside interconnection scheme 30, each of the interconnection metal layers 6 of its backside interconnection scheme 30, its interconnection metal layer 116 and a seventh one of the second group of its backside contacts 15 for delivery of power supply or ground reference or for signal transmission. A third one of its first bonding pads 33a may couple to either of the source and drain 4b and 4c of a twenty-seventh one of its transistors 4 through, in sequence, the interconnection metal layer 16 of its backside interconnection scheme 30, a third one of the plug contacts 56 of its backside interconnection scheme 30, each of the interconnection metal layers 6 of its backside interconnection scheme 30, its interconnection metal layer 116, i.e., a fifth one of its through insulator vias (TIVs) 116a, one or more of the interconnection metal layers 6 of its frontside interconnection scheme 20 and a seventh one of the first group of the frontside contacts 5 of its frontside interconnection scheme 20 for delivery of power supply or ground reference or for signal transmission. A fourth one of its first bonding pads 33a may couple to the metal gate 42 of a twenty-eighth one of its transistors 4 through, in sequence, the interconnection metal layer 16 of its backside interconnection scheme 30, a fourth one of the plug contacts 56 of its backside interconnection scheme 30, each of the interconnection metal layers 6 of its backside interconnection scheme 30, its interconnection metal layer 116, i.e., a sixth one of its through insulator vias (TIVs) 116a, one or more of the interconnection metal layers 6 of its frontside interconnection scheme 20 and a seventh one of the second group of the frontside contacts 5 of its frontside interconnection scheme 20 for delivery of power supply or ground reference or for signal transmission. A first one of its second bonding pads 33b may couple to either of the source and drain 4b and 4c of a twenty-ninth one of its transistors 4 through, in sequence, each of the interconnection metal layers 6 of its backside interconnection scheme 30, its interconnection metal layer 116 and an eighth one of the first group of its backside contacts 15 for delivery of power supply or ground reference or for signal transmission. A second one of its second bonding pads 33b may couple to the metal gate 42 of a thirtieth one of its transistors 4 through, in sequence, each of the interconnection metal layers 6 of its backside interconnection scheme 30, its interconnection metal layer 116 and an eighth one of the second group of its backside contacts 15 for delivery of power supply or ground reference or for signal transmission. A third one of its second bonding pads 33b may couple to either of the source and drain 4b and 4c of a thirty-first one of its transistors 4 through, in sequence, each of the interconnection metal layers 6 of its backside interconnection scheme 30, its interconnection metal layer 116, i.e., a seventh one of its through insulator vias (TIVs) 116a, one or more of the interconnection metal layers 6 of its frontside interconnection scheme 20 and an eighth one of the first group of the frontside contacts 5 of its frontside interconnection scheme 20 for delivery of power supply or ground reference or for signal transmission. A fourth one of its second bonding pads 33b may couple to the metal gate 42 of a thirty-second one of its transistors 4 through, in sequence, each of the interconnection metal layers 6 of its backside interconnection scheme 30, its interconnection metal layer 116, i.e., an eighth one of its through insulator vias (TIVs) 116a, one or more of the interconnection metal layers 6 of its frontside interconnection scheme 20 and an eighth one of the second group of the frontside contacts 5 of its frontside interconnection scheme 20 for delivery of power supply or ground reference or for signal transmission.

### Process for Fabricating First Type of Gate-all-Around (GAA) Transistor

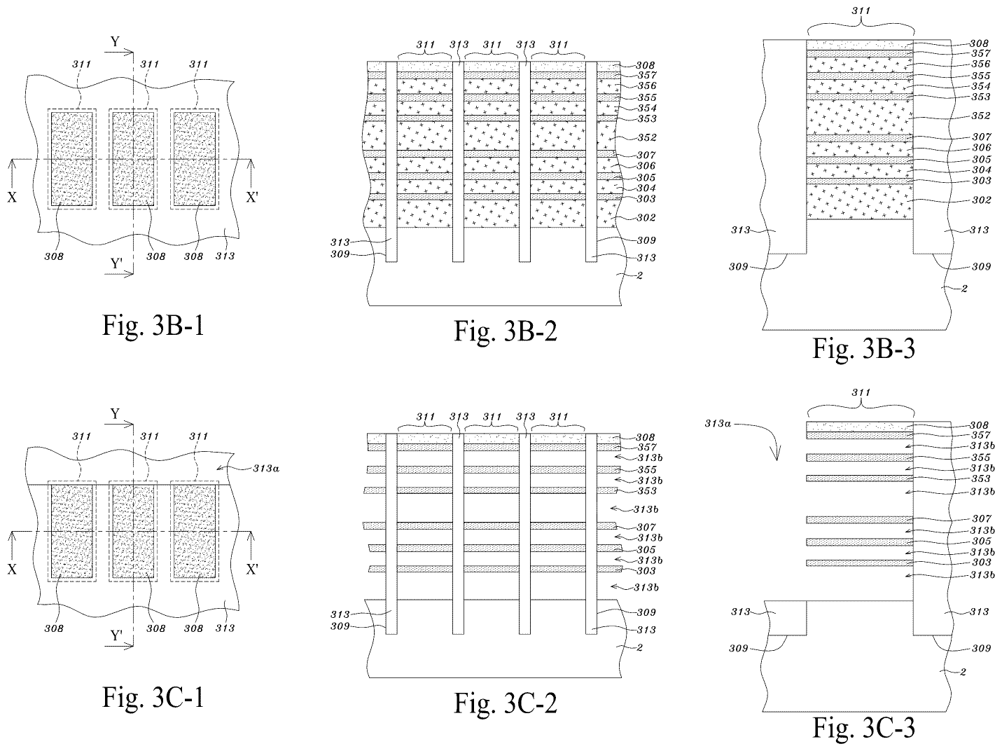

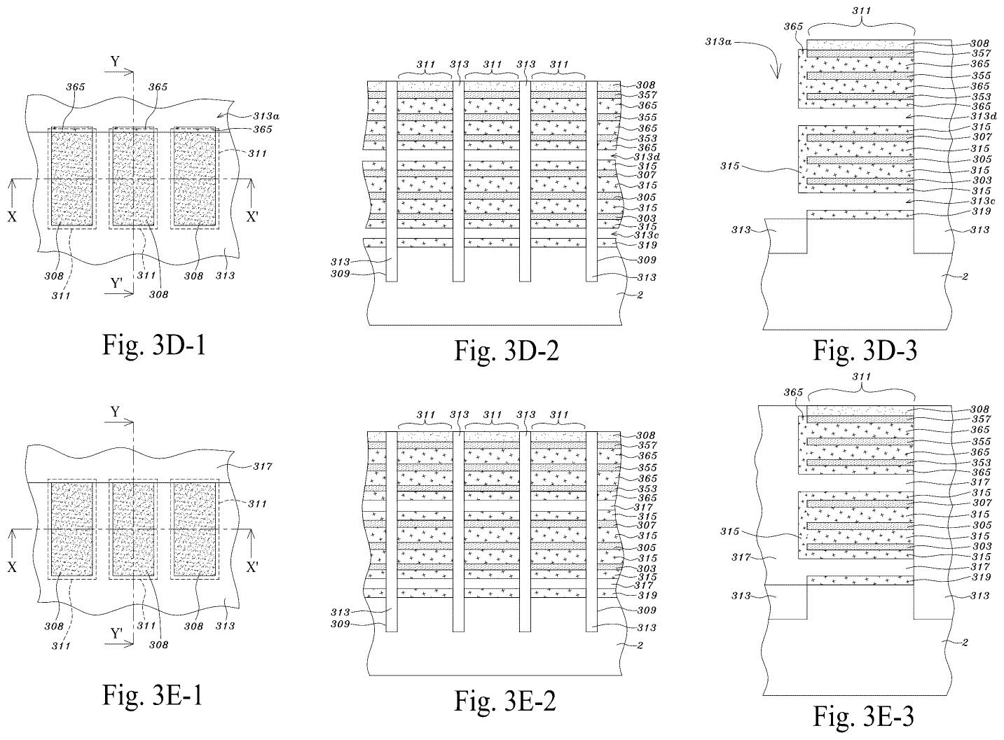

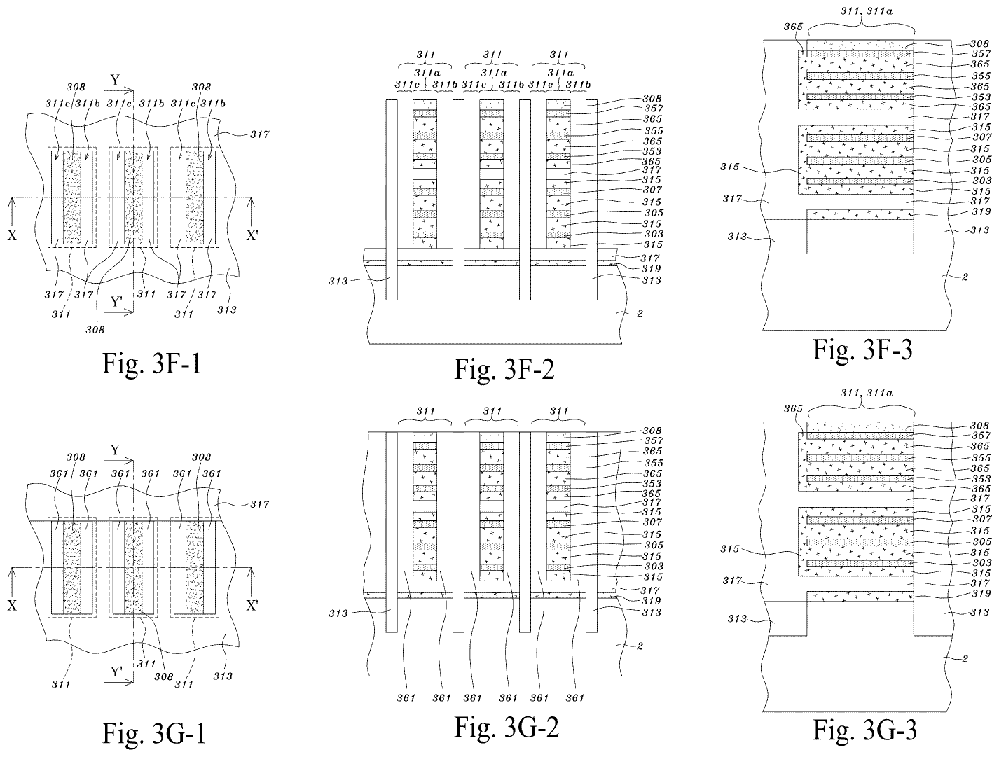

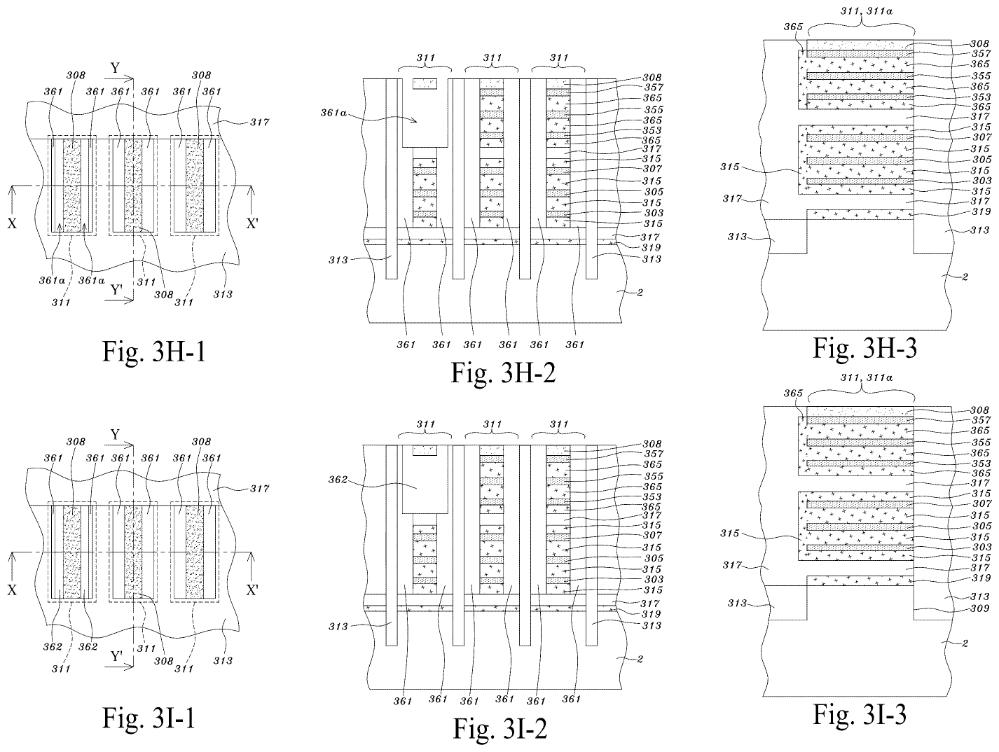

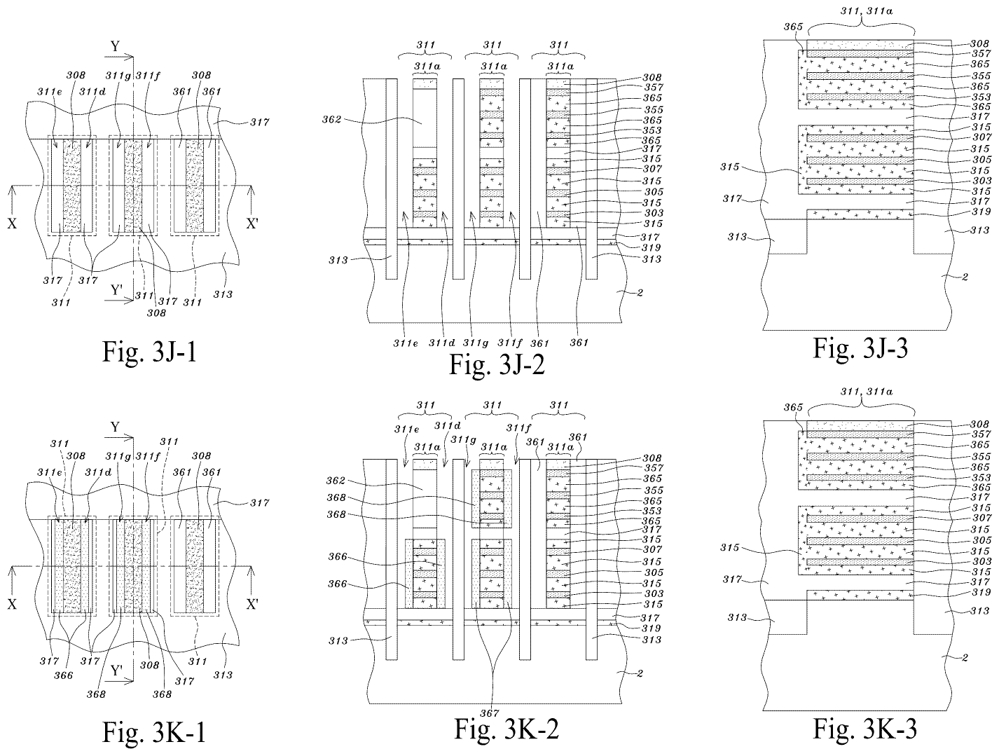

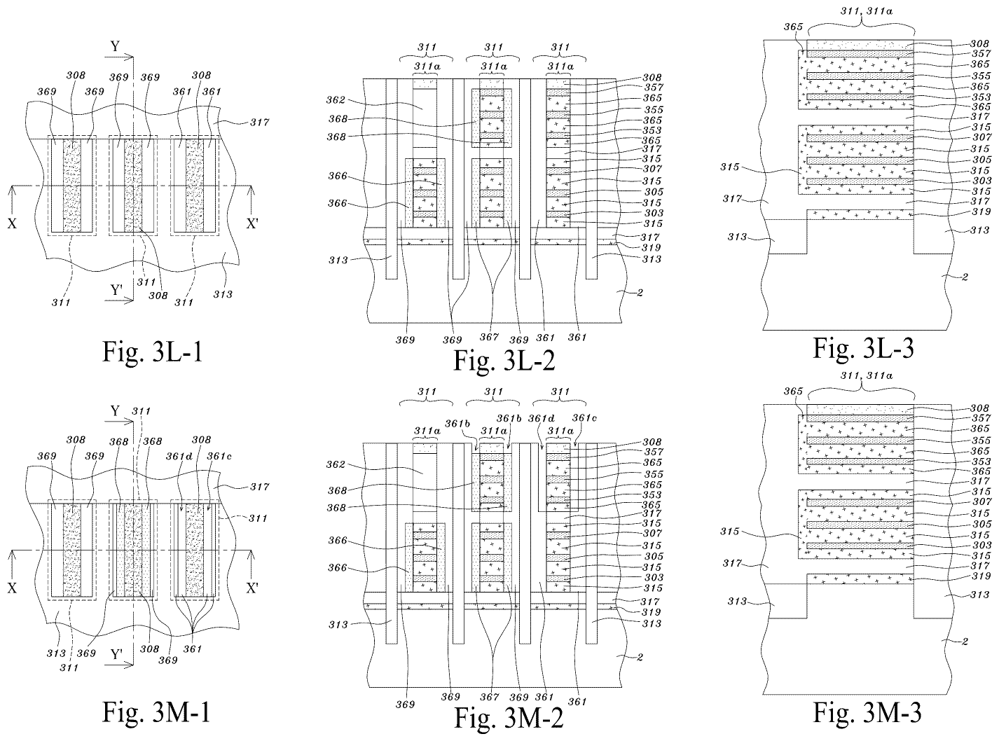

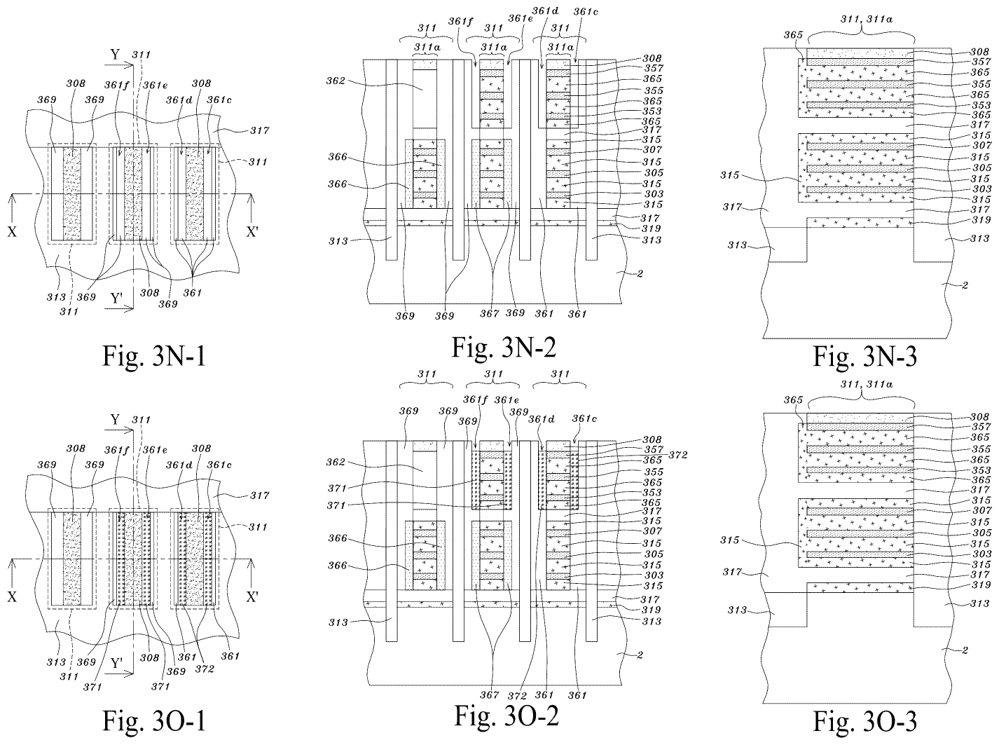

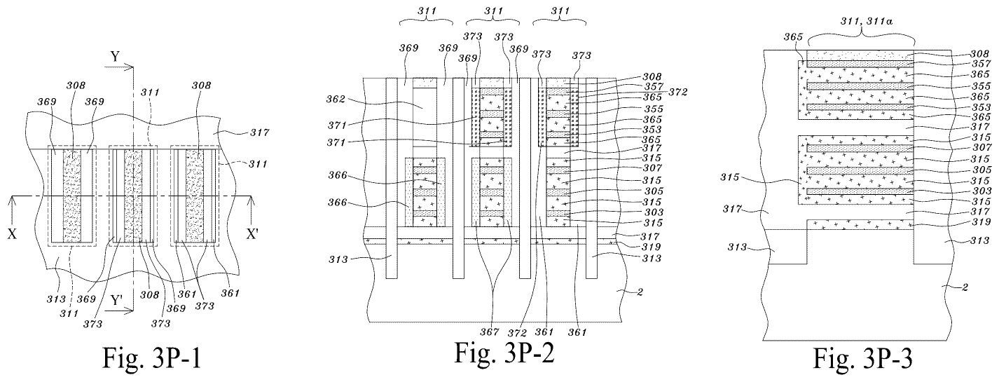

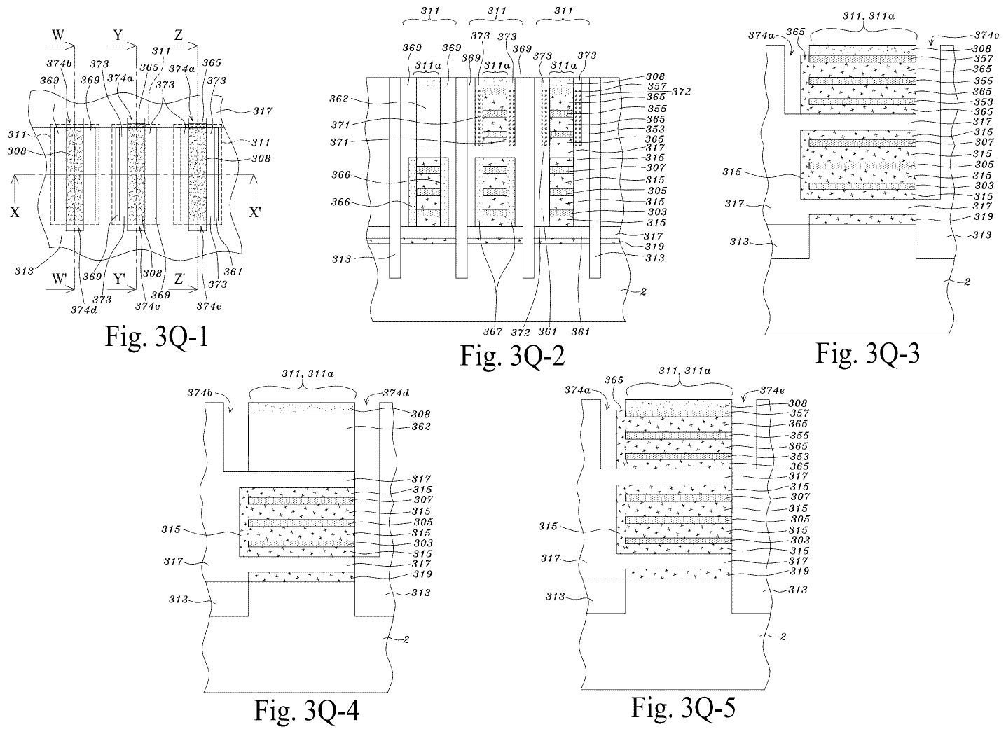

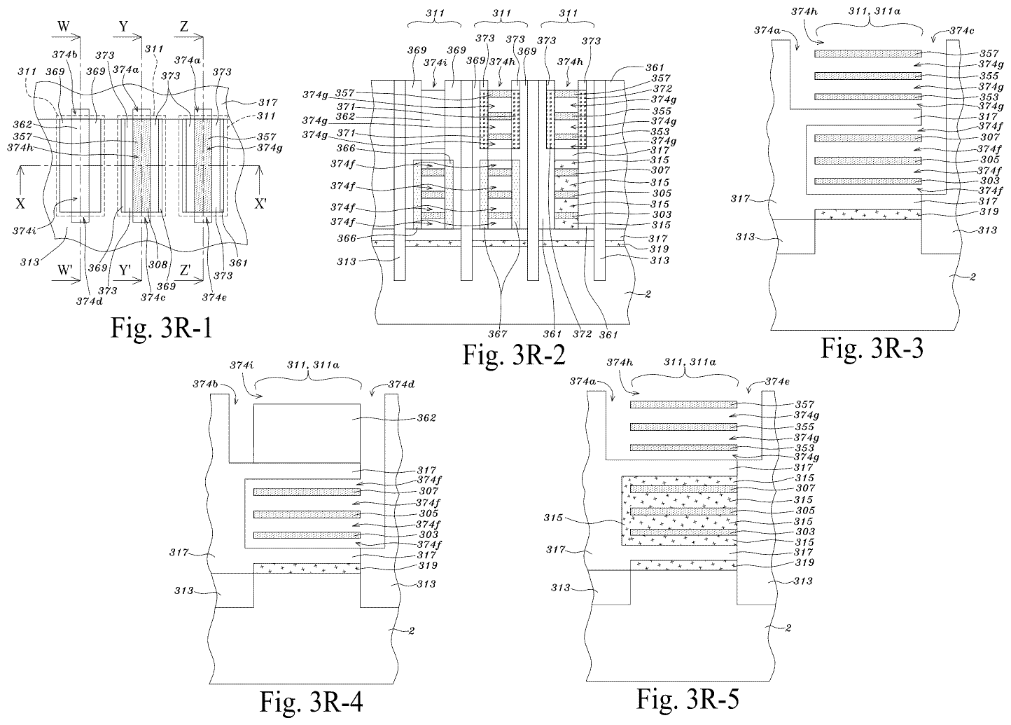

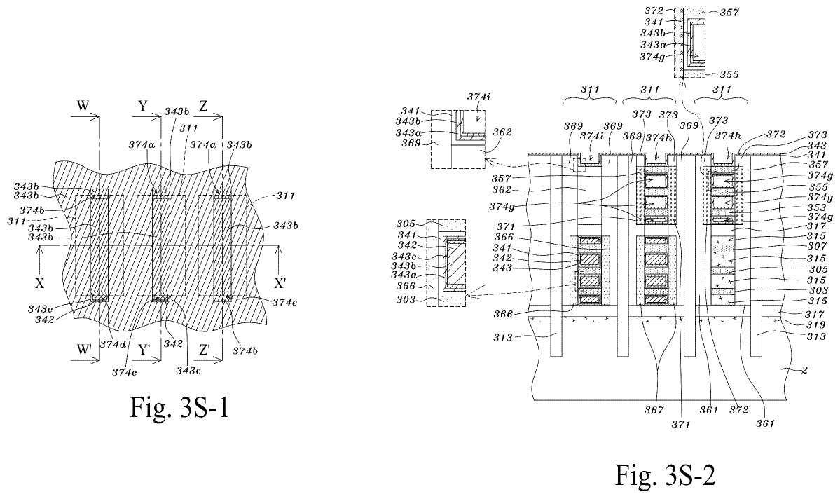

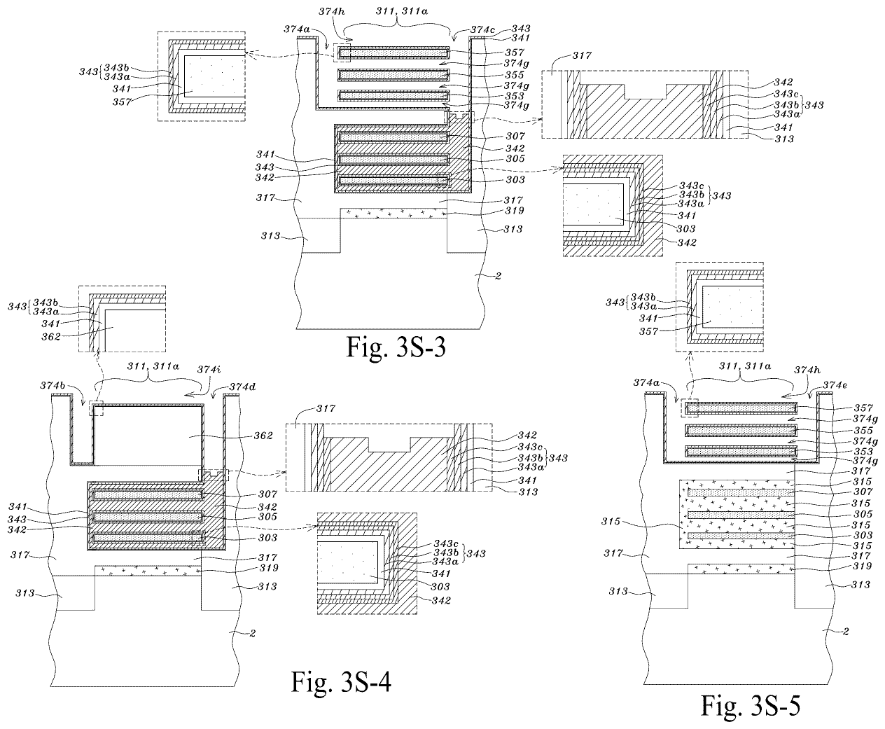

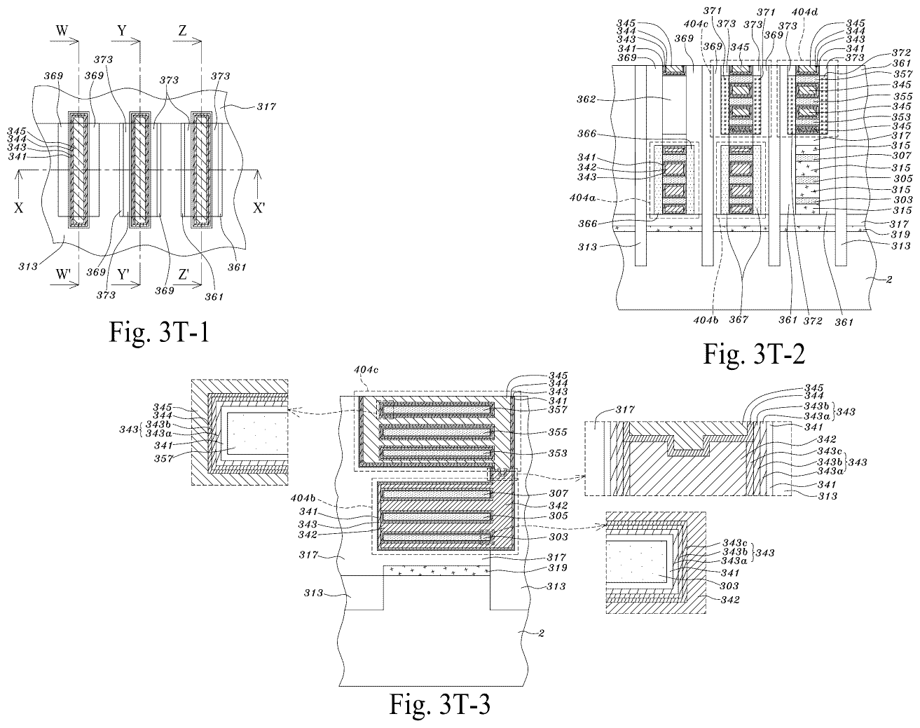

FIGS. 2A, 2B-2 through 2J-2 and 2B-3 through 2J-3 are schematically cross-sectional views showing a process for fabricating a first type of gate-all-around (GAA) transistor in accordance with an embodiment of the present application. FIGS. 2B-1 through 2J-1 are schematically top views showing a process for fabricating a first type of gate-all-around (GAA) transistor in accordance with an embodiment of the present application. Referring to FIG. 2A, a semiconductor substrate 2, such as a semiconductor wafer made of single crystal silicon, may be first provided. Next, an epitaxial layer 102 of silicon germanium (SiGe) having a vertical thickness between 0.05 and 0.5 micrometers or between 0.06 and 0.2 micrometers may be formed on a top surface of the semiconductor substrate 2. Next, an epitaxial layer 103 of silicon having a vertical thickness between 1 and 20 nanometers, between 2 and 20 nanometers, between 1 and 6 nanometers or between 4 and 10 nanometers may be formed on a top surface of the epitaxial layer 102 of silicon germanium (SiGe). Next, an epitaxial layer 104 of silicon germanium (SiGe) having a vertical thickness between 5 and 20 nanometers or between 6 and 10 nanometers may be formed on a top surface of the epitaxial layer 103 of silicon. Next, an epitaxial layer 105 of silicon having a vertical thickness between 1 and 20 nanometers, between 2 and 20 nanometers, between 1 and 6 nanometers or between 4 and 10 nanometers may be formed on a top surface of the epitaxial layer 104 of silicon germanium (SiGe). Next, an epitaxial layer 106 of silicon germanium (SiGe) having a vertical thickness between 5 and 20 nanometers or between 6 and 10 nanometers may be formed on a top surface of the epitaxial layer 105 of silicon. Next, an epitaxial layer 107 of silicon having a vertical thickness between 1 and 20 nanometers, between 2 and 20 nanometers, between 1 and 6 nanometers or between 4 and 10 nanometers may be formed on a top surface of the epitaxial layer 106 of silicon germanium (SiGe). Next, a layer 108 of hard mask may be formed on a top surface of the epitaxial layer 107 of silicon, wherein the layer 108 of hard mask may be made of silicon oxide, silicon oxynitride or a combination of silicon oxide and silicon oxynitride and have a vertical thickness between 10 and 150 nanometers or between 20 and 100 nanometers.

Next, referring to FIGS. 2B-1, 2B-2 and 2B-3, FIG. 2B-1 is a schematically top view showing a process for fabricating a first type of gate-all-around (GAA) transistor in accordance with an embodiment of the present application; FIG. 2B-2 is a schematically cross-sectional view cut along a cross-sectional line X-X′ of FIG. 2B-1; FIG. 2B-3 is a schematically cross-sectional view cut along a cross-sectional line Y-Y′ of FIG. 2B-1. An isolation trench 109 may be formed in the layer 108 of hard mask, the epitaxial layers 103, 105 and 107 of silicon, the epitaxial layers 102, 104 and 106 of silicon germanium (SiGe) and the semiconductor substrate 2 to define multiple transistor sites 111 on the semiconductor substrate 2 and separated by the isolation trench 109. The transistor sites 111 may be defined by first patterning the layer 108 of hard mask using processes of photolithography and reactive-ion etching (RIE), followed by etching the epitaxial layers 103, 105 and 107 of silicon, the epitaxial layers 102, 104 and 106 of silicon germanium (SiGe) and the semiconductor substrate 2 based on the pattern of the layer 108 of hard mask so as to form the isolation trench 109. Next, a layer 113 of field oxide may be deposited, by a process of chemical vapor deposition (CVD), on a top surface of the layer 108 of hard mask and in the isolation trench 109. Next, the layer 113 of field oxide over the top surface of the layer 108 of hard mask and the isolation trench 109 may be removed by a process of chemical mechanical polishing (CMP) to expose the top surface of the layer 108 of hard mask to be coplanar with a top surface of the layer 113 of field oxide left in the isolation trench 109.

Next, referring to FIGS. 2C-1, 2C-2 and 2C-3, FIG. 2C-1 is a schematically top view showing a process for fabricating a first type of gate-all-around (GAA) transistor in accordance with an embodiment of the present application: FIG. 2C-2 is a schematically cross-sectional view cut along a cross-sectional line X-X′ of FIG. 2C-1; FIG. 2C-3 is a schematically cross-sectional view cut along a cross-sectional line Y-Y′ of FIG. 2C-1. The layer 113 of field oxide in the isolation trench 109 at a sidewall of each of the transistor sites 111 may be removed using processes of photolithography and reactive-ion etching (RIE) to form an empty space 113a in the isolation trench 109 and at the side of each of the transistor sites 111 and to expose a sidewall of each of the epitaxial layers 103, 105 and 107 of silicon and a sidewall of each of the epitaxial layers 102, 104 and 106 of silicon germanium (SiGe), wherein the layer 113 of field oxide under the empty space 113a may be left in the semiconductor substrate 2. Next, the epitaxial layers 102, 104 and 106 of silicon germanium (SiGe) may be removed from the exposed sidewalls thereof by a process of isotropic selective etching, such as wet etching using a mixture of hydrogen peroxide (H₂O₂) and ammonium hydroxide (NH₄OH) as an etchant, to form an empty space 113b between neighboring two of the epitaxial layers 103, 105 and 107 of silicon and between the epitaxial layer 103 of silicon and the semiconductor substrate 2 and to expose a bottom and top surface of each of the epitaxial layers 103 and 105 of silicon, a bottom surface of the epitaxial layer 107 of silicon and a top surface of the semiconductor substrate 2, wherein the empty space 113a communicates with the empty spaces 113b.

Next, referring to FIGS. 2D-1, 2D-2 and 2D-3, FIG. 2D-1 is a schematically top view showing a process for fabricating a first type of gate-all-around (GAA) transistor in accordance with an embodiment of the present application; FIG. 2D-2 is a schematically cross-sectional view cut along a cross-sectional line X-X′ of FIG. 2D-1; FIG. 2D-3 is a schematically cross-sectional view cut along a cross-sectional line Y-Y′ of FIG. 2D-1. Using a selective epitaxial technology, a layer 115 of silicon germanium (SiGe) may be deposited with a thickness between 3 and 12 nanometers in the empty spaces 113a and 113b as seen in FIGS. 2C-1, 2C-2 and 2C-3, and on the exposed bottom and top surfaces of each of the epitaxial layers 103 and 105 of silicon, the exposed bottom surface of the epitaxial layer 107 of silicon and the exposed sidewall of each of the epitaxial layers 103, 105 and 107 of silicon, and a layer 119 of silicon germanium (SiGe) may be deposited with a thickness between 3 and 12 nanometers in the bottommost one of the empty spaces 113b and on the exposed top surface of the semiconductor substrate 2. The layer 115 of silicon germanium (SiGe) may be completely filled in the empty space 113b between the epitaxial layers 103 and 105 of silicon and the empty space 113b between the epitaxial layers 105 and 107 of silicon. The layers 115 and 119 of silicon germanium (SiGe) may not be completely filled in the empty space 113b between the epitaxial layer 103 of silicon and the semiconductor substrate 2, but an empty gap 113c may be formed with a vertical dimension between 0.01 and 0.5 micrometers or between 0.02 and 0.3 micrometers and between a bottom surface of the layer 115 of silicon germanium (SiGe) formed on the bottom surface of the epitaxial layer 103 of silicon and a top surface of the layer 119 of silicon germanium (SiGe) formed on the top surface of the semiconductor substrate 2.

Next, referring to FIGS. 2E-1, 2E-2 and 2E-3, FIG. 2E-1 is a schematically top view showing a process for fabricating a first type of gate-all-around (GAA) transistor in accordance with an embodiment of the present application; FIG. 2E-2 is a schematically cross-sectional view cut along a cross-sectional line X-X′ of FIG. 2E-1; FIG. 2E-3 is a schematically cross-sectional view cut along a cross-sectional line Y-Y′ of FIG. 2E-1. An insulating dielectric layer 117, i.e., silicon-on-insulator (SOI) dielectric layer may be formed, by a process of atomic layer deposition (ALD) or chemical vapor deposition (CVD), in the empty space 113a and empty gap 113c as seen in FIGS. 2D-1, 2D-2 and 2D-3, on a planar surface composed of the top surface of the layer 108 of hard mask and the top surface of the layer 113 of field oxide and on a top surface of the layer 113 of field oxide under the empty space 113a. The insulating dielectric layer 117 may be made of a layer of silicon oxide, silicon oxynitride or silicon nitride, multiple layers of silicon oxide and silicon oxynitride or multiple layers of silicon oxide and silicon nitride, wherein the insulating dielectric layer 117 in the empty gap 113c may have a vertical dimension between 0.01 and 0.5 micrometers or between 0.02 and 0.3 micrometers.

Next, referring to FIGS. 2F-1, 2F-2 and 2F-3, FIG. 2F-1 is a schematically top view showing a process for fabricating a first type of gate-all-around (GAA) transistor in accordance with an embodiment of the present application; FIG. 2F-2 is a schematically cross-sectional view cut along a cross-sectional line X-X′ of FIG. 2F-1; FIG. 2F-3 is a schematically cross-sectional view cut along a cross-sectional line Y-Y′ of FIG. 2F-1. The insulating dielectric layer 117 over the planar surface composed of the top surface of the layer 108 of hard mask and the top surface of the layer 113 of field oxide and the empty space 113a may be removed by a processes of chemical mechanical polishing (CMP) to expose the planar surface to be coplanar with a top surface of the insulating dielectric layer 117 in the empty space 113a.

Next, referring to FIGS. 2G-1, 2G-2 and 2G-3, FIG. 2G-1 is a schematically top view showing a process for fabricating a first type of gate-all-around (GAA) transistor in accordance with an embodiment of the present application; FIG. 2G-2 is a schematically cross-sectional view cut along a cross-sectional line X-X′ of FIG. 2G-1; FIG. 2G-3 is a schematically cross-sectional view cut along a cross-sectional line Y-Y′ of FIG. 2G-1. A part 111a for a gate-all-around (GAA) portion of each of transistors may be defined by patterning the layer 108 of hard mask using processes of photolithography and reactive-ion etching (RIE), followed by dry etching, based on the pattern of the layer 108 of hard mask, the epitaxial layers 103, 105 and 107 of silicon and the layer 115 of silicon germanium (SiGe) to form two empty spaces 111b and 111e for a source and drain of said each of the transistors each surrounded by a sidewall of the insulating dielectric layer 117, two neighboring sidewalls of the layer 113 of field oxide and a sidewall of the part 111a for the gate-all-around (GAA) portion of said each of the transistors, wherein each of the two empty spaces 111b and 111c may expose a top surface of the insulating dielectric layer 117 under said each of the two empty spaces 111b and 111c.

Next, referring to FIGS. 2H-1, 2H-2 and 2H-3, FIG. 2H-1 is a schematically top view showing a process for fabricating a first type of gate-all-around (GAA) transistor in accordance with an embodiment of the present application; FIG. 2H-2 is a schematically cross-sectional view cut along a cross-sectional line X-X′ of FIG. 2H-1; FIG. 2H-3 is a schematically cross-sectional view cut along a cross-sectional line Y-Y′ of FIG. 2H-1. A layer 123 of in-situ doping selective epitaxial silicon may be formed with a vertical thickness between 0.01 and 0.5 micrometers or between 0.02 and 0.3 micrometers and in each of the two empty spaces 111b and 111 for the source and drain of each of the transistors and on the top surface of the insulating dielectric layer 117, wherein the layer 123 of in-situ doping selective epitaxial silicon in said each of the two empty spaces 111b and 111 for the source and drain of said each of the transistor may join the epitaxial layers 103, 105 and 107 of silicon of the part 111a for a gate-all-around (GAA) portion of said each of the transistors and may be dopped with boron for a P-type metal-oxide-semiconductor (MOS) transistor or phosphorus for a N-type metal-oxide-semiconductor (MOS) transistor. The layer 123 of in-situ doping selective epitaxial silicon may include a lightly-dopped and a heavily-dopped layer for a lightly-doped drain of the P-type or N-type metal-oxide-semiconductor (MOS) transistor. Next, a layer of metal silicide (not shown), such as nickel silicide, cobalt silicide or titanium silicide, may be optionally deposited on a top surface of the layer 123 of in-situ doping selective epitaxial silicon and in each of the two empty spaces 111b and 111 for the source and drain of each of the transistors. Next, a layer 4d of filing oxide, such as silicon oxide, may be deposited with a vertical thickness between 1 and 10 nanometers or between 2 and 6 micrometers and on a top surface of the layer of metal silicide or the top surface of the layer 123 of in-situ doping selective epitaxial silicon in case that the layer of metal silicide is omitted. The layer 4d of filing oxide may have a top surface coplanar with the top surface of the layer 108 of hard mask, a top surface of the insulating dielectric layer 117 and a top surface of the layer 113 of field oxide.

Next, referring to FIGS. 2I-1, 2I-2 and 2I-3, FIG. 2I-1 is a schematically top view showing a process for fabricating a first type of gate-all-around (GAA) transistor in accordance with an embodiment of the present application; FIG. 2I-2 is a schematically cross-sectional view cut along a cross-sectional line X-X′ of FIG. 2I-1; FIG. 2I-3 is a schematically cross-sectional view cut along a cross-sectional line Y-Y′ of FIG. 2I-1. Using processes of photolithography and reactive-ion etching (RIE), a vertically-extending gate trench 127a may be formed from the top surface of the insulating dielectric layer 117 at one of two opposite sides of the part 111a for the gate-all-around (GAA) portion of each of the transistors to an inner of the insulating dielectric layer 117 to expose a sidewall of the layer 108 of hard mask at said one of the two opposite sides of the part 111a and expose a vertical surface of a vertically-extending portion of the layer 115 of silicon germanium (SiGe). Further, using processes of photolithography and reactive-ion etching (RIE), a vertically-extending gate trench 127b may be formed from the top surface of the layer 113 of field oxide at the other of the two opposite sides of the part 111a for the gate-all-around (GAA) portion of said each of the transistors to an inner of the layer 113 of field oxide to expose another sidewall of the layer 108 of hard mask at the other of the two opposite sides of the part 111a and expose a sidewall of each of horizontally extending portions of the layer 115 of silicon germanium (SiGe) and a sidewall of each of the epitaxial layers 103, 105 and 107 of silicon. Next, for the part 111a for the gate-all-around (GAA) portion of each of the transistors, the layer 115 of silicon germanium (SiGe) may be removed by a process of isotropic selective etching, such as wet etching using a mixture of hydrogen peroxide (H₂O₂) and ammonium hydroxide (NH₄OH) as an etchant, to form multiple horizontally-extending gate trenches 127c each between neighboring two of the epitaxial layers 103, 105 and 107 of silicon or between the epitaxial layer 103 of silicon and the insulating dielectric layer 117 vertically under the epitaxial layer 103 of silicon. Next, for the part 111a for the gate-all-around (GAA) portion of each of the transistors, the layer 108 of hard mask may be removed to form a horizontally-extending gate trench 127d over the top surface of the epitaxial layer 107 of silicon. The vertically-extending gate trenches 127a and 127b and horizontally-extending gate trenches 127c and 127d at each of the transistor sites 111 may be formed for a transistor space and around each of the epitaxial layers 103, 105 and 107 of silicon and communicate with one another. Thereby, the epitaxial layers 103, 105 and 107 of silicon in each of the transistor sites 111 may have the top and bottom surfaces and two opposite sidewalls to be exposed by the transistor space, the layer 123 of in-situ doping selective epitaxial silicon in said each of the transistor sites 111 may have two opposite inner sidewalls, facing to each other, to be exposed by the transistor space, the insulating dielectric layer 117 at said each of the transistor sites 111 may have an inner sidewall to be exposed by the transistor space and the layer 113 of field oxide at said each of the transistor sites 111 may have an inner sidewall, opposite to the inner sidewall of the insulating dielectric layer 117 thereat, to be exposed by the transistor space.

Next, referring to FIGS. 2J-1, 2J-2 and 2J-3, FIG. 2J-1 is a schematically top view showing a process for fabricating a first type of gate-all-around (GAA) transistor in accordance with an embodiment of the present application; FIG. 2J-2 is a schematically cross-sectional view cut along a cross-sectional line X-X′ of FIG. 2J-1; FIG. 2J-3 is a schematically cross-sectional view cut along a cross-sectional line Y-Y′ of FIG. 2J-1. Using a process of atomic layer deposition (ALD), an insulating dielectric layer 141 may be deposited in each of the transistor spaces, surrounding each of the epitaxial layers 103, 105 and 107 of silicon in each of the transistor sites 111 and on and in contact with the exposed top and bottom surfaces and exposed two opposite sidewalls of each of the epitaxial layers 103, 105 and 107 of silicon in said each of the transistor sites 111, the exposed two opposite inner sidewalls of the layer 123 of in-situ doping selective epitaxial silicon in said each of the transistor sites 111, the exposed inner sidewall of the insulating dielectric layer 117 and the exposed inner sidewall of the layer 113 of field oxide and on a planar surface composed of the top surface of the layer 4d of filing oxide, the top surface of the insulating dielectric layer 117 and the top surface of the layer 113 of field oxide. The insulating dielectric layer 141 may have a high dielectric constant, such as hafnium oxide (HfO₂) or tantalum oxide (Ta₂O₃). Next, a layer 43 of work function metal may be deposited in said each of the transistor spaces, on the insulating dielectric layer 141 and over the planar surface composed of the top surface of the layer 4d of filing oxide, the top surface of the insulating dielectric layer 117 and the top surface of the layer 113 of field oxide, wherein the layer 43 of work function metal may be made of titanium nitride (TiN), tantalum nitride (TaN), a titanium-aluminum (TiAl) alloy or tungsten nitride (WN). Next, using a process of atomic layer deposition (ALD), physical vapor deposition (PVD) and/or chemical vapor deposition (CVD), a metal layer 142, such as an aluminum alloy, an aluminum-copper alloy or an aluminum-titanium alloy, may be deposited in said each of the transistor spaces, on the layer 43 of work function metal and over the planar surface composed of the top surface of the layer 4d of filing oxide, the top surface of the insulating dielectric layer 117 and the top surface of the layer 113 of field oxide. Next, the metal layer 142, insulating dielectric layer 141 and layer 43 of work function metal over said each of the transistor spaces and the planar surface composed of the top surface of the layer 4d of filing oxide, the top surface of the insulating dielectric layer 117 and the top surface of the layer 113 of field oxide may be removed by a process of chemical-mechanical polishing (CMP) to expose the planar surface to be coplanar with a top surface of the metal layer 142. So far, multiple first type of transistors 4 may be well formed over the semiconductor substrate 2. The first type of transistor 4 may be employed for each of the transistors 4 as illustrated in FIGS. 1A-IF, 1H-1L and 1G-1 through 1G-8. For the first type of transistor 4, its metal layer 142 and insulating dielectric layer 141 may be formed respectively as the metal gate 42 and layer 41 of gate oxide of the gate-all-around (GAA) portion 4a of each of the transistors 4 as illustrated in FIGS. 1A-IF, 1H-1L and 1G-1 through 1G-8, each of its epitaxial layers 103, 105 and 107 of silicon may be formed as the channel 11 of said each of the transistors 4 as illustrated in FIGS. 1A-IF, 1H-1L and 1G-1 through 1G-8, its layer 123 of in-situ doping selective epitaxial silicon in the two spaces 111b and 111e for its source and drain may be formed respectively as the two epitaxial portions 4b and 4c of said each of the transistors 4 as illustrated in FIGS. 1A-IF, 1H-1L and 1G-1 through 1G-8. The insulating dielectric layer 117 and layer 113 of field oxide horizontally around each of the first type of transistors 4 may be formed as the layer 3a of field oxide horizontally surrounding said each of the transistors 4 as illustrated in FIGS. 1A-IF, 1H-1L and 1G-1 through 1G-8. The insulating dielectric layer 117 under and in contact with each of the first type of transistors 4 may be formed as the insulating dielectric layer 3b as illustrated in FIGS. 1A-IF, 1H-1L and 1G-1 through 1G-8. The layer 119 of silicon germanium (SiGe) under each of the first type of transistors 4 may be formed as the insulating dielectric layer 2s as illustrated in FIGS. 1A-IF, 1H-1L and 1G-1 through 1G-8.

### Process for Fabricating Second Type of Gate-All-Around (GAA) Transistor

FIGS. 3A, 3B-2 through 3T-2, 3B-3 through 3T-3, 3B-3 through 3T-3, 3Q-4 through 3T-4 and 3Q-5 through 3T-5 are schematically cross-sectional views showing a process for fabricating a second type of gate-all-around (GAA) transistor in accordance with an embodiment of the present application. FIGS. 3B-1 through 3T-1 are schematically top views showing a process for fabricating a second type of gate-all-around (GAA) transistor in accordance with an embodiment of the present application. Referring to FIG. 3A, a semiconductor substrate 2, such as a semiconductor wafer made of single crystal silicon, may be first provided. Next, an epitaxial layer 302 of silicon germanium (SiGe) having a vertical thickness between 0.05 and 0.5 micrometers or between 0.06 and 0.2 micrometers may be formed on a top surface of the semiconductor substrate 2. Next, an epitaxial layer 303 of silicon having a vertical thickness between 1 and 20 nanometers, between 2 and 20 nanometers, between 1 and 6 nanometers or between 4 and 10 nanometers may be formed on a top surface of the epitaxial layer 302 of silicon germanium (SiGe). Next, an epitaxial layer 304 of silicon germanium (SiGe) having a vertical thickness between 5 and 20 nanometers or between 6 and 10 nanometers may be formed on a top surface of the epitaxial layer 303 of silicon. Next, an epitaxial layer 305 of silicon having a vertical thickness between 1 and 20 nanometers, between 2 and 20 nanometers, between 1 and 6 nanometers or between 4 and 10 nanometers may be formed on a top surface of the epitaxial layer 304 of silicon germanium (SiGe). Next, an epitaxial layer 306 of silicon germanium (SiGe) having a vertical thickness between 5 and 20 nanometers or between 6 and 10 nanometers may be formed on a top surface of the epitaxial layer 305 of silicon. Next, an epitaxial layer 307 of silicon having a vertical thickness between 1 and 20 nanometers, between 2 and 20 nanometers, between 1 and 6 nanometers or between 4 and 10 nanometers may be formed on a top surface of the epitaxial layer 306 of silicon germanium (SiGe). Next, an epitaxial layer 352 of silicon germanium (SiGe) having a vertical thickness between 0.05 and 0.5 micrometers or between 0.06 and 0.2 micrometers may be formed on a top surface of the epitaxial layer 307 of silicon. Next, an epitaxial layer 353 of silicon having a vertical thickness between 1 and 20 nanometers, between 2 and 20 nanometers, between 1 and 6 nanometers or between 4 and 10 nanometers may be formed on a top surface of the epitaxial layer 352 of silicon germanium (SiGe). Next, an epitaxial layer 354 of silicon germanium (SiGe) having a vertical thickness between 5 and 20 nanometers or between 6 and 10 nanometers may be formed on a top surface of the epitaxial layer 353 of silicon. Next, an epitaxial layer 355 of silicon having a vertical thickness between 1 and 20 nanometers, between 2 and 20 nanometers, between 1 and 6 nanometers or between 4 and 10 nanometers may be formed on a top surface of the epitaxial layer 354 of silicon germanium (SiGe). Next, an epitaxial layer 356 of silicon germanium (SiGe) having a vertical thickness between 5 and 20 nanometers or between 6 and 10 nanometers may be formed on a top surface of the epitaxial layer 355 of silicon. Next, an epitaxial layer 357 of silicon having a vertical thickness between 1 and 20 nanometers, between 2 and 20 nanometers, between 1 and 6 nanometers or between 4 and 10 nanometers may be formed on a top surface of the epitaxial layer 356 of silicon germanium (SiGe). Next, a layer 308 of hard mask may be formed on a top surface of the epitaxial layer 357 of silicon, wherein the layer 308 of hard mask may be made of silicon oxide, silicon oxynitride or a combination of silicon oxide and silicon oxynitride and have a vertical thickness between 10 and 150 nanometers or between 20 and 100 nanometers.

Next, referring to FIGS. 3B-1, 3B-2 and 3B-3, FIG. 3B-1 is a schematically top view showing a process for fabricating a second type of gate-all-around (GAA) transistor in accordance with an embodiment of the present application; FIG. 3B-2 is a schematically cross-sectional view cut along a cross-sectional line X-X′ of FIG. 3B-1; FIG. 3B-3 is a schematically cross-sectional view cut along a cross-sectional line Y-Y′ of FIG. 3B-1. An isolation trench 309 may be formed in the layer 308 of hard mask, the epitaxial layers 303, 305, 307, 353, 355 and 357 of silicon, the epitaxial layers 302, 304, 306, 352, 354 and 356 of silicon germanium (SiGe) and the semiconductor substrate 2 to define multiple transistor sites 311 on the semiconductor substrate 2 and separated by the isolation trench 309. The transistor sites 311 may be defined by first patterning the layer 308 of hard mask using processes of photolithography and reactive-ion etching (RIE), followed by etching the epitaxial layers 303, 305, 307, 353, 355 and 357 of silicon, the epitaxial layers 302, 304, 306, 352, 354 and 356 of silicon germanium (SiGe) and the semiconductor substrate 2 based on the pattern of the layer 308 of hard mask so as to form the isolation trench 309. Next, a layer 313 of field oxide may be deposited, by a process of chemical vapor deposition (CVD), on a top surface of the layer 308 of hard mask and in the isolation trench 309. Next, the layer 313 of field oxide over the top surface of the layer 308 of hard mask and the isolation trench 309 may be removed by a process of chemical mechanical polishing (CMP) to expose the top surface of the layer 308 of hard mask to be coplanar with a top surface of the layer 313 of field oxide left in the isolation trench 309.

Next, referring to FIGS. 3C-1, 3C-2 and 3C-3, FIG. 3C-1 is a schematically top view showing a process for fabricating a second type of gate-all-around (GAA) transistor in accordance with an embodiment of the present application; FIG. 3C-2 is a schematically cross-sectional view cut along a cross-sectional line X-X′ of FIG. 3C-1; FIG. 3C-3 is a schematically cross-sectional view cut along a cross-sectional line Y-Y′ of FIG. 3C-1. The layer 313 of field oxide in the isolation trench 309 at a sidewall of each of the transistor sites 311 may be removed using processes of photolithography and reactive-ion etching (RIE) to form an empty space 313a in the isolation trench 309 and at the side of each of the transistor sites 311 and to expose a sidewall of each of the epitaxial layers 303, 305, 307, 353, 355 and 357 of silicon and a sidewall of each of the epitaxial layers 302, 304, 306, 352, 354 and 356 of silicon germanium (SiGe), wherein the layer 313 of field oxide under the empty space 313a may be left in the semiconductor substrate 2. Next, the epitaxial layers 302, 304, 306, 352, 354 and 356 of silicon germanium (SiGe) may be removed from the exposed sidewalls thereof by a process of isotropic selective etching, such as wet etching using a mixture of hydrogen peroxide (H₂O₂) and ammonium hydroxide (NH₄OH) as an etchant, to form an empty space 313b between neighboring two of the epitaxial layers 303, 305, 307, 353, 355 and 357 of silicon and between the epitaxial layer 303 of silicon and the semiconductor substrate 2 and to expose a bottom and top surface of each of the epitaxial layers 303, 305, 307, 353 and 355 of silicon, a bottom surface of the epitaxial layer 357 of silicon and a top surface of the semiconductor substrate 2, wherein the empty space 313a communicates with the empty spaces 313b.

Next, referring to FIGS. 3D-1, 3D-2 and 3D-3, FIG. 3D-1 is a schematically top view showing a process for fabricating a second type of gate-all-around (GAA) transistor in accordance with an embodiment of the present application; FIG. 3D-2 is a schematically cross-sectional view cut along a cross-sectional line X-X′ of FIG. 3D-1; FIG. 3D-3 is a schematically cross-sectional view cut along a cross-sectional line Y-Y′ of FIG. 3D-1. Using a selective epitaxial technology, a layer 315 of silicon germanium (SiGe) may be deposited with a thickness between 3 and 12 nanometers in the empty spaces 313a and 313b as seen in FIGS. 3C-1, 3C-2 and 3C-3 and on the exposed bottom and top surfaces of each of the epitaxial layers 303, 305 and 307 of silicon and the exposed sidewall of each of the epitaxial layers 303, 305 and 307 of silicon; a layer 365 of silicon germanium (SiGe) may be deposited with a thickness between 3 and 12 nanometers in the empty spaces 313a and 313b as seen in FIGS. 3C-1, 3C-2 and 3C-3, and on the exposed bottom and top surfaces of each of the epitaxial layers 353 and 355 of silicon, the exposed bottom surface of the epitaxial layer 357 of silicon and the exposed sidewall of each of the epitaxial layers 353, 355 and 357 of silicon; and a layer 319 of silicon germanium (SiGe) may be deposited with a thickness between 3 and 12 nanometers in the bottommost one of the empty spaces 313b and on the exposed top surface of the semiconductor substrate 2. The layer 315 of silicon germanium (SiGe) may be completely filled in the empty space 313b between the epitaxial layers 303 and 305 of silicon, the empty space 313b between the epitaxial layers 305 and 307 of silicon. The layer 365 of silicon germanium (SiGe) may be completely filled in the empty space 313b between the epitaxial layers 353 and 355 of silicon and the empty space 313b between the epitaxial layers 355 and 357 of silicon. The layers 315 and 319 of silicon germanium (SiGe) may not be completely filled in the empty space 313b between the epitaxial layer 303 of silicon and the semiconductor substrate 2; and the layers 315 and 365 of silicon germanium (SiGe) may not be completely filled in the empty space 313b between the epitaxial layers 307 and 353 of silicon. An empty gap 313c may be formed with a vertical dimension between 0.01 and 0.5 micrometers or between 0.02 and 0.3 micrometers and between a bottom surface of the layer 315 of silicon germanium (SiGe) formed on the bottom surface of the epitaxial layer 303 of silicon and a top surface of the layer 319 of silicon germanium (SiGe) formed on the top surface of the semiconductor substrate 2. An empty gap 313d may be formed with a vertical dimension between 0.01 and 0.5 micrometers or between 0.02 and 0.3 micrometers and between a bottom surface of the layer 365 of silicon germanium (SiGe) formed on the bottom surface of the epitaxial layer 353 of silicon and a top surface of the layer 315 of silicon germanium (SiGe) formed on the top surface of the epitaxial layer 307 of silicon.

Next, referring to FIGS. 3E-1, 3E-2 and 3E-3, FIG. 3E-1 is a schematically top view showing a process for fabricating a second type of gate-all-around (GAA) transistor in accordance with an embodiment of the present application; FIG. 3E-2 is a schematically cross-sectional view cut along a cross-sectional line X-X′ of FIG. 3E-1; FIG. 3E-3 is a schematically cross-sectional view cut along a cross-sectional line Y-Y′ of FIG. 3E-1. An insulating dielectric layer 317, i.e., silicon-on-insulator (SOI) dielectric layer may be formed, by a process of atomic layer deposition (ALD) or chemical vapor deposition (CVD), in the empty space 313a and empty gaps 313c and 313d as seen in FIGS. 3D-1, 3D-2 and 3D-3, on a planar surface composed of the top surface of the layer 308 of hard mask and the top surface of the layer 313 of field oxide and on a top surface of the layer 313 of field oxide under the empty space 313a. The insulating dielectric layer 317 may be made of a layer of silicon oxide, silicon oxynitride or silicon nitride, multiple layers of silicon oxide and silicon oxynitride or multiple layers of silicon oxide and silicon nitride, wherein the insulating dielectric layer 317 in each of the empty gaps 313c and 313d may have a vertical dimension between 0.01 and 0.5 micrometers or between 0.02 and 0.3 micrometers. Next, the insulating dielectric layer 317 over the planar surface composed of the top surface of the layer 308 of hard mask and the top surface of the layer 313 of field oxide and the empty space 313a may be removed by a processes of chemical mechanical polishing (CMP) to expose the planar surface to be coplanar with a top surface of the insulating dielectric layer 317 in the empty space 313a.

Next, referring to FIGS. 3F-1, 3F-2 and 3F-3, FIG. 3F-1 is a schematically top view showing a process for fabricating a second type of gate-all-around (GAA) transistor in accordance with an embodiment of the present application; FIG. 3F-2 is a schematically cross-sectional view cut along a cross-sectional line X-X′ of FIG. 3F-1; FIG. 3F-3 is a schematically cross-sectional view cut along a cross-sectional line Y-Y′ of FIG. 3F-1. A part 311a for a gate-all-around (GAA) portion of each of transistor sites 311 may be defined by patterning the layer 308 of hard mask using processes of photolithography and reactive-ion etching (RIE), followed by dry etching, based on the pattern of the layer 308 of hard mask, the epitaxial layers 303, 305, 307, 353, 355 and 357 of silicon and the layers 315 and 365 of silicon germanium (SiGe) to form two empty spaces 311b and 311c each exposing an inner sidewall of the insulating dielectric layer 317, two neighboring inner sidewalls of the layer 313 of field oxide and a sidewall of the part 311a for the gate-all-around (GAA) portion of said each of the transistor sites 311, wherein each of the two empty spaces 311b and 311c may further expose a top surface of the insulating dielectric layer 317 under said each of the two empty spaces 311b and 311c.

Next, referring to FIGS. 3G-1, 3G-2 and 3G-3, FIG. 3G-1 is a schematically top view showing a process for fabricating a second type of gate-all-around (GAA) transistor in accordance with an embodiment of the present application; FIG. 3G-2 is a schematically cross-sectional view cut along a cross-sectional line X-X′ of FIG. 3G-1; FIG. 3G-3 is a schematically cross-sectional view cut along a cross-sectional line Y-Y′ of FIG. 3G-1. A layer 361 of filling oxide, such as silicon oxide, may be formed, by a process of atomic layer deposition (ALD) or chemical vapor deposition (CVD), in each of the two empty spaces 311b and 311c in each of the transistor sites 311 as seen in FIGS. 3F-1, 3F-2 and 3F-3, on a planar surface composed of the top surface of the layer 308 of hard mask, the top surface of the layer 313 of field oxide and the top surface of the insulating dielectric layer 317 and on a top surface of the insulating dielectric layer 317 under said each of the two empty spaces 311b and 311c. Next, the layer 361 of filling oxide over the planar surface composed of the top surface of the layer 308 of hard mask, the top surface of the layer 313 of field oxide and the top surface of the insulating dielectric layer 317 and said each of the two empty spaces 311b and 311c may be removed by a processes of chemical mechanical polishing (CMP) to expose the planar surface to be coplanar with a top surface of the layer 361 of filling oxide in said each of the two empty spaces 311b and 311c.

Next, referring to FIGS. 3H-1, 3H-2 and 3H-3, FIG. 3H-1 is a schematically top view showing a process for fabricating a second type of gate-all-around (GAA) transistor in accordance with an embodiment of the present application; FIG. 3H-2 is a schematically cross-sectional view cut along a cross-sectional line X-X′ of FIG. 3H-1; FIG. 3H-3 is a schematically cross-sectional view cut along a cross-sectional line Y-Y′ of FIG. 3H-1. In each of a first group of the transistor sites 311, i.e., the left one of the transistor sites 311 in FIGS. 3H-1 and 3H-2, two etching channels may be formed, by processes of photolithography and reactive-ion etching (RIE), from the top surface of the layer 361 of filling oxide at two opposite sides of the layer 308 of hard mask into an inner of the layer 361 of filling oxide to expose two opposite sidewalls of each of the epitaxial layers 353, 355 and 357 of silicon, two opposite sidewalls of the layer 365 of silicon germanium (SiGe) between the epitaxial layers 353 and 355 of silicon, two opposite sidewalls of the layer 365 of silicon germanium (SiGe) between the epitaxial layers 355 and 357 of silicon and two opposite sidewalls of the layer 365 of silicon germanium (SiGe) between the epitaxial layer 353 of silicon and the insulating dielectric layer 317 horizontally extending between the epitaxial layers 307 and 353 of silicon. Next, in said each of the first group of the transistor sites 311, the layer 365 of silicon germanium (SiGe) and each of the epitaxial layers 353, 355 and 357 of silicon may be removed by a process of isotropic selective etching, such as wet etching using a mixture of hydrogen peroxide (H₂O₂) and ammonium hydroxide (NH₄OH) as an etchant, via the two etching channels to form an empty space 361a between a bottom surface of the layer 308 of hard mask and a top surface of the insulating dielectric layer 317 horizontally extending over the epitaxial layer 307 of silicon, wherein the empty space 361a may expose two opposite inner sidewalls of the layer 361 of filling oxide, the inner sidewall of the insulating dielectric layer 317 and the inner sidewall of the layer 313 of field oxide opposite to the inner sidewall of the insulating dielectric layer 317.

Next, referring to FIGS. 3I-1, 3I-2 and 3I-3, FIG. 3I-1 is a schematically top view showing a process for fabricating a second type of gate-all-around (GAA) transistor in accordance with an embodiment of the present application; FIG. 3I-2 is a schematically cross-sectional view cut along a cross-sectional line X-X′ of FIG. 3I-1; FIG. 3I-3 is a schematically cross-sectional view cut along a cross-sectional line Y-Y′ of FIG. 3I-1. In each of the first group of the transistor sites 311, a layer 362 of filling oxide, such as silicon oxide, may be formed, by a process of atomic layer deposition (ALD) or chemical vapor deposition (CVD), in the empty space 361a as seen in FIGS. 3H-1, 3H-2 and 3H-3 and on a planar surface composed of the top surface of the layer 308 of hard mask, the top surface of the layer 313 of field oxide, the top surface of the insulating dielectric layer 317 and the top surface of the layer 361 of filling oxide. Next, the layer 362 of filling oxide over the planar surface composed of the top surface of the layer 308 of hard mask, the top surface of the layer 313 of field oxide, the top surface of the insulating dielectric layer 317 and the top surface of the layer 361 of filling oxide may be removed by a processes of chemical mechanical polishing (CMP) to expose the planar surface to be coplanar with a top surface of the layer 362 of filling oxide.

Next, referring to FIGS. 3J-1, 3J-2 and 3J-3, FIG. 3J-1 is a schematically top view showing a process for fabricating a second type of gate-all-around (GAA) transistor in accordance with an embodiment of the present application; FIG. 3J-2 is a schematically cross-sectional view cut along a cross-sectional line X-X′ of FIG. 3J-1; FIG. 3J-3 is a schematically cross-sectional view cut along a cross-sectional line Y-Y′ of FIG. 3J-1. In each of the first group of the transistor sites 311, the layer 361 of filling oxide and the layer 362 of filling oxide not under the layer 308 of hard mask may be removed, using processes of photolithography and reactive-ion etching (RIE), to form two empty spaces 311d and 311e each exposing the inner sidewall of the insulating dielectric layer 317, the two neighboring inner sidewalls of the layer 313 of field oxide and a sidewall of the part 311a for its gate-all-around (GAA) portion, wherein each of the two empty spaces 311d and 311e may further expose the top surface of the insulating dielectric layer 317 under said each of the two empty spaces 311d and 311e. The two empty spaces 311d and 311e may further expose two opposite sidewalls of the layer 362 of filling oxide, two opposite sidewalls of the insulating dielectric layer 317 horizontally extending over the epitaxial layer 307 of silicon, two opposite sidewalls of each of the epitaxial layers 303, 305 and 307 of silicon, two opposite sidewalls of the layer 315 of silicon germanium (SiGe) on the top surface of the epitaxial layer 307 of silicon, two opposite sidewalls of the layer 315 of silicon germanium (SiGe) between the epitaxial layers 305 and 307 of silicon, two opposite sidewalls of the layer 315 of silicon germanium (SiGe) between the epitaxial layers 303 and 305 of silicon and two opposite sidewalls of the layer 315 of silicon germanium (SiGe) on the bottom surface of the epitaxial layer 303 of silicon. In each of a second group of the transistor sites 311, i.e., the middle one of the transistor sites 311 in FIGS. 3J-1 and 3J-2, the layer 361 of filling oxide may be removed, using processes of photolithography and reactive-ion etching (RIE), to form two empty spaces 311f and 311g each exposing the inner sidewall of the insulating dielectric layer 317, the two neighboring inner sidewalls of the layer 313 of field oxide and a sidewall of the part 311a for its gate-all-around (GAA) portion, wherein each of the two empty spaces 311f and 311g may further expose the top surface of the insulating dielectric layer 317 under said each of the two empty spaces 311f and 311g. The two empty spaces 311f and 311g may further expose two opposite sidewalls of the insulating dielectric layer 317 horizontally extending between the epitaxial layers 307 and 353 of silicon, two opposite sidewalls of each of the epitaxial layers 303, 305, 307, 353, 355 and 357 of silicon, two opposite sidewalls of the layer 315 of silicon germanium (SiGe) on the top surface of the epitaxial layer 307 of silicon, two opposite sidewalls of the layer 315 of silicon germanium (SiGe) between the epitaxial layers 305 and 307 of silicon, two opposite sidewalls of the layer 315 of silicon germanium (SiGe) between the epitaxial layers 303 and 305 of silicon and two opposite sidewalls of the layer 315 of silicon germanium (SiGe) on the bottom surface of the epitaxial layer 303 of silicon, two opposite sidewalls of the layer 365 of silicon germanium (SiGe) between the epitaxial layers 355 and 357 of silicon, two opposite sidewalls of the layer 365 of silicon germanium (SiGe) between the epitaxial layers 353 and 355 of silicon and two opposite sidewalls of the layer 365 of silicon germanium (SiGe) on the bottom surface of the epitaxial layer 353 of silicon.

Next, referring to FIGS. 3K-1, 3K-2 and 3K-3, FIG. 3K-1 is a schematically top view showing a process for fabricating a second type of gate-all-around (GAA) transistor in accordance with an embodiment of the present application; FIG. 3K-2 is a schematically cross-sectional view cut along a cross-sectional line X-X′ of FIG. 3K-1; FIG. 3K-3 is a schematically cross-sectional view cut along a cross-sectional line Y-Y′ of FIG. 3K-1. In each of the first group of the transistor sites 311, using a selective epitaxial technology, two layers 366 of in-situ doping selective epitaxial silicon may be respectively deposited with a vertical thickness between 0.01 and 0.5 micrometers or between 0.02 and 0.3 micrometers in the empty spaces 311d and 311e as seen in FIGS. 3J-1 and 3J-2 and on the exposed two opposite sidewalls of each of the epitaxial layers 303, 305 and 307 of silicon, exposed two opposite sidewalls of the layer 315 of silicon germanium (SiGe) on the top surface of the epitaxial layer 307 of silicon, exposed two opposite sidewalls of the layer 315 of silicon germanium (SiGe) between the epitaxial layers 305 and 307 of silicon, exposed two opposite sidewalls of the layer 315 of silicon germanium (SiGe) between the epitaxial layers 303 and 305 of silicon and exposed two opposite sidewalls of the layer 315 of silicon germanium (SiGe) on the bottom surface of the epitaxial layer 303 of silicon, wherein the layer 366 of in-situ doping selective epitaxial silicon in the empty spaces 311d and 311e may join the epitaxial layers 303, 305 and 307 of silicon and may be dopped with boron for a P-type metal-oxide-semiconductor (MOS) transistor or phosphorus for a N-type metal-oxide-semiconductor (MOS) transistor, wherein the two layers 366 of in-situ doping selective epitaxial silicon may include a lightly-dopped and a heavily-dopped layer for a lightly-doped drain of the P-type or N-type metal-oxide-semiconductor (MOS) transistor. Thereby, one of the two layers 366 of in-situ doping selective epitaxial silicon in the empty space 311d may be used as a source of a first transistor, and the other of the two layers 366 of in-situ doping selective epitaxial silicon in the empty space 311e may be used as a drain of the first transistor. In each of the second group of the transistor sites 311, using a selective epitaxial technology, two layers 367 of in-situ doping selective epitaxial silicon may be respectively deposited with a vertical thickness between 0.01 and 0.5 micrometers or between 0.02 and 0.3 micrometers in the two empty spaces 311f and 311g as seen in FIGS. 3J-1 and 3J-2 and on the exposed two opposite sidewalls of each of the epitaxial layers 303, 305 and 307 of silicon, exposed two opposite sidewalls of the layer 315 of silicon germanium (SiGe) on the top surface of the epitaxial layer 307 of silicon, exposed two opposite sidewalls of the layer 315 of silicon germanium (SiGe) between the epitaxial layers 305 and 307 of silicon, exposed two opposite sidewalls of the layer 315 of silicon germanium (SiGe) between the epitaxial layers 303 and 305 of silicon and exposed two opposite sidewalls of the layer 315 of silicon germanium (SiGe) on the bottom surface of the epitaxial layer 303 of silicon, wherein the two layers 367 of in-situ doping selective epitaxial silicon in the empty spaces 311f and 311g may join two opposite ends of each the epitaxial layers 303, 305 and 307 of silicon respectively and may be dopped with boron for a P-type metal-oxide-semiconductor (MOS) transistor or phosphorus for a N-type metal-oxide-semiconductor (MOS) transistor, wherein the two layers 367 of in-situ doping selective epitaxial silicon may include a lightly-dopped and a heavily-dopped layer for a lightly-doped drain of the P-type or N-type metal-oxide-semiconductor (MOS) transistor. Thereby, the layer 367 of in-situ doping selective epitaxial silicon in the empty space 311f may be used as a source of a second transistor, and the layer 367 of in-situ doping selective epitaxial silicon in the empty space 311g may be used as a drain of the second transistor. In each of the second group of the transistor sites 311, using a selective epitaxial technology, two layers 368 of in-situ doping selective epitaxial silicon may be respectively deposited with a vertical thickness between 0.01 and 0.5 micrometers or between 0.02 and 0.3 micrometers in the two empty spaces 311f and 311g as seen in FIGS. 3J-1 and 3J-2 and on the exposed two opposite sidewalls of each of the epitaxial layers 353, 355 and 357 of silicon, exposed two opposite sidewalls of the layer 365 of silicon germanium (SiGe) between the epitaxial layers 355 and 357 of silicon, exposed two opposite sidewalls of the layer 365 of silicon germanium (SiGe) between the epitaxial layers 353 and 355 of silicon and exposed two opposite sidewalls of the layer 365 of silicon germanium (SiGe) on the bottom surface of the epitaxial layer 353 of silicon.

Next, referring to FIGS. 3L-1, 3L-2 and 3L-3, FIG. 3L-1 is a schematically top view showing a process for fabricating a second type of gate-all-around (GAA) transistor in accordance with an embodiment of the present application; FIG. 3L-2 is a schematically cross-sectional view cut along a cross-sectional line X-X′ of FIG. 3L-1; FIG. 3L-3 is a schematically cross-sectional view cut along a cross-sectional line Y-Y′ of FIG. 3L-1. In each of the first and second groups of the transistor sites 311, a layer 369 of filling oxide, such as silicon oxide, may be formed, by a process of atomic layer deposition (ALD) or chemical vapor deposition (CVD), in the empty spaces 311d, 311e, 311f and 311g as seen in FIGS. 3K-1 and 3K-2, on a side surface of each of the layers 366, 367 and 368 of in-situ doping selective epitaxial silicon and on a planar surface composed of the top surface of the layer 308 of hard mask, the top surface of the layer 313 of field oxide and the top surface of the insulating dielectric layer 317. Next, the layer 369 of filling oxide over the planar surface composed of the top surface of the layer 308 of hard mask, the top surface of the layer 313 of field oxide and the top surface of the insulating dielectric layer 317 may be removed by a processes of chemical mechanical polishing (CMP) to expose the planar surface to be coplanar with a top surface of the layer 369 of filling oxide.

Next, referring to FIGS. 3M-1, 3M-2 and 3M-3, FIG. 3M-1 is a schematically top view showing a process for fabricating a second type of gate-all-around (GAA) transistor in accordance with an embodiment of the present application; FIG. 3M-2 is a schematically cross-sectional view cut along a cross-sectional line X-X′ of FIG. 3M-1; FIG. 3M-3 is a schematically cross-sectional view cut along a cross-sectional line Y-Y′ of FIG. 3M-1. Using processes of photolithography and reactive-ion etching (RIE), the layer 369 of filling oxide at two opposite sides of the layer 308 of hard mask in each of the second group of the transistor sites 311 may be removed to form two opposite openings 361b at the two opposite sides of the layer 308 of hard mask respectively, wherein each of the two opposite openings 361b may expose a top surface of one of the two layers 368 of in-situ doping selective epitaxial silicon under said each of the two opposite openings 361b, and in each of a third group of the transistor sites 311, i.e., the right one of the transistor sites 311 in FIGS. 3M-1 and 3M-2, and two opposite empty spaces 361c and 361d may be vertically formed from the top surface of the layer 361 of filling oxide at the two opposite sides of the layer 308 of hard mask respectively to an inner of the layer 361 of filling oxide and respectively expose two opposite sidewalls of each of the epitaxial layers 353, 355 and 357 of silicon, two opposite sidewalls of the layer 365 of silicon germanium (SiGe) between the epitaxial layers 355 and 357 of silicon, two opposite sidewalls of the layer 365 of silicon germanium (SiGe) between the epitaxial layers 353 and 355 of silicon and two opposite sidewalls of the layer 365 of silicon germanium (SiGe) on the bottom surface of the epitaxial layer 353 of silicon.

Next, referring to FIGS. 3N-1, 3N-2 and 3N-3, FIG. 3N-1 is a schematically top view showing a process for fabricating a second type of gate-all-around (GAA) transistor in accordance with an embodiment of the present application; FIG. 3N-2 is a schematically cross-sectional view cut along a cross-sectional line X-X′ of FIG. 3N-1; FIG. 3N-3 is a schematically cross-sectional view cut along a cross-sectional line Y-Y′ of FIG. 3N-1. In each of the second group of the transistor sites 311, the layer 368 of in-situ doping selective epitaxial silicon may be removed by a process of isotropic selective etching, such as wet etching using a mixture of hydrogen peroxide (H₂O₂) and ammonium hydroxide (NH₄OH) as an etchant, via the two opposite openings 361b to form two opposite empty spaces 361e and 361f respectively exposing the two opposite sidewalls of each of the epitaxial layers 353, 355 and 357 of silicon, two opposite sidewalls of the layer 365 of silicon germanium (SiGe) between the epitaxial layers 355 and 357 of silicon, two opposite sidewalls of the layer 365 of silicon germanium (SiGe) between the epitaxial layers 353 and 355 of silicon and two opposite sidewalls of the layer 365 of silicon germanium (SiGe) on the bottom surface of the epitaxial layer 353 of silicon.

Next, referring to FIGS. 3O-1, 3O-2 and 3O-3, FIG. 3O-1 is a schematically top view showing a process for fabricating a second type of gate-all-around (GAA) transistor in accordance with an embodiment of the present application; FIG. 3O-2 is a schematically cross-sectional view cut along a cross-sectional line X-X′ of FIG. 3O-1; FIG. 3O-3 is a schematically cross-sectional view cut along a cross-sectional line Y-Y′ of FIG. 3O-1. In each of the second group of the transistor sites 311, two layers 371 of in-situ doping selective epitaxial silicon may be respectively deposited with a vertical thickness between 0.01 and 0.5 micrometers or between 0.02 and 0.3 micrometers in the two empty spaces 361e and 361f as seen in FIGS. 3N-1 and 3N-2 and on the exposed two opposite sidewalls of each of the epitaxial layers 353, 355 and 357 of silicon, exposed two opposite sidewalls of the layer 365 of silicon germanium (SiGe) between the epitaxial layers 355 and 357 of silicon, exposed two opposite sidewalls of the layer 365 of silicon germanium (SiGe) between the epitaxial layers 353 and 355 of silicon and exposed two opposite sidewalls of the layer 365 of silicon germanium (SiGe) on the bottom surface of the epitaxial layer 353 of silicon, wherein the two layers 371 of in-situ doping selective epitaxial silicon in the empty spaces 361e and 361f may join two opposite ends of each of the epitaxial layers 353, 355 and 357 of silicon respectively and may be dopped with boron for a P-type metal-oxide-semiconductor (MOS) transistor or phosphorus for a N-type metal-oxide-semiconductor (MOS) transistor, wherein the two layers 371 of in-situ doping selective epitaxial silicon may include a lightly-dopped and a heavily-dopped layer for a lightly-doped drain of the P-type or N-type metal-oxide-semiconductor (MOS) transistor. Thereby, the layer 371 of in-situ doping selective epitaxial silicon in the empty space 361e may be used as a source of a third transistor, and the layer 371 of in-situ doping selective epitaxial silicon in the empty space 361f may be used as a drain of the third transistor. In each of the third group of the transistor sites 311, two layers 372 of in-situ doping selective epitaxial silicon may be respectively deposited with a vertical thickness between 0.01 and 0.5 micrometers or between 0.02 and 0.3 micrometers in the two empty spaces 361c and 361d as seen in FIGS. 3N-1 and 3N-2 and on the exposed two opposite sidewalls of each of the epitaxial layers 353, 355 and 357 of silicon, exposed two opposite sidewalls of the layer 365 of silicon germanium (SiGe) between the epitaxial layers 355 and 357 of silicon, exposed two opposite sidewalls of the layer 365 of silicon germanium (SiGe) between the epitaxial layers 353 and 355 of silicon and exposed two opposite sidewalls of the layer 365 of silicon germanium (SiGe) on the bottom surface of the epitaxial layer 353 of silicon, wherein the two layers 372 of in-situ doping selective epitaxial silicon in the empty spaces 361c and 361d may join two opposite ends of each of the epitaxial layers 353, 355 and 357 of silicon respectively and may be dopped with boron for a P-type metal-oxide-semiconductor (MOS) transistor or phosphorus for a N-type metal-oxide-semiconductor (MOS) transistor, wherein the two layers 372 of in-situ doping selective epitaxial silicon may include a lightly-dopped and a heavily-dopped layer for a lightly-doped drain of the P-type or N-type metal-oxide-semiconductor (MOS) transistor. Thereby, the layer 372 of in-situ doping selective epitaxial silicon in the empty space 361c may be used as a source of a fourth transistor, and the layer 372 of in-situ doping selective epitaxial silicon in the empty space 361d may be used as a drain of the fourth transistor.

Next, referring to FIGS. 3P-1, 3P-2 and 3P-3, FIG. 3P-1 is a schematically top view showing a process for fabricating a second type of gate-all-around (GAA) transistor in accordance with an embodiment of the present application; FIG. 3P-2 is a schematically cross-sectional view cut along a cross-sectional line X-X′ of FIG. 3P-1; FIG. 3P-3 is a schematically cross-sectional view cut along a cross-sectional line Y-Y′ of FIG. 3P-1. A layer 373 of filling oxide, such as silicon oxide, may be formed, by a process of atomic layer deposition (ALD) or chemical vapor deposition (CVD), in each of the empty spaces 361c, 361d, 361e and 361f as seen in FIGS. 3O-1 and 3O-2, on a top surface of each of the two layers 371 of in-situ doping selective epitaxial silicon, on a top surface of each of the two layers 372 of in-situ doping selective epitaxial silicon and on a planar surface composed of the top surface of the layer 308 of hard mask, the top surface of the layer 313 of field oxide, the top surface of the insulating dielectric layer 317, the top surface of the layer 361 of filling oxide and the top surface of the layer 369 of filling oxide. Next, the layer 373 of filling oxide over the planar surface composed of the top surface of the layer 308 of hard mask, the top surface of the layer 313 of field oxide, the top surface of the insulating dielectric layer 317, the top surface of the layer 361 of filling oxide and the top surface of the layer 369 of filling oxide may be removed by a processes of chemical mechanical polishing (CMP) to expose the planar surface to be coplanar with a top surface of the layer 373 of filling oxide.

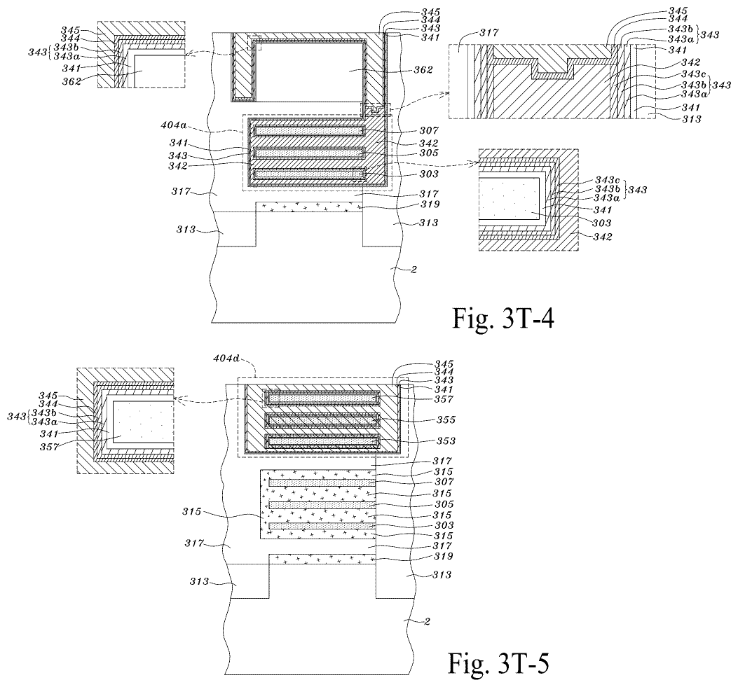

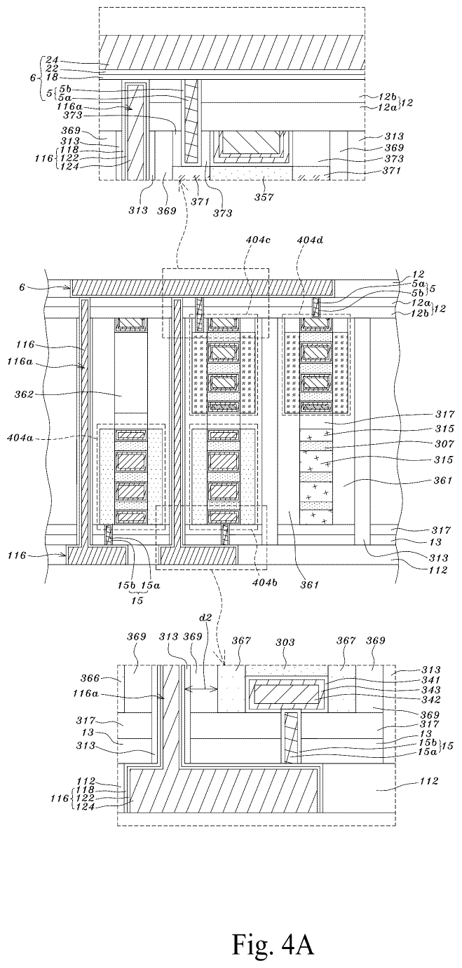

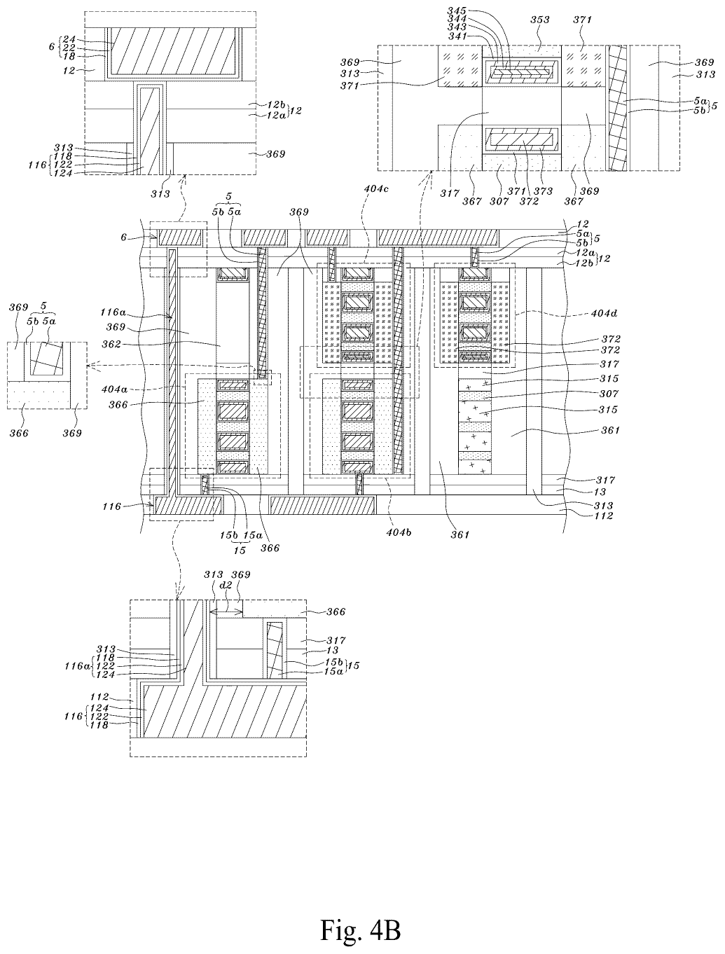

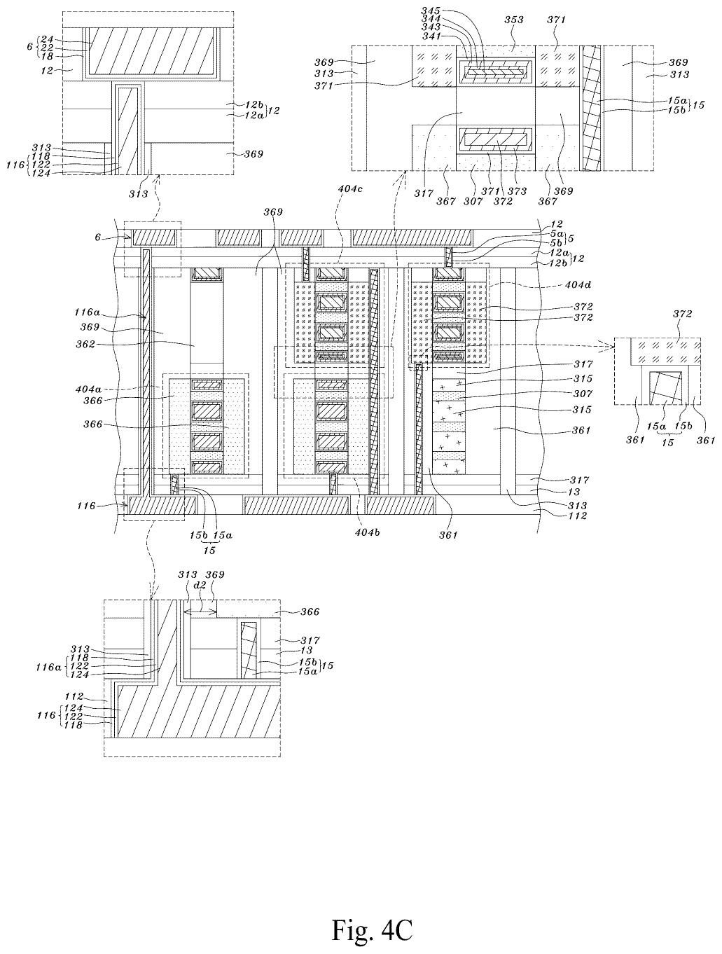

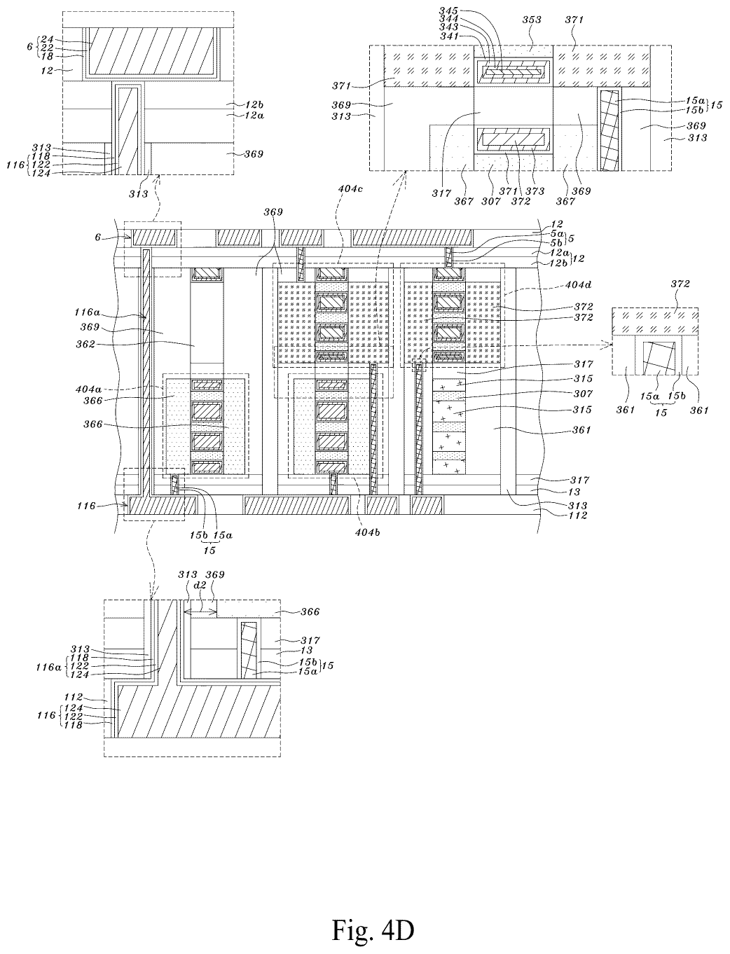

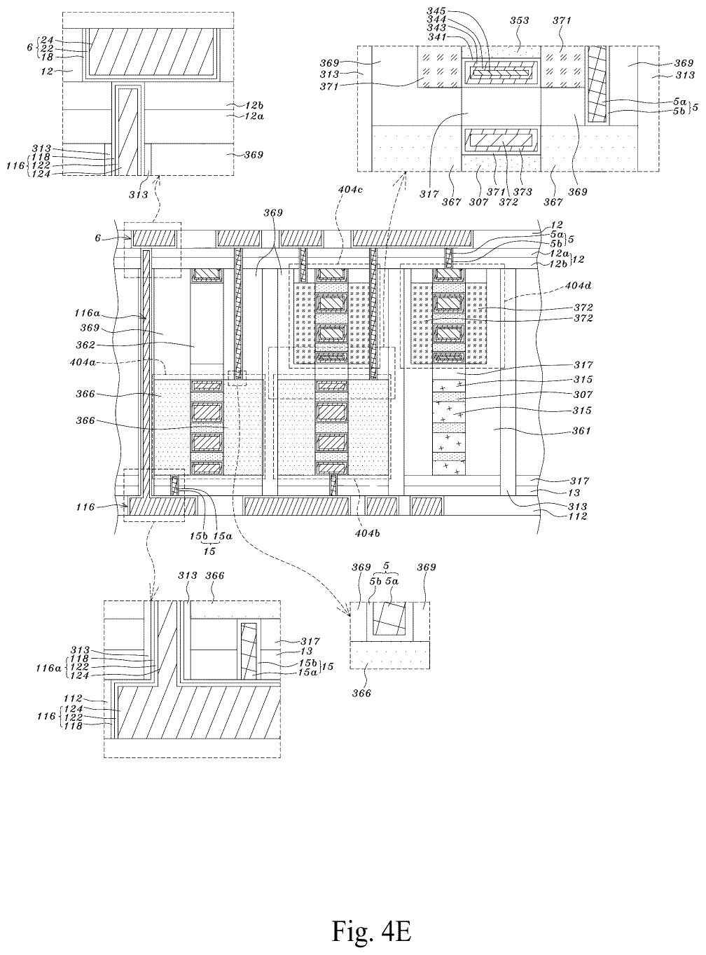

Next, referring to FIGS. 3Q-1, 3Q-2, 3Q-3, 3Q-4 and 3Q-5, FIG. 3Q-1 is a schematically top view showing a process for fabricating a second type of gate-all-around (GAA) transistor in accordance with an embodiment of the present application; FIG. 3Q-2 is a schematically cross-sectional view cut along a cross-sectional line X-X′ of FIG. 3Q-1; FIG. 3Q-3 is a schematically cross-sectional view cut along a cross-sectional line Y-Y′ of FIG. 3Q-1; FIG. 3Q-4 is a schematically cross-sectional view cut along a cross-sectional line W-W′ of FIG. 3Q-1; FIG. 3Q-5 is a schematically cross-sectional view cut along a cross-sectional line Z-Z′ of FIG. 3Q-1. Using processes of photolithography and reactive-ion etching (RIE), a vertically-extending gate trench 374a as seen in FIGS. 3Q-1, 3Q-3 and 3Q-5 may be formed from the top surface of the insulating dielectric layer 317 at one of two opposite sides of the part 311a for the gate-all-around (GAA) portion of each of the second and third groups of the transistor sites 311 to an inner of the insulating dielectric layer 317 to expose a sidewall of the layer 308 of hard mask at said one of the two opposite sides of the part 311a for the gate-all-around (GAA) portion of said each of the second and third groups of the transistor sites 311 and expose a vertical surface of a vertically-extending portion of the layer 365 of silicon germanium (SiGe). Further, using processes of photolithography and reactive-ion etching (RIE), a vertically-extending gate trench 374b as seen in FIGS. 3Q-1 and 3Q-4 may be formed from the top surface of the insulating dielectric layer 317 at one of two opposite sides of the part 311a for the gate-all-around (GAA) portion of each of the first group of the transistor sites 311 to an inner of the insulating dielectric layer 317 to expose a sidewall of the layer 308 of hard mask at said one of the two opposite sides of the part 311a for the gate-all-around (GAA) portion of said each of the first group of the transistor sites 311 and expose one of two opposite sidewalls of the layer 362 of filling oxide. Further, using processes of photolithography and reactive-ion etching (RIE), a vertically-extending gate trench 374c as seen in FIGS. 3Q-1 and 3Q-3 may be formed from the top surface of the layer 313 of field oxide at the other of the two opposite sides of the part 311a for the gate-all-around (GAA) portion of said each of the second group of the transistor sites 311 to an inner of the layer 313 of field oxide to expose another sidewall of the layer 308 of hard mask at the other of the two opposite sides of the part 311a for the gate-all-around (GAA) portion of said each of the second group of the transistor sites 311 and expose a sidewall of each of horizontally extending portions of the layer 315 of silicon germanium (SiGe), a sidewall of each of horizontally extending portions of the layer 365 of silicon germanium (SiGe), a sidewall of the insulating dielectric layer 317 horizontally extending between the epitaxial layers 307 and 353 of silicon and a sidewall of each of the epitaxial layers 303, 305, 307, 353, 355 and 357 of silicon. Further, using processes of photolithography and reactive-ion etching (RIE), a vertically-extending gate trench 374d as seen in FIGS. 3Q-1 and 3Q-4 may be formed from the top surface of the layer 313 of field oxide at the other of the two opposite sides of the part 311a for the gate-all-around (GAA) portion of said each of the first group of the transistor sites 311 to an inner of the layer 313 of field oxide to expose another sidewall of the layer 308 of hard mask at the other of the two opposite sides of the part 311a for the gate-all-around (GAA) portion of said each of the first group of the transistor sites 311 and expose the other of the two opposite sidewalls of the layer 362 of filling oxide, a sidewall of each of horizontally extending portions of the layer 315 of silicon germanium (SiGe), a sidewall of the insulating dielectric layer 317 horizontally extending between the epitaxial layers 307 and 353 of silicon and a sidewall of each of the epitaxial layers 303, 305 and 307 of silicon. Further, using processes of photolithography and reactive-ion etching (RIE), a vertically-extending gate trench 374e as seen in FIGS. 3Q-1 and 3Q-5 may be formed from the top surface of the layer 313 of field oxide at the other of the two opposite sides of the part 311a for the gate-all-around (GAA) portion of said each of the third groups of the transistor sites 311 to an inner of the layer 313 of field oxide to expose another sidewall of the layer 308 of hard mask at the other of the two opposite sides of the part 311a for the gate-all-around (GAA) portion of said each of the third groups of the transistor sites 311 and expose a sidewall of each of horizontally extending portions of the layer 365 of silicon germanium (SiGe) and a sidewall of each of the epitaxial layers 353, 355 and 357 of silicon.

Next, referring to FIGS. 3R-1, 3R-2, 3R-3, 3R-4 and 3R-5, FIG. 3R-1 is a schematically top view showing a process for fabricating a second type of gate-all-around (GAA) transistor in accordance with an embodiment of the present application; FIG. 3R-2 is a schematically cross-sectional view cut along a cross-sectional line X-X′ of FIG. 3R-1; FIG. 3R-3 is a schematically cross-sectional view cut along a cross-sectional line Y-Y′ of FIG. 3R-1; FIG. 3R-4 is a schematically cross-sectional view cut along a cross-sectional line W-W′ of FIG. 3R-1; FIG. 3R-5 is a schematically cross-sectional view cut along a cross-sectional line Z-Z′ of FIG. 3R-1. For the part 311a for the gate-all-around (GAA) portion of each of the first and second groups of transistor sites 311 as seen in FIGS. 3R-1, 3R-2, 3R-3 and 3R-4, the layer 315 of silicon germanium (SiGe) may be removed by a process of isotropic selective etching, such as wet etching using a mixture of hydrogen peroxide (H₂O₂) and ammonium hydroxide (NH₄OH) as an etchant, through the vertically-extending gate trench 374d for each of the first group of transistor sites 311 or through the vertically-extending gate trench 374c for each of the second group of transistor sites 311 to form multiple horizontally-extending gate trenches 374f each between neighboring two of the epitaxial layers 303, 305 and 307 of silicon or between the epitaxial layer 303 of silicon and the insulating dielectric layer 317 vertically under the epitaxial layer 303 of silicon or between the epitaxial layer 307 of silicon and the insulating dielectric layer 317 vertically over the epitaxial layer 307 of silicon. For the part 311a for the gate-all-around (GAA) portion of each of the second and third groups of transistor sites 311 as seen in FIGS. 3R-1, 3R-2, 3R-3 and 3R-5, the layer 365 of silicon germanium (SiGe) may be removed by a process of isotropic selective etching, such as wet etching using a mixture of hydrogen peroxide (H₂O₂) and ammonium hydroxide (NH₄OH) as an etchant, through the vertically-extending gate trenches 374a and 374c for each of the second group of transistor sites 311 or through the vertically-extending gate trenches 374a and 374e for each of the third group of transistor sites 311 to form multiple horizontally-extending gate trenches 374g each between neighboring two of the epitaxial layers 353, 355 and 357 of silicon or between the epitaxial layer 353 of silicon and the insulating dielectric layer 317 vertically under the epitaxial layer 353 of silicon. Next, for the part 311a for the gate-all-around (GAA) portion of each of the second and third groups of transistor sites 311 as seen in FIGS. 3R-1, 3R-2, 3R-3 and 3R-5, the layer 308 of hard mask may be removed to form a horizontally-extending gate trench 374h over the top surface of the epitaxial layer 357 of silicon. For the part 311a for the gate-all-around (GAA) portion of each of the first group of transistor sites 311 as seen in FIGS. 3R-1, 3R-2 and 3R-4, the layer 308 of hard mask may be removed to form a horizontally-extending gate trench 374i over a top surface of the layer 362 of filling oxide.

Referring to FIGS. 3R-1, 3R-2 and 3R-4, the vertically-extending gate trench 374d and horizontally-extending gate trenches 374f at each of the first group of transistor sites 311 may be formed for a first transistor space and around each of the epitaxial layers 303, 305 and 307 of silicon and communicate with one another. Thereby, the epitaxial layers 303, 305 and 307 of silicon in said each of the first group of transistor sites 311 may have the top and bottom surfaces and two opposite sidewalls to be exposed by the first transistor space, the layer 366 of in-situ doping selective epitaxial silicon in said each of the first group of transistor sites 311 may have two opposite inner sidewalls, facing to each other, to be exposed by the first transistor space, the insulating dielectric layer 117 at said each of the first group of transistor sites 311 may have a lower inner sidewall to be exposed by the first transistor space and the layer 113 of field oxide at said each of the first group of transistor sites 311 may have a lower inner sidewall, opposite to the lower inner sidewall of the insulating dielectric layer 117 thereat, to be exposed by the first transistor space.

Referring to FIGS. 3R-1, 3R-2 and 3R-3, the vertically-extending gate trench 374c and horizontally-extending gate trenches 374f at each of the second group of transistor sites 311 may be formed for a second transistor space and around each of the epitaxial layers 303, 305 and 307 of silicon and communicate with one another. Thereby, the epitaxial layers 303, 305 and 307 of silicon in said each of the second group of transistor sites 311 may have the top and bottom surfaces and two opposite sidewalls to be exposed by the second transistor space, the layer 367 of in-situ doping selective epitaxial silicon in said each of the second group of transistor sites 311 may have two opposite inner sidewalls, facing to each other, to be exposed by the second transistor space, the insulating dielectric layer 117 at said each of the second group of transistor sites 311 may have a lower inner sidewall to be exposed by the second transistor space and the layer 113 of field oxide at said each of the second group of transistor sites 311 may have a lower inner sidewall, opposite to the lower inner sidewall of the insulating dielectric layer 117 thereat, to be exposed by the second transistor space.

Referring to FIGS. 3R-1, 3R-2 and 3R-3, the vertically-extending gate trenches 374a and 374c and horizontally-extending gate trenches 374g and 374h at each of the second group of transistor sites 311 may be formed for a third transistor space and around each of the epitaxial layers 353, 355 and 357 of silicon and communicate with one another. Thereby, the epitaxial layers 353, 355 and 357 of silicon in said each of the second group of transistor sites 311 may have the top and bottom surfaces and two opposite sidewalls to be exposed by the third transistor space, the layer 371 of in-situ doping selective epitaxial silicon in said each of the second group of transistor sites 311 may have two opposite inner sidewalls, facing to each other, to be exposed by the third transistor space, the insulating dielectric layer 117 at said each of the second group of transistor sites 311 may have an upper inner sidewall to be exposed by the third transistor space and the layer 113 of field oxide at said each of the second group of transistor sites 311 may have an upper inner sidewall, opposite to the upper inner sidewall of the insulating dielectric layer 117 thereat, to be exposed by the third transistor space.

Referring to FIGS. 3R-1, 3R-2 and 3R-5, the vertically-extending gate trenches 374a and 374e and horizontally-extending gate trenches 374g and 374h at each of the third group of transistor sites 311 may be formed for a fourth transistor space and around each of the epitaxial layers 353, 355 and 357 of silicon and communicate with one another. Thereby, the epitaxial layers 353, 355 and 357 of silicon in said each of the third group of transistor sites 311 may have the top and bottom surfaces and two opposite sidewalls to be exposed by the fourth transistor space, the layer 372 of in-situ doping selective epitaxial silicon in said each of the third group of transistor sites 311 may have two opposite inner sidewalls, facing to each other, to be exposed by the fourth transistor space, the insulating dielectric layer 117 at said each of the third group of transistor sites 311 may have an inner sidewall to be exposed by the fourth transistor space and the layer 113 of field oxide at said each of the third group of transistor sites 311 may have an inner sidewall, opposite to the inner sidewall of the insulating dielectric layer 117 thereat, to be exposed by the fourth transistor space.

Next, referring to FIGS. 3S-1, 3S-2, 3S-3, 3S-4 and 3S-5, FIG. 3S-1 is a schematically top view showing a process for fabricating a second type of gate-all-around (GAA) transistor in accordance with an embodiment of the present application; FIG. 3S-2 is a schematically cross-sectional view cut along a cross-sectional line X-X′ of FIG. 3S-1; FIG. 3S-3 is a schematically cross-sectional view cut along a cross-sectional line Y-Y′ of FIG. 3S-1; FIG. 3S-4 is a schematically cross-sectional view cut along a cross-sectional line W-W of FIG. 3S-1; FIG. 3S-5 is a schematically cross-sectional view cut along a cross-sectional line Z-Z′ of FIG. 3S-1. Using a process of atomic layer deposition (ALD), an insulating dielectric layer 341 may be deposited in each of the first transistor spaces, surrounding each of the epitaxial layers 303, 305 and 307 of silicon in each of the first group of transistor sites 311 and on and in contact with the exposed top and bottom surfaces and exposed two opposite sidewalls of each of the epitaxial layers 303, 305 and 307 of silicon in said each of the first group of transistor sites 311, the exposed two opposite inner sidewalls of the layer 366 of in-situ doping selective epitaxial silicon in said each of the first group of transistor sites 311, the exposed lower inner sidewall of the insulating dielectric layer 317 at said each of the first group of transistor sites 311 and the exposed lower inner sidewall of the layer 313 of field oxide at said each of the first group of transistor sites 311; further, the insulating dielectric layer 341 may be deposited on and in contact with the top surface and two opposite sidewalls of the layer 362 of filling oxide, an exposed upper inner sidewall of the insulating dielectric layer 317 at said each of the first group of transistor sites 311 and an exposed upper inner sidewall of the layer 313 of field oxide at said each of the first group of transistor sites 311; further, the insulating dielectric layer 341 may be deposited in each of the second transistor spaces, surrounding each of the epitaxial layers 303, 305 and 307 of silicon in each of the second group of transistor sites 311 and on and in contact with the exposed top and bottom surfaces and exposed two opposite sidewalls of each of the epitaxial layers 303, 305 and 307 of silicon in said each of the second group of transistor sites 311, the exposed two opposite inner sidewalls of the layer 367 of in-situ doping selective epitaxial silicon in said each of the second group of transistor sites 311, the exposed inner sidewall of the insulating dielectric layer 317 at said each of the second group of transistor sites 311 and the exposed inner sidewall of the layer 313 of field oxide at said each of the second group of transistor sites 311; further, the insulating dielectric layer 341 may be deposited in each of the third transistor spaces, surrounding each of the epitaxial layers 353, 355 and 357 of silicon in each of the second group of transistor sites 311 and on and in contact with the exposed top and bottom surfaces and exposed two opposite sidewalls of each of the epitaxial layers 353, 355 and 357 of silicon in said each of the second group of transistor sites 311, the exposed two opposite inner sidewalls of the layer 371 of in-situ doping selective epitaxial silicon in said each of the second group of transistor sites 311, the exposed upper inner sidewall of the insulating dielectric layer 317 at said each of the second group of transistor sites 311 and the exposed upper inner sidewall of the layer 313 of field oxide at said each of the second group of transistor sites 311; further, the insulating dielectric layer 341 may be deposited in each of the fourth transistor spaces, surrounding each of the epitaxial layers 353, 355 and 357 of silicon in each of the third group of transistor sites 311 and on and in contact with the exposed top and bottom surfaces and exposed two opposite sidewalls of each of the epitaxial layers 353, 355 and 357 of silicon in said each of the third group of transistor sites 311, the exposed two opposite inner sidewalls of the layer 372 of in-situ doping selective epitaxial silicon in said each of the third group of transistor sites 311, the exposed inner sidewall of the insulating dielectric layer 317 at said each of the third group of transistor sites 311 and the exposed inner sidewall of the layer 313 of field oxide at said each of the third group of transistor sites 311; further, the insulating dielectric layer 341 may be deposited on a planar surface composed of the top surface of the insulating dielectric layer 317, the top surface of the layer 313 of field oxide and the top surface of each of the layers 361, 369 and 373 of filing oxide. The insulating dielectric layer 341 may have a high dielectric constant, such as hafnium oxide (HfO₂) or tantalum oxide (Ta₂O₃). Next, using a process of atomic layer deposition (ALD), a layer 343 of work function metal may be deposited in said each of the first, second, third and fourth transistor spaces, on exposed surface of the insulating dielectric layer 341 and over the planar surface composed of the top surface of the insulating dielectric layer 317, the top surface of the layer 313 of field oxide and the top surface of each of the layers 361, 369 and 373 of filing oxide. For example, the layer 343 of work function metal may be formed by depositing, using a process of atomic layer deposition (ALD), a first layer 343a of titanium nitride (TiN) having a thickness less than 1 nanometer in said each of the first, second, third and fourth transistor spaces, on the exposed surface of the insulating dielectric layer 341 and over the planar surface, followed by depositing, using a process of atomic layer deposition (ALD), a layer 343b of tantalum nitride (TaN) having a thickness less than 1 nanometer in said each of the first, second, third and fourth transistor spaces, on the first layer 343a of titanium nitride (TiN) thereof and over the planar surface, followed by depositing, using a process of atomic layer deposition (ALD), a second layer 343c of titanium nitride (TiN) having a thickness between 1 and 5 nanometers in said each of the first, second, third and fourth transistor spaces, on the layer 343b of tantalum nitride (TaN) thereof and over the planar surface. Next, using a process of atomic layer deposition (ALD), physical vapor deposition (PVD) and/or chemical vapor deposition (CVD), a metal layer 342, such as an aluminum alloy, an aluminum-copper alloy or an aluminum-titanium alloy, may be deposited in said each of the first, second, third and fourth transistor spaces, on the exposed surface of the layer 43 of work function metal and over the planar surface composed of the top surface of the insulating dielectric layer 317, the top surface of the layer 313 of field oxide and the top surface of each of the layers 361, 369 and 373 of filing oxide. Next, the metal layer 342 in each of the third and fourth transistor spaces and over the planar surface may be removed by a process of wet etching using hydrogen chloride (HCl) as an etchant to expose a surface layer of the layer 343 of work function metal, such as the second layer 343c of titanium nitride (TiN) for the example as above mentioned. Next, the surface layer of the layer 343 of work function metal in each of the third and fourth transistor spaces and over the planar surface may be removed by a process of isotropic selective etching, such as wet etching using a mixture of hydrogen peroxide (H₂O₂) and ammonium hydroxide (NH₄OH) as an etchant, to expose an inner layer of the layer 343 of work function metal, such as the layer 343b of tantalum nitride (TaN) thereof for the example as above mentioned.

Next, referring to FIGS. 3T-1, 3T-2, 3T-3, 3T-4 and 3T-5, FIG. 3T-1 is a schematically top view showing a process for fabricating a second type of gate-all-around (GAA) transistor in accordance with an embodiment of the present application; FIG. 3T-2 is a schematically cross-sectional view cut along a cross-sectional line X-X′ of FIG. 3T-1; FIG. 3T-3 is a schematically cross-sectional view cut along a cross-sectional line Y-Y′ of FIG. 3T-1; FIG. 3T-4 is a schematically cross-sectional view cut along a cross-sectional line W-W′ of FIG. 3T-1; FIG. 3T-5 is a schematically cross-sectional view cut along a cross-sectional line Z-Z′ of FIG. 3T-1. Using a process of atomic layer deposition (ALD), a layer 344 of work function may be deposited in each of the third and fourth transistor spaces, on exposed surface of the layer 343 of work function metal, i.e., the layer 343b of tantalum nitride (TaN) thereof, over the planar surface composed of the top surface of the insulating dielectric layer 317, the top surface of the layer 313 of field oxide and the top surface of each of the layers 361, 369 and 373 of filing oxide. For example, the layer 344 of work function may be may be made of titanium nitride (TiN), tantalum nitride (TaN), a titanium-aluminum (TiAl) alloy or tungsten nitride (WN). Next, using a process of atomic layer deposition (ALD), physical vapor deposition (PVD) and/or chemical vapor deposition (CVD), a metal layer 345, such as an aluminum alloy, an aluminum-copper alloy or an aluminum-titanium alloy, may be deposited in said each of the third and fourth transistor spaces, on the layer 344 of work function and over the planar surface composed of the top surface of the insulating dielectric layer 317, the top surface of the layer 313 of field oxide and the top surface of each of the layers 361, 369 and 373 of filing oxide. Next, the insulating dielectric layer 341, layer 343 of work function metal, i.e., the first layer 343a of titanium nitride (TiN) and layer 343b of tantalum nitride (TaN) thereof, layer 344 of work function metal and metal layer 345 over each of the vertically-extending gate trenches 374a-374e and horizontally-extending gate trenches 374h and 374, each of the third and fourth transistor spaces and the planar surface composed of the top surface of the insulating dielectric layer 317, the top surface of the layer 313 of field oxide and the top surface of each of the layers 361, 369 and 373 of filing oxide may be removed by a process of chemical-mechanical polishing (CMP) to expose the planar surface to be coplanar with a top surface of the metal layer 345. So far, multiple second type of transistors 404a, 404b, 404c and 404d may be well formed over the semiconductor substrate 2. Each of the second type of transistors 404a, 404b, 404c and 404d may be the first transistor 404a formed in the first transistor space, the second transistor 404b formed in the second transistor space, the third transistor 404c formed in the third transistor space and the fourth transistor 404d formed in the fourth transistor space.

For the first transistor 404a as seen in FIGS. 3T-1, 3T-2 and 3T-4, the metal layer 342 and insulating dielectric layer 341 may be formed respectively as its metal gate and layer of gate oxide, each of the epitaxial layers 303, 305 and 307 of silicon may be formed as its channel, the two layers 366 of in-situ doping selective epitaxial silicon may be formed as its source and drain respectively, wherein each of its channels 303, 305 and 307 may have a channel length, i.e., a first horizontal dimension from one of its source 366 and drain 366 to the other of its source 366 and drain 366, between 8 and 15 nanometers and a vertical thickness between 1 and 20 nanometers, between 2 and 20 nanometers, between 1 and 6 nanometers or between 4 and 10 nanometers, and the combination of the insulating dielectric layer 317 and layer 313 of field oxide may be formed as a layer of field oxide horizontally surrounding the first transistor 404a. For the second transistor 404b as seen in FIGS. 3T-1, 3T-2 and 3T-3, the metal layer 342 and insulating dielectric layer 341 may be formed respectively as its metal gate and layer of gate oxide, each of the epitaxial layers 303, 305 and 307 of silicon may be formed as its channel, the two layers 367 of in-situ doping selective epitaxial silicon may be formed as its source and drain respectively, wherein each of its channels 303, 305 and 307 may have a channel length, i.e., a first horizontal dimension from one of its source 366 and drain 366 to the other of its source 367 and drain 367, between 8 and 15 nanometers and a vertical thickness between 1 and 20 nanometers, between 2 and 20 nanometers, between 1 and 6 nanometers or between 4 and 10 nanometers, and the combination of the insulating dielectric layer 317 and layer 313 of field oxide may be formed as a layer of field oxide horizontally surrounding the second transistor 404b. For the third transistor 404c as seen in FIGS. 3T-1, 3T-2 and 3T-3, the metal layer 345 and insulating dielectric layer 341 may be formed respectively as its metal gate and layer of gate oxide, each of the epitaxial layers 353, 355 and 357 of silicon may be formed as its channel, the two layers 371 of in-situ doping selective epitaxial silicon may be formed as its source and drain respectively, wherein each of its channels 353, 355 and 357 may have a channel length, i.e., a first horizontal dimension from one of its source 371 and drain 371 to the other of its source 367 and drain 367, between 8 and 15 nanometers and a vertical thickness between 1 and 20 nanometers, between 2 and 20 nanometers, between 1 and 6 nanometers or between 4 and 10 nanometers, and the combination of the insulating dielectric layer 317 and layer 313 of field oxide may be formed as a layer of field oxide horizontally surrounding the third transistor 404c. For the fourth transistor 404d as seen in FIGS. 3T-1, 3T-2 and 3T-5, the metal layer 345 and insulating dielectric layer 341 may be formed respectively as its metal gate and layer of gate oxide, each of the epitaxial layers 353, 355 and 357 of silicon may be formed as its channel, the two layers 372 of in-situ doping selective epitaxial silicon may be formed as its source and drain respectively, wherein each of its channels 353, 355 and 357 may have a channel length, i.e., a first horizontal dimension from one of its source 372 and drain 372 to the other of its source 367 and drain 367, between 8 and 15 nanometers and a vertical thickness between 1 and 20 nanometers, between 2 and 20 nanometers, between 1 and 6 nanometers or between 4 and 10 nanometers, and the combination of the insulating dielectric layer 317 and layer 313 of field oxide may be formed as a layer of field oxide horizontally surrounding the fourth transistor 404d. For an example, each of the first and second transistors 404a and 404b may be made as a P-type metal-oxide-semiconductor (MOS) transistor and each of the third and fourth transistors 404c and 404d may be made as a N-type metal-oxide-semiconductor (MOS) transistor. For another example, each of the first and second transistors 404a and 404b may be made as an N-type metal-oxide-semiconductor (MOS) transistor and each of the third and fourth transistors 404c and 404d may be made as a P-type metal-oxide-semiconductor (MOS) transistor.

FIGS. 4A-4C is a schematically cross-sectional view showing a structure of a second type of transistors incorporated in a semiconductor integrated-circuit chip in accordance with an embodiment of the present application. For more elaboration, the second type of transistors 404a, 404b, 404c and 404d may be employed for the transistors 4 as illustrated in FIGS. 1A-1F and 1H-1L. For an element indicated by the same reference number shown in FIGS. 1A-1L, 3A, 3B-1 through 3T-1, 3B-2 through 3T-2, 3B-3 through 3T-3, 3Q-4 through 3T-4, 3Q-5 through 3T-5 and 4A-4C, the specification of the element as seen in each of FIGS. 4A-4C may be referred to that of the element as illustrated in FIGS. 1A-1L, 3A, 3B-1 through 3T-1, 3B-2 through 3T-2, 3B-3 through 3T-3, 3Q-4 through 3T-4 and 3Q-5 through 3T-5. Referring to FIGS. 4A-4C, after the second type of transistors 404a, 404b, 404c and 404d are formed over the semiconductor substrate 2 as illustrated in FIGS. 3A, 3B-1 through 3T-1, 3B-2 through 3T-2, 3B-3 through 3T-3, 3Q-4 through 3T-4 and 3Q-5 through 3T-5 for the semiconductor integrated-circuit (IC) wafer 100 to replace the transistors 4 of the semiconductor integrated-circuit (IC) wafer 100 as illustrated in FIGS. 1A-1F, 1H-1L and 1G-1 through 1G-8, the frontside interconnection scheme 20 as illustrated in FIGS. 1A-IF, 1H-1L and 1G-1 through 1G-8 may be formed over and on a frontside planar surface composed of the top, i.e., front, surface of the insulating dielectric layer 317, the top, i.e., front, surface of the layer 313 of field oxide, the top, i.e., front, surface of each of the layers 361, 369 and 373 of filing oxide and the top, i.e., front, surface of the metal layer 345 as seen in FIGS. 3T-1, 3T-2, 3T-3, 3T-4 and 3T-5. For the semiconductor integrated-circuit (IC) wafer 100, each of the first group of frontside contacts 5 of its frontside interconnection scheme 20 as seen in FIG. 1A may be formed in an opening in the innermost one of the insulating dielectric layers 12 of its frontside interconnection scheme 20 and an opening in the layer 373 of filling oxide of one of its third and fourth transistors 404c and 404d and with a bottom surface in contact with a front, i.e., top, surface of the source or drain of said one of its third and fourth transistors 404c and 404d, i.e., the top, i.e., front, surface of one of the layers 371 of in-situ doping selective epitaxial silicon thereof, or a top, i.e., front, surface of a layer of metal silicide in case formed on a top, i.e., front, surface of one of the layers 371 of in-situ doping selective epitaxial silicon thereof, wherein said each of the first group of frontside contacts 5 of its frontside interconnection scheme 20 may include the metal plug 5a in the opening in the innermost one of the insulating dielectric layers 12 of its frontside interconnection scheme 20 and the adhesion barrier layer 5b at a sidewall and bottom of the metal plug 5a thereof, between the metal plug 5a thereof and the front surface of said one of the layers 371 of in-situ doping selective epitaxial silicon and in contact with the front surface of said one of the layers 371 of in-situ doping selective epitaxial silicon or the front surface of the layer of metal silicide in case formed on the front surface of said one of the layers 371 of in-situ doping selective epitaxial silicon. Each of the second group of frontside contacts 5 of its frontside interconnection scheme 20 as seen in FIG. 1A may be formed in an opening in the innermost one of the insulating dielectric layers 12 of its frontside interconnection scheme 20 and with a bottom surface in contact with a top, i.e., front, surface of a topmost, i.e., frontmost, one of multiple horizontally extending portions of a metal gate of one of its third and fourth transistors 404c and 404d, i.e., the top, i.e., front, surface of the metal layer 345 thereof, wherein said each of the second group of frontside contacts 5 of its frontside interconnection scheme 20 may include (1) the metal plug 5a in the opening in the innermost one of the insulating dielectric layers 12 of its frontside interconnection scheme 20, and (2) the adhesion barrier layer 5b at a sidewall and bottom of the metal plug 5a thereof, between the metal plug 5a thereof and the front surface of the frontmost one of the horizontally extending portions of the metal gate of said one of its third and fourth transistors 404c and 404d and in contact with the front surface of the metal layer 345 of said one of its third and fourth transistors 404c and 404d in the frontmost one of the horizontally extending portions of the metal gate thereof.

Referring to FIG. 4B, its frontside interconnection scheme 20 may further include a third group of frontside contacts 5 each in an opening in the innermost one of the insulating dielectric layers 12 of its frontside interconnection scheme 20 and the layer 369 of filling oxide in one of the first group of the transistor sites 311 and with a bottom surface in contact with a front, i.e., top, surface of the source or drain of one of its first transistors 404a, i.e., the top, i.e., front, surface of one of the layers 366 of in-situ doping selective epitaxial silicon thereof, or a top, i.e., front, surface of a layer of metal silicide in case formed on a top, i.e., front, surface of one of the layers 366 of in-situ doping selective epitaxial silicon thereof, wherein said each of the third group of frontside contacts 5 of its frontside interconnection scheme 20 may include (1) the metal plug 5a in the opening in the innermost one of the insulating dielectric layers 12 of its frontside interconnection scheme 20 and the layer 369 of filling oxide in said one of the first group of the transistor sites 311, and (2) the adhesion barrier layer 5b at a sidewall and bottom of the metal plug 5a thereof, between the metal plug 5a thereof and the front surface of said one of the layers 366 of in-situ doping selective epitaxial silicon and in contact with the front surface of said one of the layers 366 of in-situ doping selective epitaxial silicon or the front surface of the layer of metal silicide in case formed on the front surface of said one of the layers 366 of in-situ doping selective epitaxial silicon. Its frontside interconnection scheme 20 may further include a fourth group of frontside contacts 5 each in an opening in the innermost one of the insulating dielectric layers 12 of its frontside interconnection scheme 20, in the layer 373 of filling oxide of one of its third transistors 404c and in the layer 369 of filling oxide in one of the second group of the transistor sites 311 and at a side of one of its third transistors 404c and a side of one of its second transistors 404b under said one of its third transistors 404c and with a side surface in contact with a side surface of the source or drain of said one of its third transistors 404c, i.e., a side surface of one of the layers 371 of in-situ doping selective epitaxial silicon thereof, and a side surface of the source or drain of said one of its second transistors 404b, i.e., a side surface of one of the layers 367 of in-situ doping selective epitaxial silicon thereof, wherein said each of the fourth group of frontside contacts 5 of its frontside interconnection scheme 20 may be used for delivery of power supply or ground reference or for signal transmission and include (1) the metal plug 5a in the opening in the innermost one of the insulating dielectric layers 12 of its frontside interconnection scheme 20 and the layer 369 of filling oxide in said one of the second group of the transistor sites 311 and at the side of said one of its third transistors 404c and the side of said one of its second transistors 404b, and (2) the adhesion barrier layer 5b at a sidewall and bottom of the metal plug 5a thereof, between the metal plug 5a thereof and the side surface of said one of the layers 371 of in-situ doping selective epitaxial silicon, between the metal plug 5a thereof and the side surface of said one of the layers 367 of in-situ doping selective epitaxial silicon and in contact with the side surface of said one of the layers 371 of in-situ doping selective epitaxial silicon and the side surface of said one of the layers 367 of in-situ doping selective epitaxial silicon. For example, the fourth group of frontside contacts 5 may have (1) a first frontside contact 5 coupling the drain of a first one of its third transistors 404c to the drain of a first one of its second transistors 404b vertically under the first one of its third transistors 404c, (2) a second frontside contact 5 coupling the source of a second one of its third transistors 404c to the drain of a second one of its second transistors 404b vertically under the second one of its third transistors 404c, (3) a third frontside contact 5 coupling the drain of a third one of its third transistors 404c to the source of a third one of its second transistors 404b vertically under the third one of its third transistors 404c and (4) a fourth frontside contact 5 coupling the source of a fourth one of its third transistors 404c to the source of a fourth one of its second transistors 404b vertically under the fourth one of its third transistors 404c.

Next, referring to FIGS. 4A-4C, the front surface of the insulating bonding layer 14 of the semiconductor integrated-circuit (IC) wafer 100 may be bonded to the insulating bonding layer 525 of the supporting substrate 591 as illustrated in FIG. 1B to be turned upside down. Next, the semiconductor substrate 2 and layer 319 of silicon germanium (SiGe) of the semiconductor integrated-circuit (IC) wafer 100 may be removed using one or more processes of mechanical polishing, chemical-mechanical polishing (CMP) and/or dry or wet etching such that each of the layer 313 of field oxide and insulating dielectric layer 317 of the semiconductor integrated-circuit (IC) wafer 100 may have a back, i.e., bottom, surface to be exposed, wherein the back surface of the insulating dielectric layer 317 of the semiconductor integrated-circuit (IC) wafer 100 may be recessed from the back surface of the layer 313 of field oxide of the semiconductor integrated-circuit (IC) wafer 100 to form multiple recessed spaces under the back surface of the insulating dielectric layer 317 of the semiconductor integrated-circuit (IC) wafer 100 and horizontally surrounded by the layer 313 of field oxide of the semiconductor integrated-circuit (IC) wafer 100. Next, the semiconductor integrated-circuit (IC) wafer 100 may be further formed with the layer 13 of filling oxide as illustrated in FIGS. 1D and 1E to be turned upside down in each of the recessed spaces and on the bottom surface of the insulating dielectric layer 317 of the semiconductor integrated-circuit (IC) wafer 100, wherein the back surface of the layer 313 of field oxide may be exposed to be coplanar with the back surface of the layer 13 of filling oxide. Next, multiple backside contact holes 150 as illustrated in FIG. 1F may be formed each in and through the layer 13 of filling oxide and insulating dielectric layer 317 of the semiconductor integrated-circuit (IC) wafer 100. Each of the first group of the backside contact holes 150 may expose a back, i.e., bottom, surface of one of the two layers 366 of in-situ doping selective epitaxial silicon of one of the first transistors 404a of the semiconductor integrated-circuit (IC) wafer 100 or a back, i.e., bottom, surface of one of the two layers 367 of in-situ doping selective epitaxial silicon of one of the second transistors 404b of the semiconductor integrated-circuit (IC) wafer 100. Each of the second group of the backside contact holes 150 may be further formed in and through the insulating dielectric layer 341 to expose a bottom, i.e., back, surface of a bottommost, i.e., backmost, one of multiple horizontally extending portions of a metal gate of one of the first and second transistors 404a and 404b of the semiconductor integrated-circuit (IC) wafer 100, i.e., the bottom, i.e., back, surface of the layer 343 of work function metal thereof. Further, a third group of the backside contact holes 150 as seen in FIG. 4C may be further formed each in the layer 369 of filling oxide in one of the second group of the transistor sites 311 and at a side of one of its second transistors 404b and a side of one of its third transistors 404c vertically over said one of its second transistors 404b to expose a side surface of one of the two layers 367 of in-situ doping selective epitaxial silicon of said one of the second transistors 404b and a side surface of one of the two layers 371 of in-situ doping selective epitaxial silicon of said one of the third transistors 404c. A fourth group of the backside contact holes 150 as seen in FIG. 4C may be further formed each in the layer 369 of filling oxide in one of the third group of the transistor sites 311 to expose a bottom, i.e., back, surface of one of the two layers 372 of in-situ doping selective epitaxial silicon of one of the fourth transistors 404d.

Next, referring to FIGS. 4A-4C, the first group of the backside contacts 15 may be formed in the first group of the backside contact holes 150 and the second group of the backside contacts 15 may be formed in the second group of the backside contact holes 150, as illustrated in FIG. 1F to be turned upside down. Further, a third group of the backside contacts 15 may be formed in the third group of the backside contact holes 150 and a fourth group of the backside contacts 15 may be formed in the fourth group of the backside contact holes 150. Each of the first group of the backside contacts 15 may include (1) the metal plug 15a in one of the first group of the backside contact holes 150 and (2) the adhesion barrier layer 15b at a top and sidewall of the metal plug 15a thereof, between the metal plug 15a thereof and a back, i.e., bottom, surface of one of the source and drain of one of the first and second transistors 404a and 404b of the semiconductor integrated-circuit (IC) wafer 100, i.e., the back surface of one of the two layers 366 of in-situ doping selective epitaxial silicon of one of the first transistors 404a thereof or the back surface of one of the two layers 367 of in-situ doping selective epitaxial silicon of one of the second transistors 404b thereof, and in contact with the back surface of said one of the two layers 366 of in-situ doping selective epitaxial silicon or the back surface of said one of the two layers 367 of in-situ doping selective epitaxial silicon. Each of the second group of the backside contacts 15 may include (1) the metal plug 15a in one of the second group of the backside contact holes 150 and (2) the adhesion barrier layer 15b at a top and sidewall of the metal plug 15a thereof, between the metal plug 15a thereof and the back surface of the backmost one of the horizontally extending portions of the metal gate of one of the first and second transistors 404a and 404b of the semiconductor integrated-circuit (IC) wafer 100, i.e., the back surface of the layer 343 of work function metal thereof, and in contact with the back surface of the layer 343 of work function metal of said one of the first and second transistors 404a and 404b at a surface of the backmost one of the horizontally extending portions of the metal gate thereof. Each of the third group of the backside contacts 15 as seen in FIG. 4C may be used for delivery of power supply or ground reference or for signal transmission and include (1) the metal plug 15a in one of the third group of the backside contact holes 150 and (2) the adhesion barrier layer 15b at a top and sidewall of the metal plug 15a thereof, between the metal plug 15a thereof and the side surface of one of the two layers 367 of in-situ doping selective epitaxial silicon of one of the second transistors 404b, between the metal plug 15a thereof and the side surface of one of the two layers 371 of in-situ doping selective epitaxial silicon of one of the third transistors 404c vertically over said one of the second transistors 404b and in contact with the side surface of said one of the two layers 367 of in-situ doping selective epitaxial silicon and the side surface of said one of the two layers 371 of in-situ doping selective epitaxial silicon. Each of the fourth group of the backside contacts 15 as seen in FIG. 4C may include (1) the metal plug 15a in one of the fourth group of the backside contact holes 150 and (2) the adhesion barrier layer 15b at a top and sidewall of the metal plug 15a thereof, between the metal plugs 15a thereof and a back, i.e., bottom, surface of one of the source and drain of one of the fourth transistors 404d of the semiconductor integrated-circuit (IC) wafer 100, i.e., the back surface of one of the two layers 372 of in-situ doping selective epitaxial silicon of one of the fourth transistors 404d, and in contact with the back surface of said one of the two layers 372 of in-situ doping selective epitaxial silicon. Each of the third and fourth groups of the backside contacts 15 may have a bottom, i.e., back, surface, i.e., a bottom, i.e., back, surface of the metal plug 15a thereof, coplanar with the back surface of each of the first and second groups of the backside contacts 15, i.e., the back, surface of the metal plug 15a thereof, the back surface of the layer 13 of filling oxide and the back surface of the layer 3a of field oxide. The following processes may be performed as illustrated in FIGS. 1H-IL to form any type of the first, second and third types of semiconductor integrated-circuit (IC) chip 10, wherein the interconnection metal layer 116 may be further formed on and in contact with the back surface of each of the third and fourth groups of the backside contacts 15, wherein the first portion of the adhesion metal layer 118 of the interconnection metal layer 116 may be further between each of the first portions of the copper layer 124 of the interconnection metal layer 116 and the back surface of one of the third and fourth groups of its backside contacts 15 and in contact with the back surface of one of the third and fourth groups of its backside contacts 15, and alternatively, the first portion of the adhesion metal layer 118 of the interconnection metal layer 116 may be further between each of the first portions of the tungsten layer of the interconnection metal layer 116 and the back surface of one of the third and fourth groups of its backside contacts 15 and in contact with the back surface of one of the third and fourth groups of its backside contacts 15. The interconnection metal layer 116 may be further formed with multiple through insulator vias (TIVs) 116a each in one of the openings 112b in and through either of the layer 313 of field oxide and insulating dielectric layer 317 horizontally surrounding each of the first, second, third and fourth transistors 404a, 404b, 404c and 404d and in and through the innermost one of the insulating dielectric layers 12 of the frontside interconnection scheme 20 and for delivery of power supply or ground reference or for signal transmission, wherein each of the layer 313 of field oxide and insulating dielectric layer 317 may have a vertical thickness between 0.05 and 5 micrometers, between 0.05 and 2 micrometers or between 0.1 and 0.5 micrometers. Thereby, each of the through insulator vias (TIVs) 116a may have a horizontal dimension less than or equal to 0.5 or 0.1 micrometers. A ratio of a distance d2, which is from a sidewall of one of the through insulator vias (TIVs) 116a to one of its first, second, third and fourth transistors 404a, 404b, 404c and 404d adjacent to said one of the through insulator vias (TIVs) 116a, to the horizontal dimension of said one of the through insulator vias (TIVs) 116a may be greater than or equal to 0.5, 1 or 2. The distance d2 may be greater than a thickness of a lining insulating layer of a conventional through silicon via (TSV). The distance d2 may be greater than or equal to a half of the horizontal dimension of said one of the through insulator vias (TIVs) 116a.

Alternatively, FIG. 4D is a schematically cross-sectional view showing a structure of a second type of transistors incorporated in a semiconductor integrated-circuit chip in accordance with another embodiment of the present application. The structure as illustrated in FIG. 4D is similar to the structure as illustrated in FIG. 4A. For an element indicated by the same reference number shown in FIGS. 1A-1L, 3A, 3B-1 through 3T-1, 3B-2 through 3T-2, 3B-3 through 3T-3, 3Q-4 through 3T-4, 3Q-5 through 3T-5 and 4A-4D, the specification of the element as seen in FIG. 4D may be referred to that of the element as illustrated in FIGS. 1A-1L, 3A, 3B-1 through 3T-1, 3B-2 through 3T-2, 3B-3 through 3T-3, 3Q-4 through 3T-4, 3Q-5 through 3T-5 and 4A-4C. Referring to FIG. 4D, any type of the first, second and third types of semiconductor integrated-circuit (IC) chip 10 may be provided with a first group of its third transistors 404c having the same structure as illustrated in FIGS. 4A-4C and a second group of its third transistors 404c as illustrated in FIG. 4D. Referring to FIG. 4D, the second group of its third transistors 404c may be provided with the two layers 371 of in-situ doping selective epitaxial silicon, one of which may have a horizontal thickness, i.e., width, greater than that of one of the two layers 367 of in-situ doping selective epitaxial silicon of one of its second transistors 404b vertically under said one of the two layers 371 of in-situ doping selective epitaxial silicon and have a sidewall in contact with an inner sidewall of its layer 313 of field oxide. A fifth group of the backside contact holes 150 may be further formed each in the layer 369 of filling oxide in one of the second group of the transistor sites 311 and at a side of one of its second transistors 404b to expose a side surface and optionally a bottom, i.e., back, surface (not shown in FIG. 4D) of one of the two layers 367 of in-situ doping selective epitaxial silicon of said one of its second transistors 404b and a bottom, i.e., back, surface of one of the two layers 371 of in-situ doping selective epitaxial silicon of one of the second group of its third transistors 404c vertically over said one of its second transistors 404b. Further, a fifth group of the backside contacts 15 may be formed in the fifth group of the backside contact holes 150. Each of the fifth group of the backside contacts 15 may include (1) the metal plug 15a in one of the fifth group of the backside contact holes 150 and (2) the adhesion barrier layer 15b at a top and sidewall of the metal plug 15a thereof, optionally between the metal plug 15a thereof and the back surface of one of the two layers 367 of in-situ doping selective epitaxial silicon of one of its second transistors 404b (not shown in FIG. 4D), between the metal plug 15a thereof and the side surface of said one of the two layers 367 of in-situ doping selective epitaxial silicon, between the metal plug 15a thereof and the back surface of one of the two layers 371 of in-situ doping selective epitaxial silicon of one of the second group of its third transistors 404c vertically over said one of the two layers 367 of in-situ doping selective epitaxial silicon and in contact with the back and side surfaces of said one of the two layers 367 of in-situ doping selective epitaxial silicon and the back surface of said one of the two layers 371 of in-situ doping selective epitaxial silicon. Each of the fifth groups of the backside contacts 15 may have a bottom, i.e., back, surface, i.e., a bottom, i.e., back, surface of the metal plug 15a thereof, coplanar with the back surface of each of the first, second, third and fourth groups of the backside contacts 15, i.e., the back, surface of the metal plug 15a thereof, the back surface of the layer 13 of filling oxide and the back surface of the layer 3a of field oxide. In this case, the interconnection metal layer 116 may be further formed on and in contact with the back surface of each of the fifth group of the backside contacts 15.

Alternatively, FIG. 4E is a schematically cross-sectional view showing a structure of a second type of transistors incorporated in a semiconductor integrated-circuit chip in accordance with another embodiment of the present application. The structure as illustrated in FIG. 4E is similar to the structure as illustrated in FIGS. 4A-4C. For an element indicated by the same reference number shown in FIGS. 1A-1L, 3A, 3B-1 through 3T-1, 3B-2 through 3T-2, 3B-3 through 3T-3, 3Q-4 through 3T-4, 3Q-5 through 3T-5, 4A-4C and 4E, the specification of the element as seen in FIG. 4E may be referred to that of the element as illustrated in FIGS. 1A-1L, 3A, 3B-1 through 3T-1, 3B-2 through 3T-2, 3B-3 through 3T-3, 3Q-4 through 3T-4, 3Q-5 through 3T-5 and 4A-4C. The difference from the structures as illustrated in FIGS. 4A-4C is that for any type of the first, second and third types of semiconductor integrated-circuit (IC) chip 10 each of its first transistors 404a as seen in FIG. 4E may be provided with the two layers 366 of in-situ doping selective epitaxial silicon each having a horizontal thickness, i.e., width, greater than that of each of the two layers 371 of in-situ doping selective epitaxial silicon of each of its third transistors 404c and that of each of the two layers 372 of in-situ doping selective epitaxial silicon of each of its fourth transistors 404d and having a sidewall in contact with an inner sidewall of its layer 313 of field oxide, and each of its second transistors 404b as seen in FIG. 4E may be provided with the two layers 367 of in-situ doping selective epitaxial silicon each having a horizontal thickness, i.e., width, greater than that of each of the two layers 371 of in-situ doping selective epitaxial silicon of each of its third transistors 404c and that of each of the two layers 372 of in-situ doping selective epitaxial silicon of each of its fourth transistors 404d and having a sidewall in contact with an inner sidewall of its layer 313 of field oxide. Further, referring to FIG. 4E, its frontside interconnection scheme 20 may be provided with the fourth group of frontside contacts 5 each in an opening in the innermost one of the insulating dielectric layers 12 of its frontside interconnection scheme 20, in the layer 373 of filling oxide of one of its third transistors 404c and in the layer 369 of filling oxide in one of the second group of the transistor sites 311 and at a side of one of its third transistors 404c and in contact with the front and side surfaces of one of the two layers 371 of in-situ doping selective epitaxial silicon of said one of its third transistors 404c and a top, i.e., front, surface of one of the two layers 367 of in-situ doping selective epitaxial silicon of one of its second transistors 404b vertically under said one of the two layers 371 of in-situ doping selective epitaxial silicon.

### Specification for Semiconductor Integrated-Circuit (IC) Chip for Another Embodiment

### Fourth Type of Semiconductor Integrated-Circuit (IC) Chip

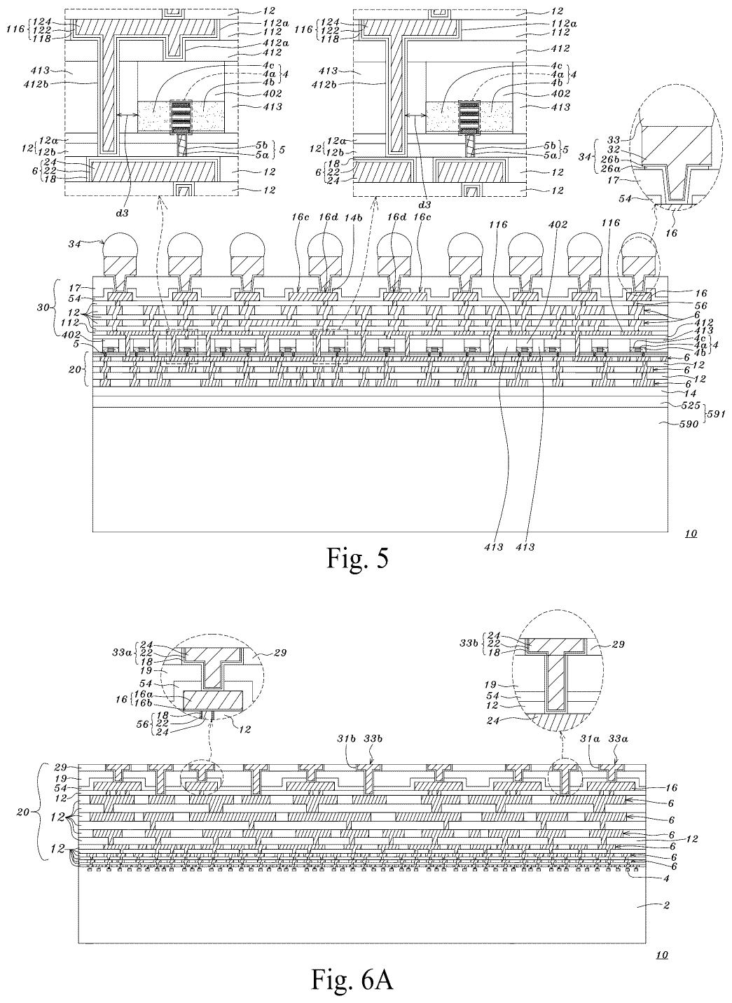

FIG. 5 is a schematically cross-sectional view showing a structure for a semiconductor integrated-circuit (IC) chip in accordance with another embodiment of the present application. The insulating dielectric layers 2s and 3b as seen in FIGS. 1A-1J may not be formed for a fourth type of semiconductor integrated-circuit (IC) chip 10 as seen in FIG. 5. For an element indicated by the same reference number shown in FIGS. 1A-1J and 5, the specification of the element as seen in FIG. 5 may be referred to that of the element as illustrated in FIG. 1A-1J. Referring to FIG. 5, the fourth type of semiconductor integrated-circuit (IC) chip 10 may be provided with a semiconductor substrate 402, such as silicon substrate, wherein its transistors 4 may be formed on a front, i.e., bottom, surface of its semiconductor substrate 402. The fourth type of semiconductor integrated-circuit (IC) chip 10 may be further provided with a layer 413 of field oxide, such as silicon oxide, having a thickness between 0.5 and 5 micrometers, between 0.5 and 3 micrometers or between 0.5 and 2 micrometers horizontally around each of its transistors 4 and each portion of its semiconductor substrate 402, wherein its layer 413 of field oxide may have a back, i.e., top, surface coplanar with a back, i.e., top, surface of its semiconductor substrate 402.

Referring to FIG. 5, for the fourth type of semiconductor integrated-circuit (IC) chip 10, the backside contacts 15 as illustrated in FIGS. 1F-1J may not be formed herein. The fourth type of semiconductor integrated-circuit (IC) chip 10 may be further provided with an insulating dielectric layer 412 between its insulating dielectric layer 112 and a planar surface composed of the back surface of its semiconductor substrate 402 and the back surface of its layer 413 of field oxide and on the planar surface composed of the back surface of its semiconductor substrate 402 and the back surface of its layer 413 of field oxide, wherein its insulating dielectric layer 412 may be made of a layer of silicon oxide or silicon oxycarbide having a vertical thickness between 0.1 and 2 micrometers, between 3 nm and 1,000 nm or between 10 nm and 500 nm, or thinner than 5 nm, 10 nm, 30 nm, 50 nm, 100 nm, 200 nm, 300 nm, 500 nm or 1,000 nm. Alternatively, its insulating dielectric layer 412 may include a material having a low dielectric constant of lower than 3, for example. Alternatively, its insulating dielectric layer 412 may be a composite layer including two silicon-oxynitride layers at a top and bottom thereof and a silicon-oxide layer between the two silicon-oxynitride layers thereof. For the fourth type of semiconductor integrated-circuit (IC) chip 10, its interconnection metal layer 116 may be provided in each of openings 112a in and through its insulating dielectric layer 112, each of openings 412a in and through its insulating dielectric layer 412 and each of openings 412b in and through its insulating dielectric layer 412 and its layer 413 of field oxide and the innermost one of the insulating dielectric layers 12 of its frontside interconnection scheme 20, wherein its interconnection metal layer 116 may include (1) the copper layer 124 in each of the openings 112a, 412a and 412b, (2) the adhesion metal layer 118 at a sidewall and bottom of the copper layer 124 in each of the openings 112a, 412a and 412b, between the copper layer 124 thereof and the back surface of the innermost one of the interconnection metal layers 6 of its frontside interconnection scheme 20, between the copper layer 124 thereof and the back surface of its semiconductor substrate 402 and in contact with the back surface of the innermost one of the interconnection metal layers 6 of its frontside interconnection scheme 20 and the back surface of its semiconductor substrate 402, and (3) the electroplating seed layer 122 between the copper layer 124 and adhesion metal layer 118 thereof. Alternatively, the electroplating seed layer 122 and copper layer 124 of its interconnection metal layer 116 may replaced with a tungsten layer (not shown) in each of the openings 112a, 412a and 412b, wherein the adhesion metal layer 118 of its interconnection metal layer 116 may be at a sidewall and bottom of the tungsten layer of its interconnection metal layer 116 in each of the openings 112a, 412a and 412b, between the tungsten layer of its interconnection metal layer 116 and the back surface of the innermost one of the interconnection metal layers 6 of its frontside interconnection scheme 20, between the tungsten layer of its interconnection metal layer 116 and the back surface of its semiconductor substrate 402 and in contact with the back surface of the innermost one of the interconnection metal layers 6 of its frontside interconnection scheme 20 and the back surface of its semiconductor substrate 402. Thereby, its interconnection metal layer 116 in the openings 412b may be formed as multiple through insulator vias (TIVs) 116a for delivery of power supply or ground reference or for signal transmission, wherein each of the through insulator vias (TIVs) 116a may have a horizontal dimension less than or equal to 0.5 or 0.1 micrometers. A ratio of a distance d3, which is from a sidewall of one of its through insulator vias (TIVs) 116a to one of its transistors 404 adjacent to said one of its through insulator vias (TIVs) 116a, to the horizontal dimension of said one of its through insulator vias (TIVs) 116a may be greater than or equal to 0.5, 1 or 2. The distance d3 may be greater than a thickness of a lining insulating layer of a conventional through silicon via (TSV). The distance d3 may be greater than or equal to a half of the horizontal dimension of said one of its through insulator vias (TIVs) 116a. The fourth type of semiconductor integrated-circuit (IC) chip 10 may be further provided with (1) the backside interconnection scheme 30 on the back surface of its insulating dielectric layer 112 and the back surface of its interconnection metal layer 116 as illustrated in FIG. 1I and (2) the micro-bumps, micro-pillars or micro-pads 34 as illustrated in FIG. 1J.

### Fifth Type of Semiconductor Integrated-Circuit (IC) Chip

Alternatively, a fifth type of semiconductor integrated-circuit (IC) chip 10 may have a similar structure to the fourth type of semiconductor integrated-circuit (IC) chip 10 as illustrated in FIG. 5. The difference therebetween is that the fifth type of semiconductor integrated-circuit (IC) chip 10 may have the first type of micro-bumps, micro-pillars or micro-pads 34 and polymer layer 257 as illustrated in FIG. 1K.

### Sixth Type of Semiconductor Integrated-Circuit (IC) Chip

Alternatively, a sixth type of semiconductor integrated-circuit (IC) chip 10 may have a similar structure to the fourth type of semiconductor integrated-circuit (IC) chip 10 as illustrated in FIG. 5. The difference therebetween is that the sixth type of semiconductor integrated-circuit (IC) chip 10 may not be provided with the micro-bumps, micro-pillars or micro-pads 34 as seen in FIG. 5, but the backside interconnection scheme 30 of the sixth type of semiconductor integrated-circuit (IC) chip 10 may be provided with the insulating dielectric layers 19 and 29 and first and second bonding pads 33a and 33b as illustrated in FIG. 1L.

### Seventh Type of Semiconductor Integrated-Circuit (IC) Chip

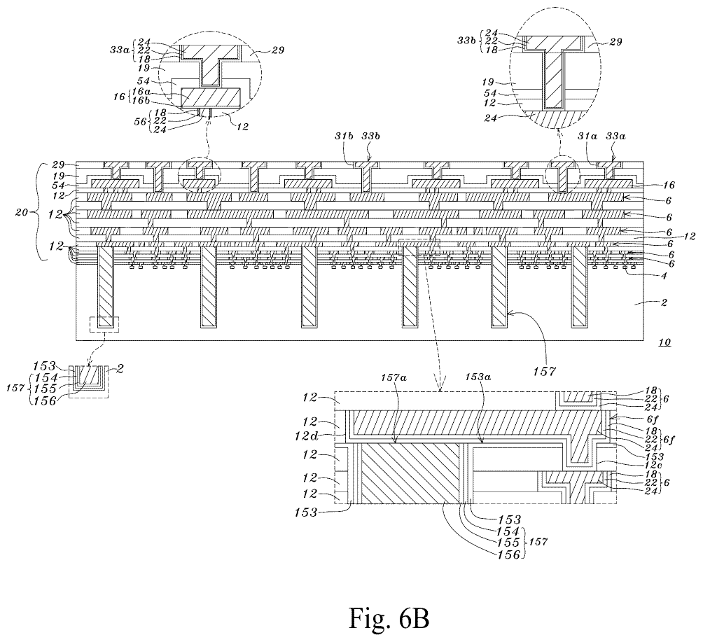

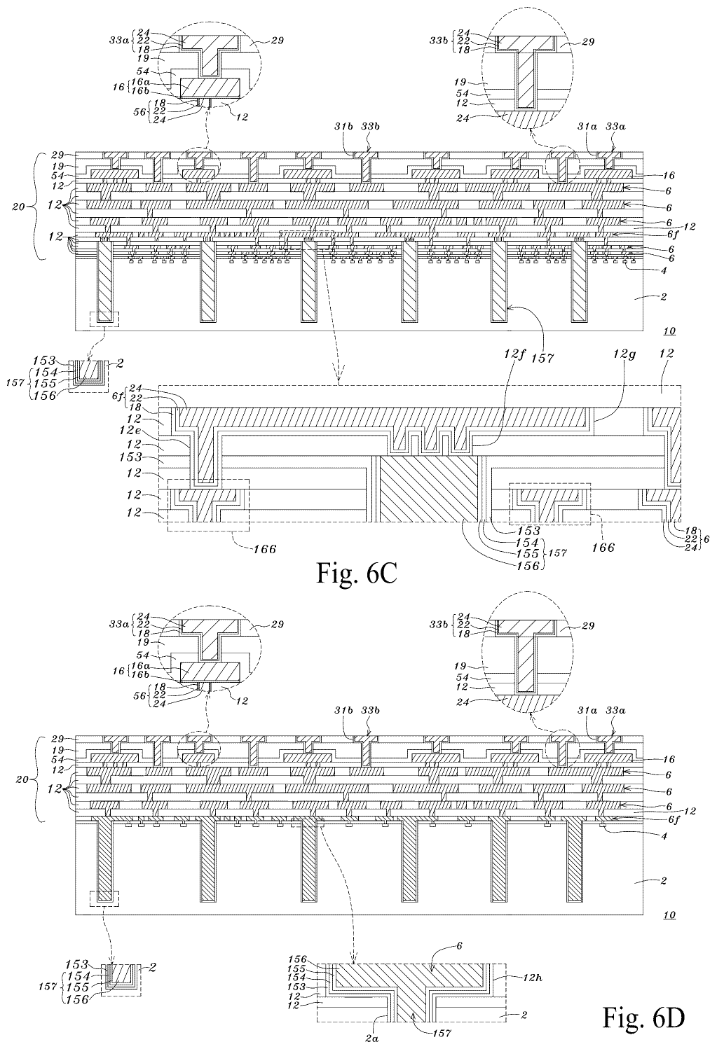

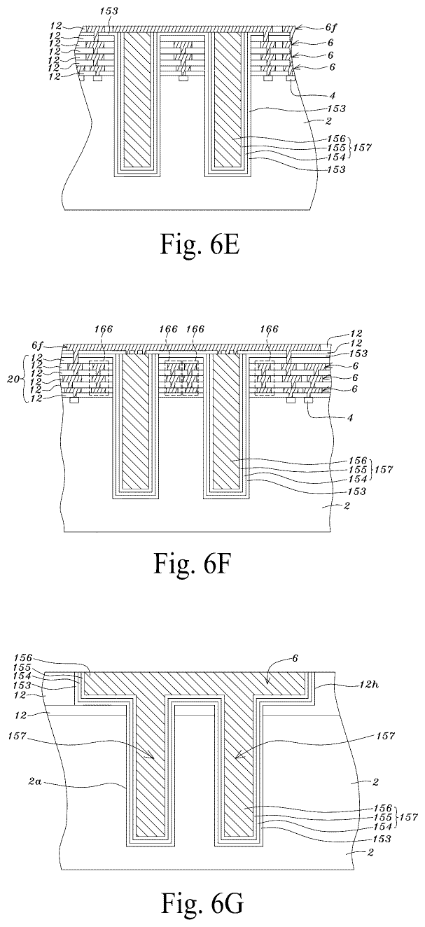

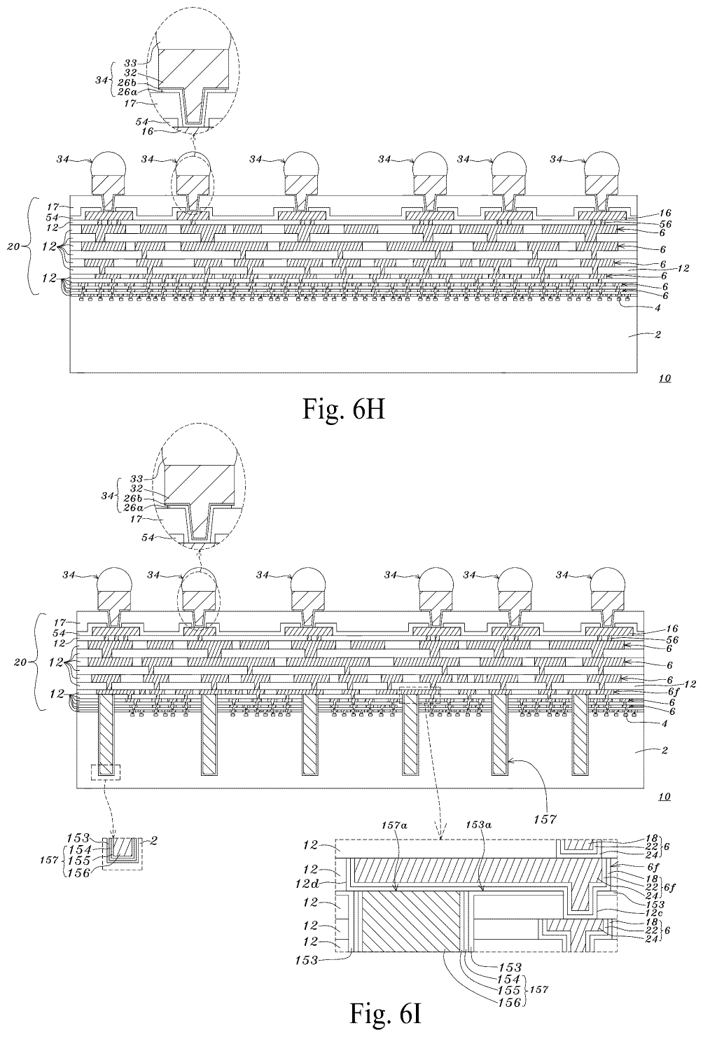

FIG. 6A is a schematically cross-sectional view showing a seventh type of semiconductor integrated-circuit (IC) chip in accordance with an embodiment of the present application. Referring to FIG. 6A, a seventh type of semiconductor integrated-circuit (IC) chip 10 may include (1) a semiconductor substrate 2, such as silicon substrate; (2) multiple semiconductor devices 4, such as planar metal-oxide-semiconductor (MOS) transistors, fin field effective transistors (FINFETs), gate-all-around field effective transistors (GAAFETs) as illustrated in FIGS. 2A, 2B-1 through 2J-1, 2B-2 through 2J-2, 2B-3 through 2J-3, 3A, 3B-1 through 3T-1, 3B-2 through 3T-2, 3B-3 through 3T-3, 3Q-4 through 3T-4, 3Q-5 through 3T-5, or passive devices, at a top surface of its semiconductor substrate 2; and (3) a frontside interconnection scheme 20 over its semiconductor substrate 2, provided with one or more interconnection metal layers 6 coupling to its semiconductor devices 4 and one or more insulating dielectric layers 12 each between neighboring two of the interconnection metal layers 6 of its frontside interconnection scheme 20, wherein each of the interconnection metal layers 6 of its frontside interconnection scheme 20 may have the same specification as that of any of the interconnection metal layers 6 of the frontside interconnection scheme 20 of the third type of semiconductor integrated-circuit (IC) chip 10 as illustrated in FIG. 1A to be turned upside down, and each of the insulating dielectric layers 12 of its frontside interconnection scheme 20 may have the same specification as that of any of the insulating dielectric layers 12 of the frontside interconnection scheme 20 of the third type of semiconductor integrated-circuit (IC) chip 10 as illustrated in FIG. 1A to be turned upside down. Its frontside interconnection scheme 20 may be further provided with (1) multiple plug contacts 56 each in an opening in the topmost one of the insulating dielectric layers 12 thereof and in contact with a top surface of the topmost one of the interconnection metal layers 6 thereof, wherein each of the plug contacts 56 thereof may have the same specification as that of any of the plug contacts 56 of the backside interconnection scheme 30 of the third type of semiconductor integrated-circuit (IC) chip 10 as illustrated in FIG. 1I, (2) an interconnection metal layer 16 on the top surface of the topmost one of the insulating dielectric layers 12 thereof and a top surface of each of the plug contacts 56 thereof, wherein the interconnection metal layer 16 thereof may have the same specification as that of the interconnection metal layer 16 of the backside interconnection scheme 30 of the third type of semiconductor integrated-circuit (IC) chip 10 as illustrated in FIG. 1I, (3) a passivation layer 54 on a top surface and sidewall of the interconnection metal layer 16 thereof and the top surface of the topmost one of the insulating dielectric layers 12 thereof, wherein the passivation layer 54 thereof may have the same specification as that of the passivation layer 54 of the backside interconnection scheme 30 of the third type of semiconductor integrated-circuit (IC) chip 10 as illustrated in FIG. 1I, (4) an insulating dielectric layer 19 on the top surface of the passivation layer 54 thereof, wherein the insulating dielectric layer 19 thereof may have the same specification as that of the insulating dielectric layer 19 of the backside interconnection scheme 30 of the third type of semiconductor integrated-circuit (IC) chip 10 as illustrated in FIG. 1L, (5) an insulating bonding layer 29 on the top surface of the insulating dielectric layer 19 thereof, wherein the insulating bonding layer 29 thereof may have the same specification as that of the insulating bonding layer 29 of the backside interconnection scheme 30 of the third type of semiconductor integrated-circuit (IC) chip 10 as illustrated in FIG. 1L, (6) multiple first bonding pads 33a each in one of the first openings 31a in and through the insulating bonding layer 29, insulating dielectric layer 19 and passivation layer 54 thereof and in contact with a top surface of the interconnection metal layer 16 thereof, wherein each of the first bonding pads 33a thereof may have the same specification as that of the first bonding pads 33a of the backside interconnection scheme 30 of the third type of semiconductor integrated-circuit (IC) chip 10 as illustrated in FIG. 1L, and (7) multiple second bonding pads 33b each in one of the second openings 31b in and through the insulating bonding layer 29, insulating dielectric layer 19 and passivation layer 54 thereof and the topmost one of the insulating dielectric layers 12 thereof and in contact with the top surface of topmost one of the interconnection metal layers 6 thereof, wherein each of the second bonding pads 33b thereof may have the same specification as that of the second bonding pads 33b of the backside interconnection scheme 30 of the third type of semiconductor integrated-circuit (IC) chip 10 as illustrated in FIG. 1L. Each of its first and second bonding pads 33a and 33b may have a top, i.e., front, surface coplanar with a top, i.e., front, surface of its insulating bonding layer 29.

### Eighth Type of Semiconductor Integrated-Circuit (IC) Chip

FIG. 6B is a schematically cross-sectional view showing an eighth type of semiconductor integrated-circuit (IC) chip in accordance with an embodiment of the present application. Referring to FIG. 6B, an eighth type of semiconductor integrated-circuit (IC) chip 10 may have a similar structure to the seventh type of semiconductor IC chip 10 as illustrated in FIG. 6A. For an element indicated by the same reference number shown in FIGS. 6A and 6B, the specification of the element as seen in FIG. 6B may be referred to that of the element as illustrated in FIG. 6A. The difference therebetween is that the eighth type of semiconductor integrated-circuit (IC) chip 10 may further include multiple through silicon vias (TSV) 157 in its semiconductor substrate 2 and one or more of the insulating dielectric layers 12 of its frontside interconnection scheme 20 for a first kind of connection structure for its through silicon vias (TSVs) 157 and its frontside interconnection scheme 20 as seen in FIG. 6B. When the eighth type of semiconductor integrated-circuit (IC) chip 10 is arranged with the first kind of connection structure for its through silicon vias (TSVs) 157 and its frontside interconnection scheme 20, the eighth type of semiconductor IC chip 10 may be a memory IC chip or memory and input/output (I/O) chip, such as static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip. With regard to the eighth type of semiconductor IC chip 10 as seen in FIG. 6B, for the first kind of connection structure for its through silicon vias (TSVs) 157 and its frontside interconnection scheme 20 as seen in FIG. 6B, a middle one of the interconnection metal layers 6 of its frontside interconnection scheme 20 is defined as a reference layer 6f, wherein its frontside interconnection scheme 20 may include a first group of the interconnection metal layers 6 between the reference layer 6f of its frontside interconnection scheme 20 and its semiconductor substrate 2 and a first group of the insulating dielectric layers 12 between the reference layer 6f of its frontside interconnection scheme 20 and its semiconductor substrate 2, wherein each of the first group of the insulating dielectric layers 12 of its frontside interconnection scheme 20 may be between neighboring two of the first group of the interconnection metal layers 6 of its frontside interconnection scheme 20, between the topmost one of the first group of the interconnection metal layers 6 of its frontside interconnection scheme 20 and the reference layer 6f of its frontside interconnection scheme or between the bottommost one of the first group of the interconnection metal layers 6 of its frontside interconnection scheme 20 and its semiconductor substrate 2. Its frontside interconnection scheme 20 may include a second group of the interconnection metal layers 6 between the reference layer 6f of its frontside interconnection scheme 20 and its passivation layer 14 and a second group of the insulating dielectric layers 12 between the reference layer 6f of its frontside interconnection scheme 20 and its passivation layer 14, wherein each of the second group of the insulating dielectric layers 12 of its frontside interconnection scheme 20 may be between neighboring two of the second group of the interconnection metal layers 6 of its frontside interconnection scheme 20 or between the bottommost one of the second group of the interconnection metal layers 6 of its frontside interconnection scheme 20 and the reference layer 6f of its frontside interconnection scheme 20. Each of its through silicon vias (TSV) 157 may couple to one or more of its semiconductor devices 4, such as transistors, through the reference layer 6f of its frontside interconnection scheme 20 and each of the first group of the interconnection metal layers 6 of its frontside interconnection scheme 20. Each of the first group of the interconnection metal layers 6 of its frontside interconnection scheme 20 may be thinner than each of the second group of the interconnection metal layers 6 of its frontside interconnection scheme 20. Further, each of its through silicon vias (TSVs) 157 may vertically extend in and through each of the first group of the insulating dielectric layers 12 of its frontside interconnection scheme 20 and in its semiconductor substrate 2 and may have a top surface 157a in contact with a bottom surface of the reference layer 6f of its frontside interconnection scheme 20.

With regard to the eighth type of semiconductor IC chip 10 as seen in FIG. 6B, for the first kind of connection structure for its through silicon vias (TSVs) 157 and its frontside interconnection scheme 20, each of its through silicon vias (TSVs) 157 may have a depth between 3 μm and 200 μm, between 5 μm and 20 μm, between 2 μm and 10 μm, between 1.5 μm and 5 μm or 0.5 μm and 3 μm and a largest transverse dimension, such as diameter or width, between 0.5 μm and 25 μm or 1 μm and 5 μm. Each of its through silicon vias (TSVs) 157 may include (1) an electroplated copper layer 156 having a depth between 3 μm and 200 μm, between 5 μm and 20 μm, between 2 μm and 10 μm, between 1.5 μm and 5 μm or 0.5 μm and 3 μm and a largest transverse dimension, such as diameter or width, between 0.5 μm and 25 μm or 1 μm and 5 μm in its semiconductor substrate 2 and each of the first group of the insulating dielectric layers 12 of its frontside interconnection scheme 20 under the reference layer 6f of its frontside interconnection scheme 20, (2) an adhesion metal layer 154, such as titanium, titanium nitride, tantalum or tantalum nitride, having a thickness between 1 and 50 nanometers, at a sidewall of the electroplated copper layer 156 of its through silicon vias (TSVs) 157, and (3) an electroplating seed layer 155, such as copper, having a thickness between 3 and 200 nanometers, between the electroplated copper layer 156 and adhesion metal layer 154 of its through silicon vias (TSVs) 157. The eighth type of semiconductor IC chip 10 may further include an insulating lining layer 153, such as silicon oxide, silicon oxynitride or silicon nitride, having a thickness between 3 and 200 nanometers or between 5 and 120 nanometers on a bottom surface of the reference layer 6f of its frontside interconnection scheme 20, on a top surface of the topmost one of the first group of the insulating dielectric layers 12 of its frontside interconnection scheme 20, between the bottom surface of the reference layer 6f of its frontside interconnection scheme 20 and the top surface of the topmost one of the first group of the insulating dielectric layers 12 of its frontside interconnection scheme 20, at the sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of each opening in its semiconductor substrate 2 and the outer sidewall of one of its through silicon vias (TSVs) 157. Its insulating lining layer 153 may have a top surface 153a substantially coplanar with the top surface of the electroplated copper layer 156 of each of its through silicon vias (TSVs) 157, i.e., the top surface 157a. The reference layer 6f of its frontside interconnection scheme 20 may have a first portion in each of multiple openings 12c vertically through its insulating lining layer 153 and the topmost one of the first group of the insulating dielectric layers 12 of its frontside interconnection scheme 20 and contacting the top surface of the topmost one of the first group of the interconnection metal layers 6 of its frontside interconnection scheme 20 and a second portion in each of multiple openings 12d in a reference one of the insulating dielectric layers 12 of its frontside interconnection scheme 20 on the top surface 153a of its insulating lining layer 153, wherein the second portion of the reference layer 6f of its frontside interconnection scheme 20 is further over each of the multiple openings 12c and on the top surface 153a of its insulating lining layer 153 and the top surface 157a of each of its through silicon vias (TSVs) 157 and has a top surface substantially coplanar with a top surface of the reference one of the insulating dielectric layers 12 of its frontside interconnection scheme 20. The electroplated copper layer 24 of the reference layer 6f of its frontside interconnection scheme 20 may have a first portion in each of the multiple openings 12c and a second portion in each of the multiple openings 12d, over each of the multiple openings 12c and the top surface 153a of its insulating lining layer 153, and the adhesion metal layer 18 of the reference layer 6f of its frontside interconnection scheme 20 may have a first portion in each of the multiple openings 12c, at a bottom and sidewall of the first portion of the electroplated copper layer 24 of the reference layer 6f of its frontside interconnection scheme 20, between the first portion of the electroplated copper layer 24 of the reference layer 6f of its frontside interconnection scheme 20 and the top surface of the topmost one of the first group of the interconnection metal layers 6 of its frontside interconnection scheme 20 and in contact with the top surface of the topmost one of the first group of the interconnection metal layers 6 of its frontside interconnection scheme 20 and a second portion in each of the multiple openings 12d, on the top surface 153a of its insulating lining layer 153 and the top surface 157a of each of its through silicon vias (TSVs) 157 and at a bottom and sidewall of the second portion of the electroplated copper layer 24 of the reference layer 6f of its frontside interconnection scheme 20, wherein the first portion of the electroplated copper layer 24 of the reference layer 6f of its frontside interconnection scheme 20, the first portion of the adhesion metal layer 18 of the reference layer 6f of its frontside interconnection scheme 20 and the electroplating seed layer 22 between the first portion of the electroplated copper layer 24 of the reference layer 6f of its frontside interconnection scheme 20 and the first portion of the adhesion metal layer 18 of the reference layer 6f of its frontside interconnection scheme 20 may be provided as the first portion of the reference layer 6f of its frontside interconnection scheme 20, and the second portion of the electroplated copper layer 24 of the reference layer 6f of its frontside interconnection scheme 20, the second portion of the adhesion metal layer 18 of the reference layer 6f of its frontside interconnection scheme 20 and the electroplating seed layer 22 between the second portion of the electroplated copper layer 24 of the reference layer 6f of its frontside interconnection scheme 20 and the second portion of the adhesion metal layer 18 of the reference layer 6f of its frontside interconnection scheme 20 may be provided as the second portion of the reference layer 6f of its frontside interconnection scheme 20.

Alternatively, referring to FIG. 6B, when the eighth type of semiconductor IC chip 10 is arranged with the first kind of connection structure for its through silicon vias (TSVs) 157 and its frontside interconnection scheme 20, the eighth type of semiconductor IC chip 10 may be a logic IC chip, such as field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip. In case that the eighth type of semiconductor IC chip 10 is used as the memory IC chip or memory and input/output (I/O)) chip having the first kind of connection structure for its through silicon vias (TSVs) 157 and its frontside interconnection scheme 20, the number of the second group of the interconnection metal layers 6 of its frontside interconnection scheme 20 may be smaller than or equal to 2 or 4 and the number of the first group of the interconnection metal layers 6 of its frontside interconnection scheme 20 may be greater than or equal to 1, 2 or 3. In case that the eighth type of semiconductor IC chip 10 is used as the logic IC chip having the first kind of connection structure for its through silicon vias (TSVs) 157 and its frontside interconnection scheme 20, the number of the second group of the interconnection metal layers 6 of its frontside interconnection scheme 20 may be smaller than or equal to 2 or 5 and the number of the first group of the interconnection metal layers 6 of its frontside interconnection scheme 20 may be greater than or equal to 4, 7 or 10. Alternatively, the eighth type of semiconductor IC chip 10 may be an auxiliary IC chip, such as input/output (I/O) IC chip, control IC chip or power-management integrated-circuit (PMIC) chip, having the first kind of connection structure for its through silicon vias (TSVs) 157 and its frontside interconnection scheme 20.

Alternatively, FIG. 6C is a cross-sectional view showing a second kind of connection structure for through silicon vias (TSVs) and an interconnection scheme in accordance with an embodiment of the present application. When the eighth type of semiconductor IC chip 10 is used as a logic IC chip, such as field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip, the eighth type of semiconductor IC chip 10 may be provided with a second kind of connection structure for its through silicon vias (TSVs) 157 and its frontside interconnection scheme 20 as seen in FIG. 6C instead of the first kind of connection structure for the through silicon vias (TSVs) 157 and the frontside interconnection scheme 20 as seen in FIG. 6B. For an element indicated by the same reference number shown in FIGS. 6B and 6C, the specification of the element as seen in FIG. 6C may be referred to that of the element as illustrated in FIG. 6B unless otherwise mentioned below. The second kind of connection structure for its through silicon vias (TSVs) 157 and its frontside interconnection scheme 20 may have a similar structure to the first kind of connection structure for its through silicon vias (TSVs) 157 and its frontside interconnection scheme 20 as illustrated in FIG. 6B. The difference therebetween is that for the second kind of connection structure for its through silicon vias (TSVs) 157 and its frontside interconnection scheme 20, its insulating lining layer 153, such as silicon oxide, silicon oxynitride or silicon nitride, having a thickness between 3 and 200 nanometers or between 5 and 120 nanometers may be formed on a top surface of the second topmost one of the first group of the insulating dielectric layers 12 of its frontside interconnection scheme 20, at the sidewall of the electroplated copper layer 156 of each of its through silicon vias (TSVs) 157, on an outer sidewall of each of its through silicon vias (TSVs) 157, on an inner sidewall of each opening in its semiconductor substrate 2 and between the inner sidewall of each opening in its semiconductor substrate 2 and the outer sidewall of one of its through silicon vias (TSVs) 157. Its insulating lining layer 153 may have a top surface 153a substantially coplanar with the top surface of the electroplated copper layer 156 of each of its through silicon vias (TSVs) 157, i.e., the top surface 157a. The topmost one of the first group of the insulating dielectric layers 12 of its frontside interconnection scheme 20 may be formed on the top surface 153a of its insulating lining layer 153 and the top surface 157a of each of its through silicon vias (TSVs) 157. The reference layer 6f of its frontside interconnection scheme 20 may have a first portion in each of multiple openings 12e vertically through its insulating lining layer 153 and the topmost one and second topmost one of the first group of the insulating dielectric layers 12 of its frontside interconnection scheme 20 and contacting the top surface of the topmost one of the first group of the interconnection metal layers 6 of its frontside interconnection scheme 20, a second portion in each of multiple openings 12f vertically through the topmost one of the first group of the insulating dielectric layers 12 of its frontside interconnection scheme 20 and contacting the top surface 157a of one of its through silicon vias (TSVs) 157 and a third portion in each of multiple openings 12g in a reference one of the insulating dielectric layers 12 of its frontside interconnection scheme 20 on the topmost one of the first group of the insulating dielectric layers 12 of its frontside interconnection scheme 20, wherein the third portion of the reference layer 6f of its frontside interconnection scheme 20 is further over each of the multiple openings 12e and 12f and on a top surface of the topmost one of the first group of the insulating dielectric layers 12 of its frontside interconnection scheme 20 and has a top surface substantially coplanar with a top surface of the reference one of the insulating dielectric layers 12 of its frontside interconnection scheme 20. The multiple openings 12f may have a number greater than or equal to 1, 2 or 3, for example, over each of its through silicon vias (TSVs) 157. The electroplated copper layer 24 of the reference layer 6f of its frontside interconnection scheme 20 may have a first portion in each of the multiple openings 12e, a second portion in each of the multiple openings 12f and a third portion in each of the multiple openings 12g, over each of the multiple openings 12e and 12f and the top surface of the topmost one of the first group of the insulating dielectric layers 12 of its frontside interconnection scheme 20, and the adhesion metal layer 18 of the reference layer 6f of its frontside interconnection scheme 20 may have a first portion in each of the multiple openings 12e, at a bottom and sidewall of the first portion of the electroplated copper layer 24 of the reference layer 6f of its frontside interconnection scheme 20, between the first portion of the electroplated copper layer 24 of the reference layer 6f of its frontside interconnection scheme 20 and the top surface of the topmost one of the first group of the interconnection metal layers 6 of its frontside interconnection scheme 20 and in contact with the top surface of the topmost one of the first group of the interconnection metal layers 6 of its frontside interconnection scheme 20, a second portion in each of the openings 12f, at a bottom and sidewall of the second portion of the electroplated copper layer 24 of the reference layer 6f of its frontside interconnection scheme 20, between the second portion of the electroplated copper layer 24 of the reference layer 6f of its frontside interconnection scheme 20 and the top surface of each of its through silicon vias (TSVs) 157 and in contact with the top surface of each of its through silicon vias (TSVs) 157, and a third portion in each of the multiple openings 12f, on the top surface of the topmost one of the first group of the insulating dielectric layers 12 of its frontside interconnection scheme 20 and at a bottom and sidewall of the third portion of the electroplated copper layer 24 of the reference layer 6f of its frontside interconnection scheme 20, wherein the first portion of the electroplated copper layer 24 of the reference layer 6f of its frontside interconnection scheme 20, the first portion of the adhesion metal layer 18 of the reference layer 6f of its frontside interconnection scheme 20 and the electroplating seed layer 22 between the first portion of the electroplated copper layer 24 of the reference layer 6f of its frontside interconnection scheme 20 and the first portion of the adhesion metal layer 18 of the reference layer 6f of its frontside interconnection scheme 20 may be provided as the first portion of the reference layer 6f of its frontside interconnection scheme 20; the second portion of the electroplated copper layer 24 of the reference layer 6f of its frontside interconnection scheme 20, the second portion of the adhesion metal layer 18 of the reference layer 6f of its frontside interconnection scheme 20 and the electroplating seed layer 22 between the second portion of the electroplated copper layer 24 of the reference layer 6f of its frontside interconnection scheme 20 and the second portion of the adhesion metal layer 18 of the reference layer 6f of its frontside interconnection scheme 20 may be provided as the second portion of the reference layer 6f of its frontside interconnection scheme 20; the third portion of the electroplated copper layer 24 of the reference layer 6f of its frontside interconnection scheme 20, the third portion of the adhesion metal layer 18 of the reference layer 6f of its frontside interconnection scheme 20 and the electroplating seed layer 22 between the third portion of the electroplated copper layer 24 of the reference layer 6f of its frontside interconnection scheme 20 and the third portion of the adhesion metal layer 18 of the reference layer 6f of its frontside interconnection scheme 20 may be provided as the third portion of the reference layer 6f of its frontside interconnection scheme 20. The first group of the interconnection metal layers 6 of its frontside interconnection scheme 20 may provide a seal ring 166 surrounding each of its through silicon vias (TSVs) 157, wherein the seal ring 166 may couple to a voltage of ground reference. For more elaboration, each of its seal rings 166 may be provided by a ring-shaped portion of each of the first group of the interconnection metal layers 6 of its frontside interconnection scheme 20 stacked and aligned with and coupling to the ring-shaped portion(s) of the other(s) of the first group of the interconnection metal layers 6 of its frontside interconnection scheme 20 to surround one of its through silicon vias (TSVs) 157.

Alternatively, referring to FIG. 6C, when the eighth type of semiconductor IC chip 10 is arranged with the second kind of connection structure for its through silicon vias (TSVs) 157 and its frontside interconnection scheme 20, the eighth type of semiconductor IC chip 10 may be a memory IC chip or memory and input/output (I/O) chip, such as static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip. In case that the eighth type of semiconductor IC chip 10 is used as the memory IC chip or memory and input/output (I/O) chip having the second kind of connection structure for its through silicon vias (TSVs) 157 and its frontside interconnection scheme 20, the number of the second group of the interconnection metal layers 6 of its frontside interconnection scheme 20 may be smaller than or equal to 2 or 4 and the number of the first group of the interconnection metal layers 6 of its frontside interconnection scheme 20 may be greater than or equal to 1, 2 or 3. In case that the eighth type of semiconductor IC chip 10 is used as the logic IC chip having the second kind of connection structure for its through silicon vias (TSVs) 157 and its frontside interconnection scheme 20, the number of the second group of the interconnection metal layers 6 of its frontside interconnection scheme 20 may be smaller than or equal to 2 or 5 and the number of the first group of the interconnection metal layers 6 of its frontside interconnection scheme 20 may be greater than or equal to 4, 7 or 10. The eighth type of semiconductor IC chip 100 may be an auxiliary IC chip, such as input/output (I/O)) IC chip, control IC chip or power-management integrated-circuit (PMIC) chip, having the second kind of connection structure for its through silicon vias (TSVs) 157 and its frontside interconnection scheme 20.

Alternatively, FIG. 6D is a cross-sectional view showing a third kind of connection structure for through silicon vias (TSVs) and an interconnection scheme in accordance with an embodiment of the present application. The eighth type of semiconductor IC chip 10 may be provided with a third kind of connection structure for its through silicon vias (TSVs) 157 and its frontside interconnection scheme 20 as seen in FIG. 6D instead of the first kind of connection structure for the through silicon vias (TSVs) 157 and the frontside interconnection scheme 20 as seen in FIG. 6B. For an element indicated by the same reference number shown in FIGS. 6B and 6D, the specification of the element as seen in FIG. 6D may be referred to that of the element as illustrated in FIG. 6B unless otherwise mentioned below. The third kind of connection structure for its through silicon vias (TSVs) 157 and its frontside interconnection scheme 20 may have a similar structure to the first kind of connection structure for its through silicon vias (TSVs) 157 and its frontside interconnection scheme 20 as illustrated in FIG. 6B. The difference therebetween is that for the third kind of connection structure for its through silicon vias (TSVs) 157 and its frontside interconnection scheme 20, the bottommost one of the interconnection metal layers 6 of its frontside interconnection scheme 20 and each of its through silicon vias (TSVs) 157 may be formed to be integral as a part. For more elaboration, the bottommost one of the interconnection metal layers 6 of its frontside interconnection scheme 20 may have a first portion, formed as its through silicon vias (TSVs) 157, in each of multiple openings 2a in and through a lower one of the insulating dielectric layers 12 of its frontside interconnection scheme 20 and in its semiconductor substrate 2, and a second portion, formed as its metal lines or traces, in each of multiple openings 12h in an upper one of the insulating dielectric layers 12 of its frontside interconnection scheme 20 on the lower one of the insulating dielectric layers 12 of its frontside interconnection scheme 20, wherein the second portion of the bottommost one of the interconnection metal layers 6 of its frontside interconnection scheme 20 is further over each of the multiple openings 2a and a top surface of the lower one of the insulating dielectric layers 12 of its frontside interconnection scheme 20 and has a top surface substantially coplanar with a top surface of the upper one of the insulating dielectric layers 12 of its frontside interconnection scheme 20. The bottommost one of the interconnection metal layers 6 of its frontside interconnection scheme 20 may include (1) an electroplated copper layer 156 in each of the multiple openings 12h and each of the multiple openings 2a, (2) an adhesion metal layer 154 at a bottom and sidewall of each of the multiple openings 12h and a bottom and sidewall of each of the multiple openings 2a, and (3) an electroplating seed layer 155 at the bottom and sidewall of each of the multiple openings 12h and the bottom and sidewall of each of the multiple openings 2a and between the electroplated copper layer 156 and adhesion metal layer 154. The electroplated copper layer 156 of the bottommost one of the interconnection metal layers 6 of its frontside interconnection scheme 20 may have a first portion in each of the multiple openings 2a and a second portion in each of the multiple openings 12h, over each of the multiple openings 2a and the lower one of the insulating dielectric layers 12 of its frontside interconnection scheme 20, and the adhesion metal layer 154 of the bottommost one of the interconnection metal layers 6 of its frontside interconnection scheme 20 may have a first portion in each of the multiple openings 2a and at a bottom and sidewall of the first portion of the electroplated copper layer 156 of the bottommost one of the interconnection metal layers 6 of its frontside interconnection scheme 20 and a second portion in each of the multiple openings 12h, over the lower one of the insulating dielectric layers 12 of its frontside interconnection scheme 20 and at a bottom and sidewall of the second portion of the electroplated copper layer 156 of the bottommost one of the interconnection metal layers 6 of its frontside interconnection scheme 20. The first portion of the electroplated copper layer 156 of the bottommost one of the interconnection metal layers 6 of its frontside interconnection scheme 20, the first portion of the adhesion metal layer 154 of the bottommost one of the interconnection metal layers 6 of its frontside interconnection scheme 20 and the electroplating seed layer 155 between the first portion of the electroplated copper layer 156 of the bottommost one of the interconnection metal layers 6 of its frontside interconnection scheme 20 and the first portion of the adhesion metal layer 154 of the bottommost one of the interconnection metal layers 6 of its frontside interconnection scheme 20 may be provided as the first portion of the bottommost one of the interconnection metal layers 6 of its frontside interconnection scheme 20, and the second portion of the electroplated copper layer 156 of the bottommost one of the interconnection metal layers 6 of its frontside interconnection scheme 20, the second portion of the adhesion metal layer 154 of the bottommost one of the interconnection metal layers 6 of its frontside interconnection scheme 20 and the electroplating seed layer 155 between the second portion of the electroplated copper layer 156 of the bottommost one of the interconnection metal layers 6 of its frontside interconnection scheme 20 and the second portion of the adhesion metal layer 154 of the bottommost one of the interconnection metal layers 6 of its frontside interconnection scheme 20 may be provided as the second portion of the bottommost one of the interconnection metal layers 6 of its frontside interconnection scheme 20. Thereby, the second portion of the bottommost one of the interconnection metal layers 6 of its frontside interconnection scheme 20 may couple each of its through silicon vias (TSVs) 157 to one of its semiconductor devices 4, such as transistors. The first portion of the electroplated copper layer 156 of the bottommost one of the interconnection metal layers 6 of its frontside interconnection scheme 20 may have a depth between 30 and 200 micrometers and a largest transverse dimension, such as diameter or width, between 2 and 20 micrometers or between 4 and 10 micrometers. The second portion of the electroplated copper layer 156 of the bottommost one of the interconnection metal layers 6 of its frontside interconnection scheme 20 may have a thickness between 3 nm and 500 nm. The adhesion metal layer 154 of the bottommost one of the interconnection metal layers 6 of its frontside interconnection scheme 20 may be a titanium (Ti), titanium-nitride (TiN), tantalum (Ta) or tantalum-nitride (TaN) layer having a thickness between 1 and 50 nanometers. The electroplating seed layer 155 of the bottommost one of the interconnection metal layers 6 of its frontside interconnection scheme 20 may be made of copper having a thickness between 3 and 200 nanometers. The eighth type of semiconductor IC chip 10 may further include an insulating lining layer 153, such as thermally grown silicon oxide (SiO₂) and/or CVD silicon nitride (Si₃N₄), at a bottom and sidewall of the first portion of the bottommost one of the interconnection metal layers 6 of its frontside interconnection scheme 20 and a bottom and sidewall of the second portion of the bottommost one of the interconnection metal layers 6 of its frontside interconnection scheme 20. Its insulating lining layer 153 may have a first portion in each of the multiple openings 2a and at the bottom and sidewall of the first portion of the electroplated copper layer 156 of the bottommost one of the interconnection metal layers 6 of its frontside interconnection scheme 20 and between the first portion of the adhesion metal layer 154 of the bottommost one of the interconnection metal layers 6 of its frontside interconnection scheme 20 and an inner surface of said each of the multiple openings 2a and a second portion in each of the multiple openings 12h, over the lower one of the insulating dielectric layers 12 of its frontside interconnection scheme 20, at the bottom and sidewall of the second portion of the electroplated copper layer 156 of the bottommost one of the interconnection metal layers 6 of its frontside interconnection scheme 20 and between the second portion of the adhesion metal layer 154 of the bottommost one of the interconnection metal layers 6 of its frontside interconnection scheme 20 and an inner surface of said each of the multiple openings 12h.

Referring to FIG. 6D, the eighth type of semiconductor IC chip 10 may be a logic IC chip, such as field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip or system-on-chip (SoC) IC chip, having the third kind of connection structure for its through silicon vias (TSVs) 157 and its frontside interconnection scheme 20. Alternatively, the eighth type of semiconductor IC chip 10 may be a memory IC chip or memory and input/output (I/O) chip, such as static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip or ferroelectric random access memory (FRAM) IC chip, having the third kind of connection structure for its through silicon vias (TSVs) 157 and its frontside interconnection scheme 20.

Alternatively, with regard to the eighth type of semiconductor IC chip 10, for the first kind of connection structure for its through silicon vias (TSVs) 157 and its frontside interconnection scheme 20 as seen in FIG. 6E, each two or more of its through silicon vias (TSVs) 157 as seen in FIG. 6E may be arranged as its set of through silicon vias (TSVs) 157 and the second portion of the electroplated copper layer 24 of the reference layer 6f of its frontside interconnection scheme 20 may couple its set of through silicon vias (TSVs) 157. For an element indicated by the same reference number shown in FIGS. 6B and 6E, the specification of the element as seen in FIG. 6E may be referred to that of the element as illustrated in FIG. 6B. For the eighth type of semiconductor IC chip 10 as seen in FIG. 6E, each of its set of through silicon vias (TSVs) 157 may couple to one of its semiconductor devices 4, such as transistors, through, in sequence, the second portion of the electroplated copper layer 24 of the reference layer 6f of its frontside interconnection scheme 20, one of the first portions of the electroplated copper layer 24 of the reference layer 6f of its frontside interconnection scheme 20 and each of the first group of the interconnection metal layers 6 of its frontside interconnection scheme 20.

Alternatively, with regard to the eighth type of semiconductor IC chip 10, for the second kind of connection structure for its through silicon vias (TSVs) 157 and its frontside interconnection scheme 20 as seen in FIG. 6F, each two or more of its through silicon vias (TSVs) 157 as seen in FIG. 6F may be arranged as its set of through silicon vias (TSVs) 157 and the third portion of the electroplated copper layer 24 of the reference layer 6f of its frontside interconnection scheme 20 may couple its set of through silicon vias (TSVs) 157. For an element indicated by the same reference number shown in FIGS. 6C and 6F, the specification of the element as seen in FIG. 6F may be referred to that of the element as illustrated in FIG. 6C. For the eighth type of semiconductor IC chip 10 as seen in FIG. 6F, each of its set of through silicon vias (TSVs) 157 may couple to one of its semiconductor devices 4, such as transistors, through, in sequence, one of the second portions of the electroplated copper layer 24 of the reference layer 6f of its frontside interconnection scheme 20, the third portion of the electroplated copper layer 24 of the reference layer 6f of its frontside interconnection scheme 20, one of the first portions of the electroplated copper layer 24 of the reference layer 6f of its frontside interconnection scheme 20 and each of the first group of the interconnection metal layers 6 of its frontside interconnection scheme 20.

Alternatively, with regard to the eighth type of semiconductor IC chip 10, for the third kind of connection structure for its through silicon vias (TSVs) 157 and its frontside interconnection scheme 20 as seen in FIG. 6G, each two or more of its through silicon vias (TSVs) 157 as seen in FIG. 6G may be arranged as its set of through silicon vias (TSVs) 157 and the second portion of the electroplated copper layer 156 of the bottommost one of the interconnection metal layers 6 of its frontside interconnection scheme 20 may couple its set of through silicon vias (TSVs) 157. For an element indicated by the same reference number shown in FIGS. 6D and 6G, the specification of the element as seen in FIG. 6G may be referred to that of the element as illustrated in FIG. 6D. For the eighth type of semiconductor IC chip 10 as seen in FIG. 6G, each of its set of through silicon vias (TSVs) 157 may couple to one of its semiconductor devices 4, such as transistors, through the second portion of the electroplated copper layer 156 of the bottommost one of the interconnection metal layers 6 of its frontside interconnection scheme 20.

### Ninth Type of Semiconductor Integrated-Circuit (IC) Chip

FIG. 6H is a schematically cross-sectional view showing a ninth type of semiconductor integrated-circuit (IC) chip in accordance with an embodiment of the present application. Referring to FIG. 6H, a ninth type of semiconductor integrated-circuit (IC) chip 10 may have a similar structure to the seventh type of semiconductor IC chip 10 as illustrated in FIG. 6A. For an element indicated by the same reference number shown in FIGS. 6A and 6H, the specification of the element as seen in FIG. 6H may be referred to that of the element as illustrated in FIG. 6A. The difference therebetween is that the insulating dielectric layer 19, insulating bonding layer 29 and first and second bonding pads 33a and 33b of the frontside interconnection scheme 20 of the seventh type of semiconductor integrated-circuit (IC) chip 10 as seen in FIG. 6A may not be formed for the frontside interconnection scheme 20 of the ninth type of semiconductor integrated-circuit (IC) chip 10, but the frontside interconnection scheme 20 of the ninth type of semiconductor integrated-circuit (IC) chip 10 may be further provided with the polymer layer 17 on the top surface of the passivation layer 54 thereof and the top surface of the interconnection metal layer 16 thereof, wherein the polymer layer 17 thereof may have the same specification as that of the polymer layer 17 of the backside interconnection scheme 30 of the first type of semiconductor integrated-circuit (IC) chip 10 as illustrated in FIG. 1J. For the ninth type of semiconductor integrated-circuit (IC) chip 10, the polymer layer 17 of its frontside interconnection scheme 20 may be further formed in each opening in the passivation layer 54 of its frontside interconnection scheme 20 and on the top surface of the interconnection metal layer 16 of its frontside interconnection scheme 20 at a bottom of said each opening. The ninth type of semiconductor integrated-circuit (IC) chip 10 may be further provided with multiple micro-bumps, micro-pillars or micro-pads 34 each on the top surface of the interconnection metal layer 16 of its frontside interconnection scheme 20 and a top surface of the polymer layer 17 of its frontside interconnection scheme 20, wherein each of its micro-bumps, micro-pillars or micro-pads 34 may be of one type of the first and second types having the same specification as that of the first and second types of micro-bumps, micro-pillars or micro-pads 34 of the first type of semiconductor integrated-circuit (IC) chip 10 as illustrated in FIG. 1J, respectively, wherein the adhesion metal layer 26a of each of its first or second type of micro-bumps, micro-pillars or micro-pads 34 may be between the electroplated copper layer 32 of said each of its first or second type of micro-bumps, micro-pillars or micro-pads 34 and the top surface of the interconnection metal layer 16 of the frontside interconnection scheme 20 of the ninth type of semiconductor integrated-circuit (IC) chip 10, between the electroplated copper layer 32 of said each of its first or second type of micro-bumps, micro-pillars or micro-pads 34 and the polymer layer 17 of the frontside interconnection scheme 20 of the ninth type of semiconductor integrated-circuit (IC) chip 10 and on and in contact with the interconnection metal layer 16 and polymer layer 17 of the frontside interconnection scheme 20 of the ninth type of semiconductor integrated-circuit (IC) chip 10.

### Tenth Type of Semiconductor Integrated-Circuit (IC) Chip

FIG. 6I is a schematically cross-sectional view showing a tenth type of semiconductor integrated-circuit (IC) chip in accordance with an embodiment of the present application. Referring to FIG. 6I, a tenth type of semiconductor integrated-circuit (IC) chip 10 may have a similar structure to the eighth type of semiconductor IC chip 10 as illustrated in FIGS. 6B-6G. For an element indicated by the same reference number shown in FIGS. 6A-6G and 6I, the specification of the element as seen in FIG. 6I may be referred to that of the element as illustrated in FIG. 6A-6G. The difference therebetween is that the insulating dielectric layer 19, insulating bonding layer 29 and first and second bonding pads 33a and 33b of the frontside interconnection scheme 20 of the eighth type of semiconductor integrated-circuit (IC) chip 10 as seen in FIG. 6B-6G may not be formed for the frontside interconnection scheme 20 of the tenth type of semiconductor integrated-circuit (IC) chip 10, but the frontside interconnection scheme 20 of the tenth type of semiconductor integrated-circuit (IC) chip 10 may be further provided with the polymer layer 17 on the top surface of the passivation layer 54 thereof and the top surface of the interconnection metal layer 16 thereof, wherein the polymer layer 17 thereof may have the same specification as that of the polymer layer 17 of the backside interconnection scheme 30 of the first type of semiconductor integrated-circuit (IC) chip 10 as illustrated in FIG. 1J. For the tenth type of semiconductor integrated-circuit (IC) chip 10, the polymer layer 17 of its frontside interconnection scheme 20 may be further formed in each opening in the passivation layer 54 of its frontside interconnection scheme 20 and on the top surface of the interconnection metal layer 16 of its frontside interconnection scheme 20 at a bottom of said each opening. The tenth type of semiconductor integrated-circuit (IC) chip 10 may be further provided with multiple micro-bumps, micro-pillars or micro-pads 34 each on the top surface of the interconnection metal layer 16 of its frontside interconnection scheme 20 and a top surface of the polymer layer 17 of its frontside interconnection scheme 20, wherein each of its micro-bumps, micro-pillars or micro-pads 34 may have the same specification as that of the micro-bump, micro-pillar or micro-pad 34 as illustrated in FIG. 6H. Also, the tenth type of semiconductor integrated-circuit (IC) chip 10 may have the first kind of connection structure for its through silicon vias (TSVs) 157 and its frontside interconnection scheme 20 as seen in FIGS. 6B and 6E, the second kind of connection structure for its through silicon vias (TSVs) 157 and its frontside interconnection scheme 20 as seen in FIGS. 6C and 6F, or the third kind of connection structure for its through silicon vias (TSVs) 157 and its frontside interconnection scheme 20 as seen in FIGS. 6D and 6G.

### Process for Fabricating First Type of Chip Module

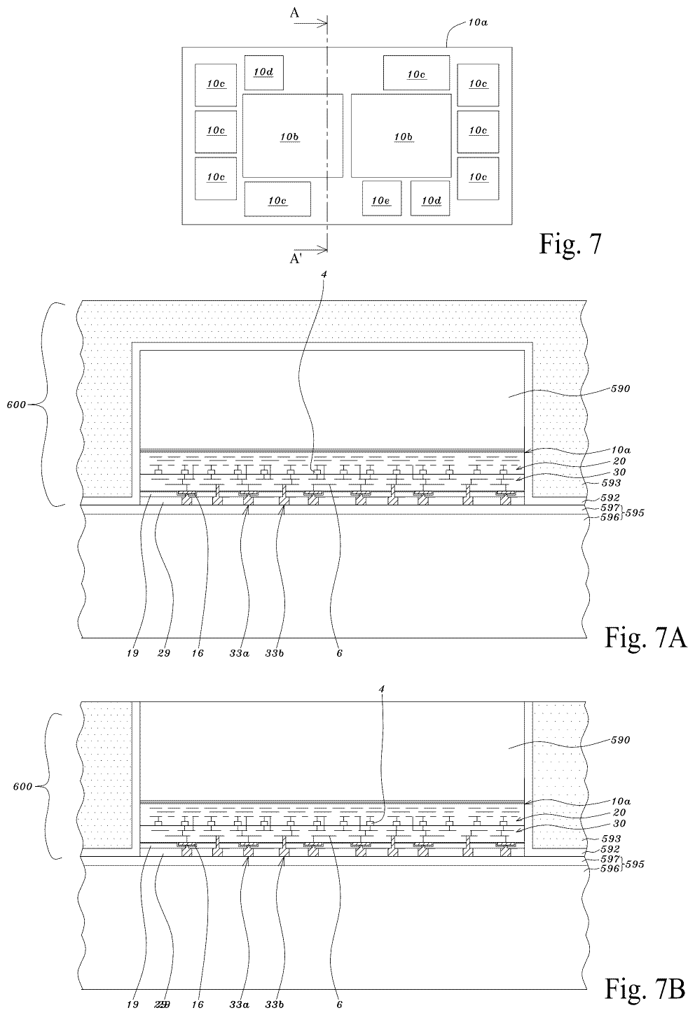

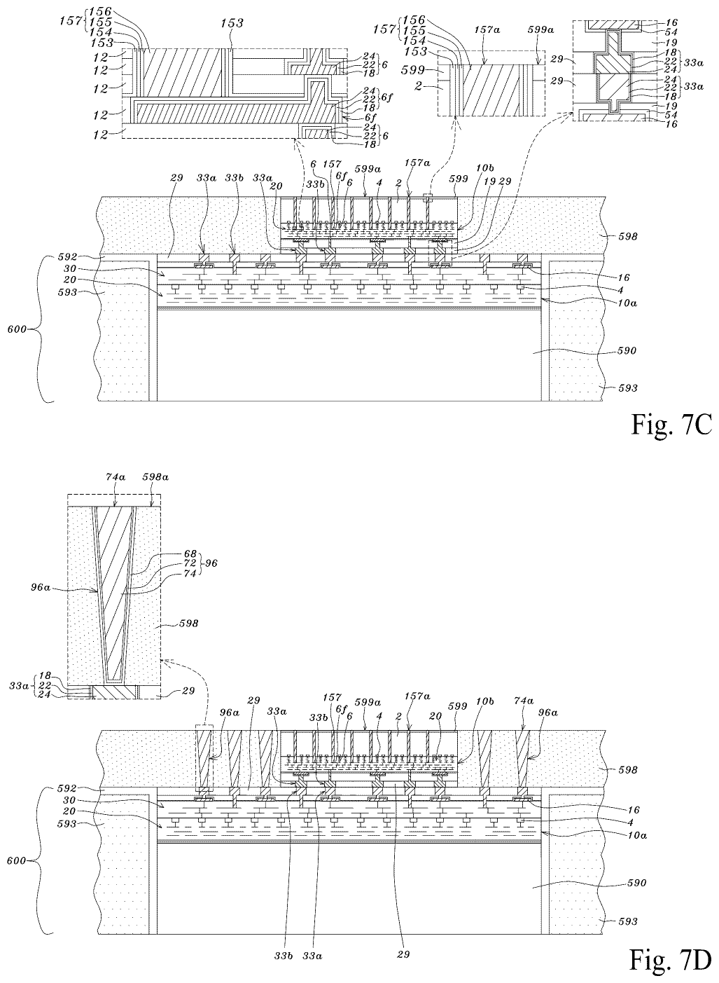

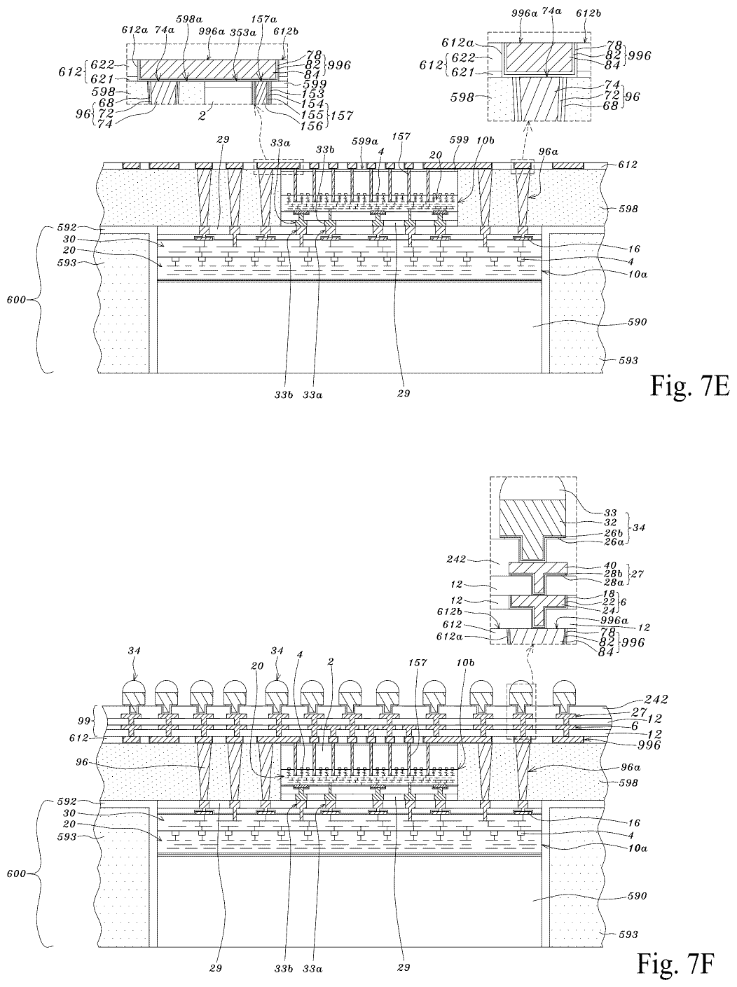

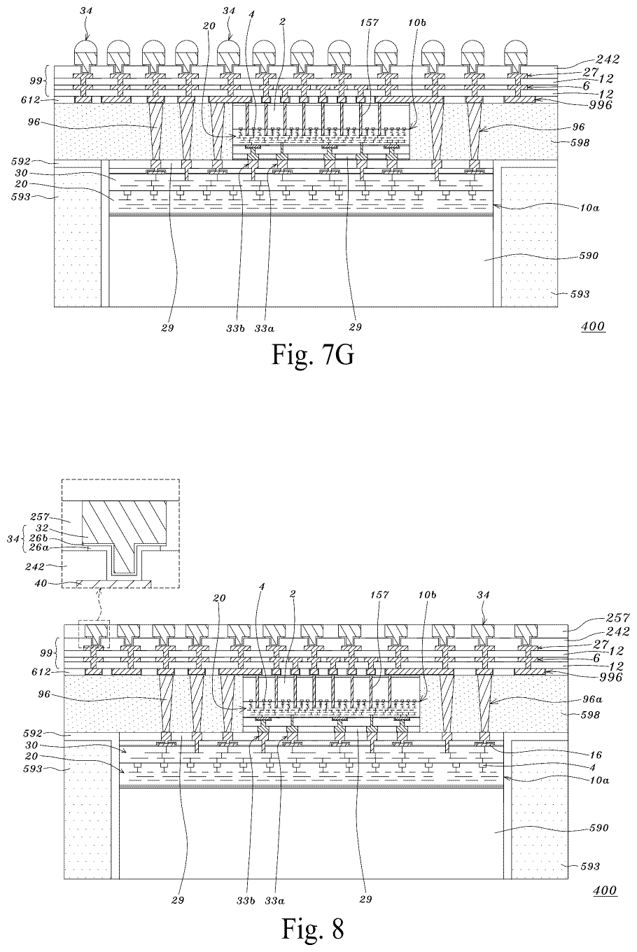

FIG. 7 is a schematically top view showing arrangement of semiconductor integrated-circuit (IC) chips for a first type of chip module in accordance with an embodiment of the present application. FIGS. 7A-7G are schematically cross-sectional views showing a process for fabricating a first type of chip module in accordance with an embodiment of the present application, wherein FIG. 7G is a schematically cross-sectional view cut along a cross-sectional line A-A′ of FIG. 7 for semiconductor integrated-circuit (IC) chips. Referring to FIG. 7A, a temporary substrate 595 may be provided with a supporting substrate 596 and an adhesive layer 597 on a top surface of the supporting substrate 596. Next, multiple of the third or sixth type of semiconductor integrated-circuit (IC) chips 10 as illustrated in FIG. 1L, that are, the semiconductor integrated-circuit (IC) chips 10a (only one is shown in FIG. 7A) for the embodiment in FIG. 7, may be turned upside down to be each boned to a top of the adhesive layer 597 of the temporary substrate 595, wherein the backside interconnection scheme 30 of said each of the third or sixth type of semiconductor integrated-circuit (IC) chips 10 may include the insulating bonding layer 29 having a bottom surface bonded to and in contact with a top surface of the adhesive layer 597 of the temporary substrate 595 and the first and second bonding pads 33a and 33b having a bottom surface bonded to and in contact with the top surface of the adhesive layer 597 of the temporary substrate 595. Next, referring to FIG. 7A, an insulating dielectric layer 592, such as silicon oxide or silicon oxynitride, may be formed on the top surface of the adhesive layer 597 of the temporary substrate 595 and a top and sidewall of each of the third or sixth type of semiconductor integrated-circuit (IC) chips 10 and between neighboring two of the third or sixth type of semiconductor integrated-circuit (IC) chips 10, wherein the insulating dielectric layer 592 may be formed on and in contact with a top surface of the silicon substrate 590 of each of the third or sixth type of semiconductor integrated-circuit (IC) chips 10. Next, a sealing layer 593, i.e., insulating dielectric layer, such as silicon-oxide-containing molding compound, epoxy-based material or polyimide, may be formed on the insulating dielectric layer 592, over the silicon substrate 590 of each of the third or sixth type of semiconductor integrated-circuit (IC) chips 10 and between neighboring two of the third or sixth type of semiconductor integrated-circuit (IC) chips 10.

Next, referring to FIG. 7B, the sealing layer 593 and insulating dielectric layer 592 over the silicon substrate 590 of each of the third or sixth type of semiconductor integrated-circuit (IC) chips 10 may be removed by a process of chemical mechanical polishing (CMP) or mechanical polishing to expose a top surface of the silicon substrate 590 of each of the third or sixth type of semiconductor integrated-circuit (IC) chips 10 to be coplanar with a top surface of the sealing layer 593 left between neighboring two of the third or sixth type of semiconductor integrated-circuit (IC) chips 10 and horizontally around each of the third or sixth type of semiconductor integrated-circuit (IC) chips 10. So far, a preformed wafer 600 may be formed on the top surface of the adhesive layer 597 of the temporary substrate 595.

Next, the temporary substrate 595 as seen in FIG. 7B may be removed from the preformed wafer 600 and the preformed wafer 600 may be turned upside down for the following processes. Next, referring to FIG. 7C, multiple eighth type of semiconductor integrated-circuit (IC) chips 10 as illustrated in FIGS. 6B-6G, that are, the semiconductor integrated-circuit (IC) chips 10b, 10c, 10d and 10e (only one 10b is shown in FIG. 7C) for the embodiment in FIG. 7, may be each turned upside down and provided with the frontside interconnection scheme 20 including (1) the insulating bonding layer 29 have the bottom surface to be bonded to the top surface of the insulating bonding layer 29 of the backside interconnection scheme 30 of one of the third or sixth type of semiconductor integrated-circuit (IC) chips 10 of the preformed wafer 600 via oxide-to-oxide bonding, and (2) the first and second bonding pads 33a and 33b, i.e., the copper layer 24 thereof, each having the bottom surface to be bonded to the top surface of any of a first group of the first and second bonding pads 33a and 33b, i.e., the copper layer 24 thereof, of the backside interconnection scheme 30 of said one of the third or sixth type of semiconductor integrated-circuit (IC) chip 10 via copper-to-copper bonding. For example, the insulating bonding layer 29 of the frontside interconnection scheme 20 of each of the eighth type of semiconductor integrated-circuit (IC) chips 10 for the first case may be the layer of silicon oxide having a bottom surface bonded to a top surface of the layer of silicon oxide of the insulating bonding layer 29 of the backside interconnection scheme 30 of one of the third or sixth type of semiconductor integrated-circuit (IC) chips 10 of the preformed wafer 600 for the first case or to a top surface of the layer of silicon oxynitride of the insulating bonding layer 29 of the backside interconnection scheme 30 of one of the third or sixth type of semiconductor integrated-circuit (IC) chips 10 of the preformed wafer 600 for the second case; alternatively, the insulating bonding layer 29 of the frontside interconnection scheme 20 of each of the eighth type of semiconductor integrated-circuit (IC) chips 10 for the second case may be the layer of silicon oxynitride having a bottom surface bonded to a top surface of the layer of silicon oxide of the insulating bonding layer 29 of the backside interconnection scheme 30 of one of the third or sixth type of semiconductor integrated-circuit (IC) chips 10 of the preformed wafer 600 for the first case or to a top surface of the layer of silicon oxynitride of the insulating bonding layer 29 of the backside interconnection scheme 30 of one of the third or sixth type of semiconductor integrated-circuit (IC) chip 10 of the preformed wafer 600 for the second case. Alternatively, said each of the eighth type of semiconductor integrated-circuit (IC) chips 10 may be replaced with a tenth type of semiconductor integrated-circuit (IC) chip 10 as illustrated in FIG. 6I to be turned upside down and provided with the second type of micro-bumps, micro-pillars or micro-pads 34 each having the tin-containing solder cap 33 to be bonded to the copper layer 24 of said any of the first group of the first and second bonding pads 33a and 33b of the backside interconnection scheme 30 of said one of the third or sixth type of semiconductor integrated-circuit (IC) chip 10 and an underfill 564, such as a polymer layer, may be further filled into a gap between the tenth type of semiconductor integrated-circuit (IC) chip 10 and said one of the third or sixth type of semiconductor integrated-circuit (IC) chips 10 to cover a sidewall of each of the second type of micro-bumps, micro-pillars or micro-pads 34 of the tenth type of semiconductor integrated-circuit (IC) chip 10.

Next, referring to FIG. 7C, a sealing layer 598, i.e., insulating dielectric layer, such as silicon-oxide-containing molding compound, epoxy-based material or polyimide, may be formed on a top surface of the preformed wafer, between neighboring two of the eighth or tenth type of semiconductor integrated-circuit (IC) chips 10, horizontally around each of the eighth or tenth type of semiconductor integrated-circuit (IC) chips 10 and on a top surface of each of the eighth or tenth type of semiconductor integrated-circuit (IC) chips 10. Next, the sealing layer 598 over each of the eighth or tenth type of semiconductor integrated-circuit (IC) chips 10 and an upper portion of each of the eighth or tenth type of semiconductor integrated-circuit (IC) chips 10 may be removed by a process of chemical mechanical polishing (CMP) or mechanical polishing to expose a top surface of the semiconductor substrate 2 of each of the eighth or tenth type of semiconductor integrated-circuit (IC) chips 10 and a top surface 157a of each of the through silicon vias (TSV) 157, i.e., a top surface of the electroplated copper layer 156 thereof, of each of the eighth or tenth type of semiconductor integrated-circuit (IC) chips 10 to be coplanar with a top surface 598a of the sealing layer 598 left between neighboring two of the eighth or tenth type of semiconductor integrated-circuit (IC) chips 10 and horizontally around each of the eighth or tenth type of semiconductor integrated-circuit (IC) chips 10. Next, a recessed space may be formed over a recessed surface of the semiconductor substrate 2 of each of the eighth or tenth type of semiconductor integrated-circuit (IC) chips 10 and recessed from the top surface 157a of each of the through silicon vias (TSV) 157, i.e., the top surface of the electroplated copper layer 156 thereof, of each of the eighth or tenth type of semiconductor integrated-circuit (IC) chips 10 and the top surface 598a of the left sealing layer 598. Next, an insulating dielectric layer 599, such as silicon oxide or silicon oxynitride, may be formed in each of the recessed spaces, on the recessed surface of the semiconductor substrate 2 of each of the eighth or tenth type of semiconductor integrated-circuit (IC) chips 10, the top surface 157a of each of the through silicon vias (TSV) 157, i.e., the top surface of the electroplated copper layer 156 thereof, of each of the eighth or tenth type of semiconductor integrated-circuit (IC) chips 10 and the top surface 598a of the left sealing layer 598. Next, the insulating dielectric layer 599 over each of the recessed spaces, the top surface 157a of each of the through silicon vias (TSV) 157, i.e., the top surface of the electroplated copper layer 156 thereof, of each of the eighth or tenth type of semiconductor integrated-circuit (IC) chips 10 and the top surface 598a of the left sealing layer 598 may be removed by a process of chemical mechanical polishing (CMP) or mechanical polishing to expose the top surface 157a of each of the through silicon vias (TSV) 157, i.e., the top surface of the electroplated copper layer 156 thereof, of each of the eighth or tenth type of semiconductor integrated-circuit (IC) chips 10 and the top surface 598a of the left sealing layer 598 to be coplanar with a top surface 599a of the insulating dielectric layer 599 left in each of the recessed spaces.

Next, referring to FIG. 7D, multiple openings 96a may be formed each in and through the sealing layer 598 and vertically over one of a second group of the first and second bonding pads 33a and 33b of the backside interconnection scheme 30 of one of the third or sixth type of semiconductor integrated-circuit (IC) chips 10 of the preformed wafer 600. Next, multiple through insulator vias (TIVs) 96 may be formed in the openings 96a for vertical interconnection by multiple steps including (1) depositing, using a chemical-vapor-deposition (CVD) or physical-vapor-deposition (PVD) process, an adhesion metal layer 68, such as titanium, titanium nitride, tantalum or tantalum nitride, on a sidewall of each of the openings 96a, a top surface of each of the second group of the first and second bonding pads 33a and 33b, i.e., a top surface of the copper layer 24 thereof, of the backside interconnection scheme 30 of each of the third or sixth type of semiconductor integrated-circuit (IC) chip 10 of the preformed wafer 600 and a planar surface composed of the top surface 157a of each of the through silicon vias (TSV) 157, i.e., the top surface of the electroplated copper layer 156 thereof, of each of the eighth or tenth type of semiconductor integrated-circuit (IC) chips 10, the top surface 598a of the sealing layer 598 and the top surface 599a of the insulating dielectric layer 599, (2) depositing, using a chemical-vapor-deposition (CVD) or physical-vapor-deposition (PVD) process, an electroplating seed layer 72, such as copper, on the adhesion metal layer 68, over the planar surface and in each of the openings 96a, (3) depositing, using an electroplating process, a copper layer 74 on the electroplating seed layer 72, over the planar surface and in each of the openings 96a and (4) removing, using a chemical-mechanical-polishing (CMP) or mechanical grinding process, the electroplated copper layer 74, electroplating seed layer 72 and adhesion metal layer 68 outside the openings 96a and over the planar surface to expose the planar to be coplanar with a top surface of each of the through insulator vias (TIVs) 96, i.e., a top surface of the electroplated copper layer 74 thereof. Thereby, each of the through insulator vias (TIVs) 96 may be formed with (1) the electroplated copper layer 74 having a thickness between 2 and 30 micrometers, between 3 and 20 micrometers, between 3 and 15 micrometers, between 3 and 10 micrometers or between 3 and 7 micrometers, (2) the adhesion metal layer 68 having a thickness between 1 nm and 50 nm at a sidewall and bottom of the electroplated copper layer 74 of said each of the through insulator vias (TIVs) 96, on and in contact with the top surface of the copper layer 24 of one of the second group of the first and second bonding pads 33a and 33b of one of the third or sixth type of semiconductor integrated-circuit (IC) chips 10 of the preformed wafer 600 and between the electroplated copper layer 74 of said each of the through insulator vias (TIVs) 96 and the top surface of the copper layer 24 of said one of the second group of the first and second bonding pads 33a and 33b, and (3) the electroplating seed layer 72 between the electroplated copper layer 74 and adhesion metal layer 68 of said each of the through insulator vias (TIVs) 96. Each of the through insulator vias (TIVs) 96 may have a thickness between 2 and 30 micrometers, between 3 and 20 micrometers, between 3 and 15 micrometers, between 3 and 10 micrometers or between 3 and 7 micrometers and a width between 0.5 and 7 micrometers, between 1 and 4 micrometers or between 2 and 5 micrometers, and a pitch or space between each neighboring two of the through insulator vias (TIVs) 96 may be between 2 and 30 micrometers, between 3 and 20 micrometers or between 2 and 15 micrometers. The insulating dielectric layer 112 may have a thickness between 2 and 30 micrometers, between 3 and 20 micrometers, between 3 and 15 micrometers, between 3 and 10 micrometers or between 3 and 7 micrometers.

Next, referring to FIG. 7E, an insulating dielectric layer 612 may be formed on a planar surface composed of the top surface of the electroplated copper layer 156 of each of the through silicon vias (TSV) 157 of each of the eighth or tenth type of semiconductor integrated-circuit (IC) chips 10, the top surface 598a of the sealing layer 598, the top surface 599a of the insulating dielectric layer 599 and the top surface of the electroplated copper layer 74 of each of the through insulator vias (TIVs) 96 by multiple steps including (1) depositing, using a chemical-vapor-deposition (CVD) process, a silicon-oxynitride layer 621 having a thickness between 0.05 and 0.2 micrometers on the planar surface and (2) depositing, using a chemical-vapor-deposition (CVD) process, a silicon-oxide layer 622 having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm on a top surface of the silicon-oxynitride layer 621. Next, multiple openings 612a may be formed each in and through the silicon-oxide and silicon-oxynitride layers 622 and 621 of the insulating dielectric layer 612 and vertically over the planar surface. Next, an interconnection metal layer 996 may be formed in the openings 612a by multiple steps including (1) depositing, using a chemical-vapor-deposition (CVD) or physical-vapor-deposition (PVD) process, an adhesion metal layer 78, such as titanium, titanium nitride, tantalum or tantalum nitride, on a top surface 612b of the silicon-oxide layer 622 of the insulating dielectric layer 612, a sidewall of each of the openings 612a and the planar surface, (2) depositing, using a chemical-vapor-deposition (CVD) or physical-vapor-deposition (PVD) process, an electroplating seed layer 82, such as copper, on the adhesion metal layer 78, over the top surface 612b of the silicon-oxide layer 622 of the insulating dielectric layer 612 and in each of the openings 612a, (3) depositing, using an electroplating process, a copper layer 84 on the electroplating seed layer 82, over the top surface 612b of the silicon-oxide layer 622 of the insulating dielectric layer 612 and in each of the openings 612a and (4) removing, using a chemical-mechanical-polishing (CMP) or mechanical grinding process, the electroplated copper layer 84, electroplating seed layer 82 and adhesion metal layer 78 outside the openings 612a and over the top surface 612b of the silicon-oxide layer 622 of the insulating dielectric layer 612 to expose the top surface 612b of the silicon-oxide layer 622 of the insulating dielectric layer 612 to be coplanar with a top surface 996a of the electroplated copper layer 84. Thereby, the interconnection metal layer 996 may be formed with multiple metal pads or lines each having (1) the electroplated copper layer 84 having a thickness between 0.1 and 2 micrometers, between 3 nm and 1,000 nm or between 10 nm and 500 nm or thinner than or equal to 5 nm, 10 nm, 30 nm, 50 nm, 100 nm, 200 nm, 300 nm, 500 nm or 1,000 nm, (2) the adhesion metal layer 78 having a thickness between 1 nm and 50 nm at a sidewall and bottom of the electroplated copper layer 84 of said each of the metal pads or lines, on and in contact with the top surface 74a of the electroplated copper layer 74 of one or more of the through insulator vias (TIVs) 96 and/or the top surface 157a of the electroplated copper layer 156 of one or more of the through silicon vias (TSVs) 157 of one of the eighth or tenth type of semiconductor integrated-circuit (IC) chips 10, optionally between the electroplated copper layer 84 of said each of the metal pads or lines and the top surface 74a of the electroplated copper layer 74 of said one or more of the through insulator vias (TIVs) 96 and optionally between the electroplated copper layer 84 of said each of the metal pads or lines and the top surface 157a of the electroplated copper layer 156 of said one or more of the through silicon vias (TSVs) 157 and (3) the electroplating seed layer 82 between the electroplated copper layer 84 and adhesion metal layer 78 thereof. The interconnection metal layer 996 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm or narrower than 5 nm, 10 nm, 20 nm, 30 nm, 70 nm, 100 nm, 300 nm, 500 nm or 1,000 nm, for example. The insulating dielectric layer 612 may have a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

Next, referring to FIG. 7F, an interconnection scheme 99 for a first alternative may be formed on the top surface 612b of the silicon-oxide layer 622 of the insulating dielectric layer 612 and the top surface 996a of the electroplated copper layer 84 of the interconnection metal layer 996. The interconnection scheme 99 for the first alternative may include (1) one or more interconnection metal layers 6 (only one is shown) coupling to the interconnection metal layer 996 and (2) one or more insulating dielectric layers 12 each between neighboring two of the one or more interconnection metal layers 6 of the interconnection scheme 99, between the bottommost one of the one or more interconnection metal layers 6 of the interconnection scheme 99 and the interconnection metal layer 996 or over and on the topmost one of the one or more interconnection metal layers 6 of the interconnection scheme 99, wherein neighboring two of the one or more interconnection metal layers 6 of the interconnection scheme 99 may couple to each other through openings in one of the one or more insulating dielectric layers 12 of the interconnection scheme 99 therebetween. Each of the one or more interconnection metal layers 6 of the interconnection scheme 99 for the first alternative may include (1) an electroplated copper layer 24 having lower portions in openings in a lower one of the one or more insulating dielectric layers 12, such as silicon oxide or silicon oxycarbide (SiOC) layers each having a thickness between 3 nm and 500 nm, of the interconnection scheme 99 and upper portions having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm over the lower one of the one or more insulating dielectric layers 12 and in openings in an upper one of the one or more insulating dielectric layers 12 of the interconnection scheme 99, (2) an adhesion metal layer 18, such as titanium, titanium nitride, tantalum or tantalum nitride, having a thickness between 1 nm and 50 nm at a bottom and sidewall of each of the lower portions of the electroplated copper layer 24 of said each of the one or more interconnection metal layers 6 and at a bottom and sidewall of each of the upper portions of the electroplated copper layer 24 of said each of the one or more interconnection metal layers 6, and (3) an electroplating seed layer 22, such as copper, between the electroplated copper layer 24 and adhesion metal layer 18 of said each of the one or more interconnection metal layers 6, wherein the electroplated copper layer 24 of said each of the one or more interconnection metal layers 6 may have a top surface substantially coplanar with a top surface of the upper one of the one or more insulating dielectric layers 12. Each of the one or more interconnection metal layers 6 of the interconnection scheme 99 may be patterned with a metal line or trace having a thickness between 0.1 and 2 micrometers, between 3 nm and 1,000 nm, between 10 nm and 500 nm or thinner than or equal to 5 nm, 10 nm, 30 nm, 50 nm, 100 nm, 200 nm, 300 nm, 500 nm or 1,000 nm and a width between 3 nm and 1,000 nm or between 10 nm and 500 nm, or narrower than 5 nm, 10 nm, 20 nm, 30 nm, 70 nm, 100 nm, 300 nm, 500 nm or 1,000 nm, for example. Each of the one or more insulating dielectric layers 12 of the interconnection scheme 99 may be made of a layer of silicon oxide or silicon oxycarbide having a thickness between 0.1 and 2 micrometers, between 3 nm and 1,000 nm, between 10 nm and 500 nm or thinner than 5 nm, 10 nm, 30 nm, 50 nm, 100 nm, 200 nm, 300 nm, 500 nm or 1,000 nm.

Further, referring to FIG. 7F, the interconnection scheme 99 for the first alternative may include (1) one or more interconnection metal layers 27 (only one is shown) over the one or more interconnection metal layers 6 and one or more insulating dielectric layers 12 of the interconnection scheme 99 and (2) one or more insulating dielectric layers 242 each between neighboring two of the one or more interconnection metal layers 27 of the interconnection scheme 99, between the bottommost one of the one or more interconnection metal layers 27 of the interconnection scheme 99 and the topmost one of the one or more interconnection metal layers 6 of the interconnection scheme 99, or over and on the topmost one of the one or more interconnection metal layers 27 of the interconnection scheme 99. Between the topmost one of the one or more interconnection metal layers 6 of the interconnection scheme 99 and the bottommost one of the one or more interconnection metal layers 27 of the interconnection scheme 99 may be (1) the topmost one of the one or more insulating dielectric layers 12 of the interconnection scheme 99 for a first aspect, (2) the topmost one of the one or more insulating dielectric layers 12 of the interconnection scheme 99 and the bottommost one of the one or more insulating dielectric layers 42 of the interconnection scheme 99 for a second aspect or (3) the bottommost one of the one or more insulating dielectric layers 42 of the interconnection scheme 99 for a third aspect. For the first aspect, the bottommost one of the one or more interconnection metal layers 27 of the interconnection scheme 99 may couple to the topmost one of the one or more interconnection metal layers 6 of the interconnection scheme 99 through one or more openings in the topmost one of the one or more insulating dielectric layers 12 of the interconnection scheme 99. For the second aspect, the bottommost one of the one or more interconnection metal layers 27 of the interconnection scheme 99 may couple to the topmost one of the one or more interconnection metal layers 6 of the interconnection scheme 99 through one or more openings in the topmost one of the one or more insulating dielectric layers 12 of the interconnection scheme 99 and the bottommost one of the one or more insulating dielectric layers 42 of the interconnection scheme 99. For the third aspect, the bottommost one of the one or more interconnection metal layers 27 of the interconnection scheme 99 may couple to the topmost one of the one or more interconnection metal layers 6 of the interconnection scheme 99 through one or more openings in the bottommost one of the one or more insulating dielectric layers 42 of the interconnection scheme 99. Multiple openings 42a may be formed each in the topmost one of the one or more insulating dielectric layers 42 of the interconnection scheme 99 and exposing a metal pad of the topmost one of the one or more interconnection metal layers 27 of the interconnection scheme 99.

Referring to FIG. 7F, each of the one or more interconnection metal layers 27 of the interconnection scheme 99 for the first alternative may include (1) a bulk metal layer 40, such as copper layer having a thickness between 0.3 μm and 20 μm for a first aspect or aluminum layer having a thickness between 0.5 and 4 micrometers or between 1 and 3 micrometers for a second aspect, and (2) an adhesion metal layer 28a, such as titanium, titanium nitride, tantalum or tantalum nitride, having a thickness between 1 nm and 50 nm, at a bottom of the bulk metal layer 40 of said each of the one or more interconnection metal layers 27 but not at a sidewall of the bulk metal layer 40 of said each of the one or more interconnection metal layers 27. Alternatively, for the first aspect, said each of the one or more interconnection metal layers 27 may further include an electroplating seed layer 28b, such as copper, between the bulk metal layer 40 of said each of the one or more interconnection metal layers 27 and the adhesion metal layer 28a of said each of the one or more interconnection metal layers 27. Each of the one or more interconnection metal layers 27 of the interconnection scheme 99 may be patterned with a metal line or trace having a thickness between, for example, 0.3 μm and 20 μm, 0.5 μm and 10 μm, 1 μm and 5 μm, 1 μm and 10 μm, or 2 μm and 10 μm, or thicker than or equal to 0.3 μm, 0.5 μm, 0.7 μm, 1 μm, 1.5 μm, 2 μm or 3 μm and a width between, for example, 0.3 μm and 20 μm, 0.5 μm and 10 μm, 1 μm and 5 μm, 1 μm and 10 μm, or 2 μm and 10 μm, or wider than or equal to 0.3 μm, 0.5 μm, 0.7 μm, 1 μm, 1.5 μm, 2 μm or 3 μm. Each of the one or more insulating dielectric layers 42 of the interconnection scheme 99 may be made of (1) a polymer layer, such as polyimide, benzocyclobutene (BCB), parylene, epoxy-based material or compound, photo epoxy SU-8, elastomer or silicone, having a thickness between 0.3 μm and 20 μm, 0.5 μm and 10 μm, 1 μm and 5 μm, or 1 μm and 10 μm or thicker than or equal to 0.3 μm, 0.5 μm, 0.7 μm, 1 μm, 1.5 μm, 2 μm or 3 μm, or (2) an inorganic layer, such as silicon oxide, silicon oxynitride or silicon nitride, having a thickness between 0.5 μm and 3 μm.

Alternatively, referring to FIG. 7F, the one or more interconnection metal layers 27 and one or more insulating dielectric layers 42 may not be provided for the interconnection scheme 99 for a second alternative, and the topmost one of the one or more insulating dielectric layers 12 of the interconnection scheme 99 for the second alternative may be provided on and over the topmost one of the one or more interconnection metal layers 6 of the interconnection scheme 99 for the second alternative with multiple openings to be formed each in the topmost one of the one or more insulating dielectric layers 12 of the interconnection scheme 99 for the second alternative and exposing a metal pad of the topmost one of the one or more interconnection metal layers 6 of the interconnection scheme 99 for the second alternative.

Alternatively, referring to FIG. 7F, the one or more interconnection metal layers 6 and one or more insulating dielectric layers 12 may not be provided for the interconnection scheme 99 for a third alternative and the bottommost one of the one or more insulating dielectric layers 42 of the interconnection scheme 99 for the third alternative may be provided on the top surface 612b of the silicon-oxide layer 622 of the insulating dielectric layer 612 and the top surface 996a of the electroplated copper layer 84 of the interconnection metal layer 996, wherein the bottommost one of the one or more interconnection metal layers 27 of the interconnection scheme 99 for the third alternative may couple to the interconnection metal layer 996 through an opening in the bottommost one of the one or more insulating dielectric layers 42 of the interconnection scheme 99 for the third alternative.

Next, referring to FIG. 7F, multiple micro-bumps, micro-pillars or micro-pads 34 may be formed each on (1) one of the metal pads of the topmost one of the one or more interconnection metal layers 27 of the interconnection scheme 99 for either alternative of the first and third alternatives, or (2) one of the metal pads of the topmost one of the one or more interconnection metal layers 6 of the interconnection scheme 99 for the second alternative. Each of the micro-bumps, micro-pillars or micro-pads 34 may be of one type of the first and second types having the same specification as that of the first and second types of micro-bumps, micro-pillars or micro-pads 34 of the first type of semiconductor integrated-circuit (IC) chip 10 as illustrated in FIG. 1J, respectively, wherein the adhesion metal layer 26a of each of the first or second type of micro-bumps, micro-pillars or micro-pads 34 may be (1) between the electroplated copper layer 32 of said each of the first or second type of micro-bumps, micro-pillars or micro-pads 34 and one of the metal pads of the topmost one of the one or more interconnection metal layers 27 of the interconnection scheme 99 for either alternative of the first and third alternatives and on and in contact with said one of the metal pads of the topmost one of the one or more interconnection metal layers 27 of the interconnection scheme 99 for said either alternative of the first and third alternatives, or (2) between the electroplated copper layer 32 of said each of the first or second type of micro-bumps, micro-pillars or micro-pads 34 and one of the metal pads of the topmost one of the one or more interconnection metal layers 6 of the interconnection scheme 99 for the second alternative and on and in contact with said one of the metal pads of the topmost one of the one or more interconnection metal layers 6 of the interconnection scheme 99 for the second alternative.

Next, the sealing layer 593 and insulating dielectric layer 592 of the preformed wafer 600, the sealing layer 598, the insulating dielectric layer 612 and the insulating dielectric layers 12 and/or 42 of the interconnection scheme 99 may be cut into multiple first type of chip modules 400 as seen in FIG. 7G. Referring to FIG. 7G, for the first type of chip module 400, a first one of its first or second type of micro-bumps, micro-pillars or micro-pads 34 may couple to one of the through silicon vias (TSV) 157 of one of its eighth or tenth type of semiconductor integrated-circuit (IC) chips 10 through, in sequence, each of the one or more interconnection metal layers 27 and/or 6 of its interconnection scheme 99 and its interconnection metal layer 996 for power or ground delivery or signal transmission; a second one of its first or second type of micro-bumps, micro-pillars or micro-pads 34 may couple to any of its eighth or tenth type of semiconductor integrated-circuit (IC) chips 10 through, in sequence, each of the one or more interconnection metal layers 27 and/or 6 of its interconnection scheme 99, its interconnection metal layer 996, one of its through insulator vias (TIVs) 96, one of the second group of the first and second bonding pads 33a and 33b of the backside interconnection scheme 30 of its third or sixth type of semiconductor integrated-circuit (IC) chip 10, one or more of the interconnection metal layers 6 of the backside interconnection scheme 30 of its third or sixth type of semiconductor integrated-circuit (IC) chip 10 and one of the first group of the first and second bonding pads 33a and 33b of the backside interconnection scheme 30 of its third or sixth type of semiconductor integrated-circuit (IC) chip 10 for power or ground delivery or signal transmission; a third one of its first or second type of micro-bumps, micro-pillars or micro-pads 34 may couple to any of the transistors 4, 404a, 404b, 404c or 404d of its third or sixth type of semiconductor integrated-circuit (IC) chip 10 through, in sequence, each of the one or more interconnection metal layers 27 and/or 6 of its interconnection scheme 99, its interconnection metal layer 996, one of its through insulator vias (TIVs) 96, one of the second group of the first and second bonding pads 33a and 33b of the backside interconnection scheme 30 of its third or sixth type of semiconductor integrated-circuit (IC) chip 10, each of the interconnection metal layers 6 of the backside interconnection scheme 30 of its third or sixth type of semiconductor integrated-circuit (IC) chip 10 and the interconnection metal layer 116 of its third or sixth type of semiconductor integrated-circuit (IC) chip 10 for power or ground delivery or signal transmission; a fourth one of its first or second type of micro-bumps, micro-pillars or micro-pads 34 may couple to any of the transistors 4, 404a, 404b, 404c or 404d of its third or sixth type of semiconductor integrated-circuit (IC) chip 10 through, in sequence, each of the one or more interconnection metal layers 27 and/or 6 of its interconnection scheme 99, its interconnection metal layer 996, one of its through insulator vias (TIVs) 96, one of the second group of the first and second bonding pads 33a and 33b of the backside interconnection scheme 30 of its third or sixth type of semiconductor integrated-circuit (IC) chip 10, each of the interconnection metal layers 6 of the backside interconnection scheme 30 of its third or sixth type of semiconductor integrated-circuit (IC) chip 10, one of the through insulator vias (TIVs) 116a of its third or sixth type of semiconductor integrated-circuit (IC) chip 10 and one or more of the interconnection metal layers 6 of the frontside interconnection scheme 20 of its third or sixth type of semiconductor integrated-circuit (IC) chip 10 for power or ground delivery or signal transmission; each of its eighth or tenth type of semiconductor integrated-circuit (IC) chips 10 may couple to any of the transistors 4, 404a, 404b, 404c or 404d of its third or sixth type of semiconductor integrated-circuit (IC) chip 10 through, in sequence, one of the first group of the first and second bonding pads 33a and 33b of the backside interconnection scheme 30 of its third or sixth type of semiconductor integrated-circuit (IC) chip 10, each of the interconnection metal layers 6 of the backside interconnection scheme 30 of its third or sixth type of semiconductor integrated-circuit (IC) chip 10 and the interconnection metal layer 116 of its third or sixth type of semiconductor integrated-circuit (IC) chip 10 for power or ground delivery or signal transmission; each of its eighth or tenth type of semiconductor integrated-circuit (IC) chips 10 may couple to any of the transistors 4, 404a, 404b, 404c or 404d of its third or sixth type of semiconductor integrated-circuit (IC) chip 10 through, in sequence, one of the first group of the first and second bonding pads 33a and 33b of the backside interconnection scheme 30 of its third or sixth type of semiconductor integrated-circuit (IC) chip 10, each of the interconnection metal layers 6 of the backside interconnection scheme 30 of its third or sixth type of semiconductor integrated-circuit (IC) chip 10, one of the through insulator vias (TIVs) 116a of its third or sixth type of semiconductor integrated-circuit (IC) chip 10 and one or more of the interconnection metal layers 6 of the frontside interconnection scheme 20 of its third or sixth type of semiconductor integrated-circuit (IC) chip 10 for power or ground delivery or signal transmission.

Referring to FIG. 7G, for the first type of chip module 400, each of its eighth or tenth type of semiconductor integrated-circuit (IC) chips 10 and third or sixth type of semiconductor integrated-circuit (IC) chip 10 may be a logic IC chip, field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip, system-on-chip (SoC) IC chip, memory IC chip, memory and input/output (I/O) IC chip, static random-access memory (SRAM) IC chip, static random-access memory (SRAM) and input/output (I/O)) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip, ferroelectric random access memory (FRAM) IC chip, auxiliary IC chip, input/output (I/O) IC chip, control IC chip or power-management integrated-circuit (PMIC) chip. For example, when its third or sixth type of semiconductor integrated-circuit (IC) chip 10 is a logic IC chip, such as graphic processing unit (GPU) IC chip, each of its eighth or tenth type of semiconductor integrated-circuit (IC) chips 10 may be a memory IC chip, such as static random-access memory (SRAM) IC chip or dynamic random-access memory (DRAM) IC chip, for parallel data transmission with its third or sixth type of semiconductor integrated-circuit (IC) chip 10 with a data bit width of equal to or greater than 64, 128, 256, 512, 1024, 2048, 4096, 8K, or 16K. When its third or sixth type of semiconductor integrated-circuit (IC) chip 10 is a memory IC chip, such as static random-access memory (SRAM) IC chip or dynamic random-access memory (DRAM) IC chip, each of its eighth or tenth type of semiconductor integrated-circuit (IC) chips 10 may be a logic IC chip, such as graphic processing unit (GPU) IC chip, for parallel data transmission with its third or sixth type of semiconductor integrated-circuit (IC) chip 10 with a data bit width of equal to or greater than 64, 128, 256, 512, 1024, 2048, 4096, 8K, or 16K. When its third or sixth type of semiconductor integrated-circuit (IC) chip 10 is an input/output (I/O) IC chip, each of its eighth or tenth type of semiconductor integrated-circuit (IC) chips 10 may be a logic IC chip, such as graphic processing unit (GPU) IC chip, central-processing-unit (CPU) IC chip or digital signal processor (DSP) IC chip.

Referring to FIG. 7G, for the first type of chip module 400 for the embodiment in FIG. 7, its semiconductor integrated-circuit (IC) chip 10a may be a base integrated-circuit (IC) chip including input/output (I/O) circuits, static random-access memory (SRAM) cells and/or regulators to be used as an input/output (I/O) integrated-circuit (IC) chip, static random-access memory (SRAM) IC chip or power-management integrated-circuit (PMIC) chip. Its semiconductor integrated-circuit (IC) chips 10b may include two processing and computing IC chips, either one of which may be a graphic processing unit (GPU) IC chip and the other of which may be another graphic processing unit (GPU) IC chip, a central-processing-unit (CPU) IC chip or a digital signal processor (DSP) IC chip, arranged side by side and over its base integrated-circuit (IC) chip 10a. Each of its semiconductor integrated-circuit (IC) chips 10c may be a memory IC chips 10, such as high-band-width (HBM) integrated-circuit (IC) chip, static random-access memory (SRAM) IC chip or dynamic random-access memory (DRAM) IC chip, arranged over its base integrated-circuit (IC) chip 10a and horizontally at a side of one of its two processing and computing IC chips 10b for parallel data transmission with said one of its two processing and computing IC chips 10b with a data bit width of equal to or greater than 64, 128, 256, 512, 1024, 2048, 4096, 8K, or 16K. Each of its semiconductor integrated-circuit (IC) chips 10d may be an input/output (I/O)) integrated-circuit (IC) chip arranged over its base integrated-circuit (IC) chip 10a and horizontally at a side of one of its two processing and computing IC chips 10b. Its semiconductor integrated-circuit (IC) chip 10e may be a power-management integrated-circuit (PMIC) chip 10e arranged over its base integrated-circuit (IC) chip 10a and horizontally at a side of one of its two processing and computing IC chips 10b.

### Structure for Second Type of Chip Module

FIG. 8 is a schematically cross-sectional views showing a second type of chip module in accordance with an embodiment of the present application. Referring to FIG. 8, a second type of chip module 400 may have a similar structure to the first type of chip module 400 as illustrated in FIGS. 7A-7G. For an element indicated by the same reference number shown in FIGS. 7A-7G and 8, the specification of the element as seen in FIG. 8 may be referred to that of the element as illustrated in FIGS. 7A-7G. The difference therebetween is that the second type of chip module 400 as seen in FIG. 8 may be formed with the first type of micro-bumps, micro-pillars or micro-pads 34 having the same specification as illustrated in FIGS. 1J and 7F and a polymer layer 257, i.e., insulating dielectric layer, on a top surface of the topmost one of the combination of the one or more insulating dielectric layers 12 and/or 242 of its interconnection scheme 99 and in contact with a sidewall of the electroplated copper layer 32 of each of its first type of micro-bumps, micro-pillars or micro-pads 34, wherein its polymer layer 257 may be made of polyimide and have a top surface coplanar with a top surface of each of its first type of micro-bumps, micro-pillars or micro-pads 34, i.e., a top surface of the electroplated copper layer 32 thereof.

### Process for Fabricating Third Chip Module

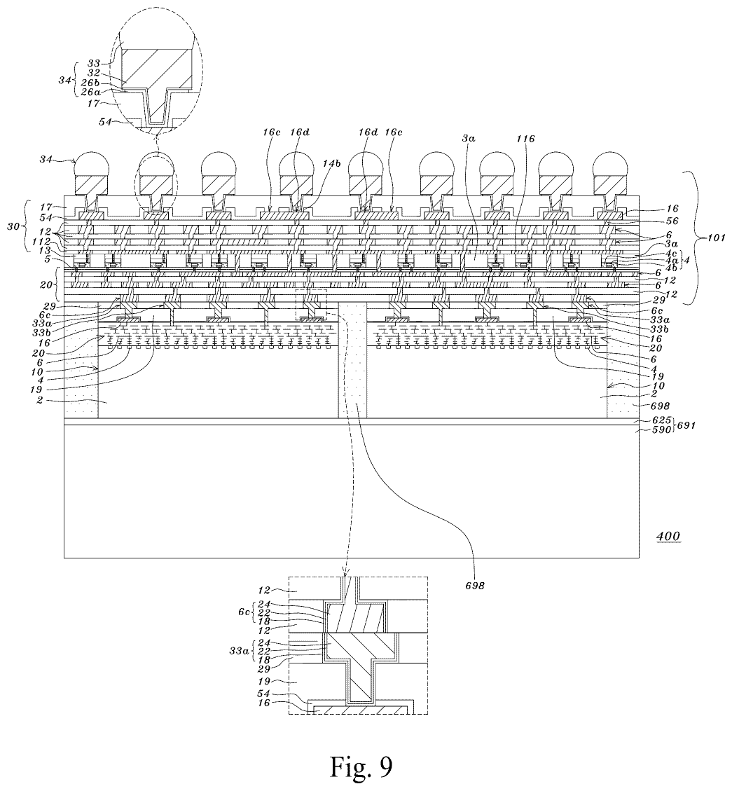

FIG. 9 is a schematically cross-sectional views showing a third type of chip module in accordance with an embodiment of the present application. After a chip probe (CP) test is performed for the semiconductor integrated-circuit (IC) wafer 100 as illustrated in FIG. 1I, the backside interconnection scheme 30 of the semiconductor integrated-circuit (IC) wafer 100 may have a backside bonded to a temporary substrate (not shown). Alternatively, the semiconductor integrated-circuit (IC) wafer 100 may have the second type of transistors 404a, 404b, 404c and 404d as illustrated in FIGS. 3A, 3B-1 through 3T-1, 3B-2 through 3T-2, 3B-3 through 3T-3, 3Q-4 through 3T-4, 3Q-5 through 3T-5 and 4A-4C. Next, the supporting substrate 591 and insulating bonding layer 14 may be removed from a frontside of the semiconductor integrated-circuit (IC) wafer 100 to expose the front, i.e., bottom, surface of the outermost one of the interconnection metal layers 6 of the frontside interconnection scheme 20 of the semiconductor integrated-circuit (IC) wafer 100 and the front, i.e., bottom, surface of the outermost one of the insulating dielectric layers 12 of the frontside interconnection scheme 20 of the semiconductor integrated-circuit (IC) wafer 100. In this case, the outermost one of the insulating dielectric layers 12 of the frontside interconnection scheme 20 of the semiconductor integrated-circuit (IC) wafer 100 may be used as an insulating bonding layer 12, which may (1) for a first case, be made of silicon oxide, or (2) for a second case, be made of silicon oxynitride or include a layer of silicon oxide and a layer of silicon oxynitride on a front, i.e., bottom, surface of the layer of silicon oxide thereof and may have a vertical thickness between 0.5 and 5 micrometers or between 1 and 3 micrometers. The outermost one of the interconnection metal layers 6 of the frontside interconnection scheme 20 of the semiconductor integrate-circuit (IC) wafer 100 may include multiple bonding pads 6c each in the insulating bonding layer 12 of the frontside interconnection scheme 20 of the semiconductor integrated-circuit (IC) wafer 100 and have a front, i.e., bottom, surface coplanar with the front, i.e., bottom, surface of the insulating bonding layer 12 of the frontside interconnection scheme 20 of the semiconductor integrated-circuit (IC) wafer 100, as seen in FIG. 9.

Next, referring to FIG. 9, multiple seventh type of semiconductor integrated-circuit (IC) chips 10 as illustrated in FIG. 6A may be each provided with the frontside interconnection scheme 20 including (1) the insulating bonding layer 29 having the top, i.e., front, surface to be bonded to the bottom, i.e., front, surface of the insulating bonding layer 12 of the frontside interconnection scheme 20 of the semiconductor integrated-circuit (IC) wafer 100 via oxide-to-oxide bonding, and (2) the first and second bonding pads 33a and 33b, i.e., the copper layer 24 thereof, each having the top, i.e., front, surface to be bonded to the bottom, i.e., front, surface of one of the bonding pads 6c, i.e., a bottom, i.e., front, surface of the copper layer 24 thereof, of the frontside interconnection scheme 20 of the semiconductor integrated-circuit (IC) wafer 100 via copper-to-copper bonding. For example, the insulating bonding layer 29 of the frontside interconnection scheme 20 of each of the seventh type of semiconductor integrated-circuit (IC) chips 10 for the first case may be the layer of silicon oxide having a top, i.e., front, surface bonded to a bottom, i.e., front, surface of the layer of silicon oxide of the insulating bonding layer 12 of the frontside interconnection scheme 20 of the semiconductor integrated-circuit (IC) wafer 100 for the first case or to a bottom, i.e., front, surface of the layer of silicon oxynitride of the insulating bonding layer 12 of the frontside interconnection scheme 20 of the semiconductor integrated-circuit (IC) wafer 100 for the second case; alternatively, the insulating bonding layer 29 of the frontside interconnection scheme 20 of each of the seventh type of semiconductor integrated-circuit (IC) chips 10 for the second case may be the layer of silicon oxynitride having a top, i.e., front, surface bonded to a bottom, i.e., front, surface of the layer of silicon oxide of the insulating bonding layer 12 of the frontside interconnection scheme 20 of the semiconductor integrated-circuit (IC) wafer 100 for the first case or to a bottom, i.e., front, surface of the layer of silicon oxynitride of the insulating bonding layer 12 of the frontside interconnection scheme 20 of the semiconductor integrated-circuit (IC) wafer 100 for the second case. Alternatively, said each of the seventh type of semiconductor integrated-circuit (IC) chips 10 may be replaced with a ninth type of semiconductor integrated-circuit (IC) chip 10 as illustrated in FIG. 6H to be provided with the second type of micro-bumps, micro-pillars or micro-pads 34 each having the tin-containing solder cap 33 to be bonded to the bottom, i.e., front, surface of the copper layer 24 of one of the bonding pads 6c of the frontside interconnection scheme 20 of the semiconductor integrated-circuit (IC) wafer 100 and an underfill, such as a polymer layer, may be further filled into a gap between the ninth type of semiconductor integrated-circuit (IC) chip 10 and the semiconductor integrated-circuit (IC) wafer 100 to cover a sidewall of each of the second type of micro-bumps, micro-pillars or micro-pads 34 of the ninth type of semiconductor integrated-circuit (IC) chip 10.

Next, referring to FIG. 9, a sealing layer 698, i.e., insulating dielectric layer, such as silicon-oxide-containing molding compound, epoxy-based material or polyimide, may be formed on the bottom, i.e., front, surface of the insulating bonding layer 12 of the frontside interconnection scheme 20 of the semiconductor integrated-circuit (IC) wafer 100, between neighboring two of the seventh or ninth type of semiconductor integrated-circuit (IC) chips 10, horizontally around each of the seventh or ninth type of semiconductor integrated-circuit (IC) chips 10 and on a bottom surface of each of the seventh or ninth type of semiconductor integrated-circuit (IC) chips 10. Next, the sealing layer 698 under each of the seventh or ninth type of semiconductor integrated-circuit (IC) chips 10 and a lower portion of each of the seventh or ninth type of semiconductor integrated-circuit (IC) chips 10 may be removed by a process of chemical mechanical polishing (CMP) or mechanical polishing to expose a bottom, i.e., back, surface of the semiconductor substrate 2 of each of the seventh or ninth type of semiconductor integrated-circuit (IC) chips 10 to be coplanar with a bottom surface of the sealing layer 698 left between neighboring two of the seventh or ninth type of semiconductor integrated-circuit (IC) chips 10 and horizontally around each of the seventh or ninth type of semiconductor integrated-circuit (IC) chips 10. Next, a supporting substrate 691 may be provided with a silicon substrate 590 made of single-crystal silicon or polycrystal silicon and having a vertical thickness between 30 and 400 micrometers and an adhesive layer 625 on a top surface of its silicon substrate 590. The adhesive layer 625 of the supporting substrate 691 may have a top surface bonded to the bottom, i.e., back, surface of the semiconductor substrate 2 of each of the seventh or ninth type of semiconductor integrated-circuit (IC) chips 10 and the bottom surface of the sealing layer 698. Next, the temporary substrate (not shown) previously bonded to the backside of the backside interconnection scheme 30 of the semiconductor integrated-circuit (IC) wafer 100 may be removed from the backside of the backside interconnection scheme 30 of the semiconductor integrated-circuit (IC) wafer 100 to expose a top, i.e., back, surface the passivation layer 54 of the backside interconnection scheme 30 of the semiconductor integrated-circuit (IC) wafer 100 and a top, i.e., back, surface of each of the metal pads 16c and 16d of the interconnection metal layer 16 of the backside interconnection scheme 30 of the semiconductor integrated-circuit (IC) wafer 100. Next, the backside interconnection scheme 30 of the semiconductor integrated-circuit (IC) wafer 100 may be further formed with a polymer layer 17, i.e., insulating dielectric layer, on the back surface of the passivation layer 54 of the backside interconnection scheme 30 of the semiconductor integrated-circuit (IC) wafer 100 and the back surface of each of the metal pads 16c of the backside interconnection scheme 30 of the semiconductor integrated-circuit (IC) wafer 100, wherein the polymer layer 17 of the backside interconnection scheme 30 of the semiconductor integrated-circuit (IC) wafer 100 may be made of polyimide having a vertical thickness between 3 and 10 micrometers. Multiple openings may be formed each in the polymer layer 17 of the backside interconnection scheme 30 of the semiconductor integrated-circuit (IC) wafer 100 to expose the back surface of one of the metal pads 16d of the backside interconnection scheme 30 of the semiconductor integrated-circuit (IC) wafer 100, wherein the polymer layer 17 of the backside interconnection scheme 30 of the semiconductor integrated-circuit (IC) wafer 100 may be further formed in each of the openings 54b in the passivation layer 54 of the backside interconnection scheme 30 of the semiconductor integrated-circuit (IC) wafer 100 and on the back surface of each of the metal pads 16d of the backside interconnection scheme 30 of the semiconductor integrated-circuit (IC) wafer 100 at a bottom of said each of the openings 54b. Next, the semiconductor integrated-circuit (IC) wafer 100 may be further formed with multiple micro-bumps, micro-pillars or micro-pads 34 each on the back surface of one of the metal pads 16d of its backside interconnection scheme 30 and a back, i.e., top, surface of the polymer layer 17 of its backside interconnection scheme 30, wherein each of its micro-bumps, micro-pillars or micro-pads 34 may be of one type of the first and second types having the same specification as that of the first and second types of micro-bumps, micro-pillars or micro-pads 34 of the first type of semiconductor integrated-circuit (IC) chip 10 as illustrated in FIG. 1J, respectively.

Next, the semiconductor integrated-circuit (IC) wafer 100, sealing layer 698 and supporting substrate 691 may be cut into multiple third type of chip modules 400 (only one as shown in FIG. 9), wherein the semiconductor integrated-circuit (IC) wafer 100 may be cut into multiple base integrated-circuit (IC) chips 101. Referring to FIG. 9, for the third type of chip module 400, a first one of its first and second types of micro-bumps, micro-pillars or micro-pads 34 may couple to any of the transistors 4, 404a, 404b, 404c or 404d of its base integrated-circuit (IC) chip 101 through, in sequence, the interconnection metal layer 16 of the backside interconnection scheme 30 of its base integrated-circuit (IC) chip 101, each of the interconnection metal layers 6 of the backside interconnection scheme 30 of its base integrated-circuit (IC) chip 101 and the interconnection metal layer 116 of its base integrated-circuit (IC) chip 101 for power or ground delivery or signal transmission; a second one of its first and second types of micro-bumps, micro-pillars or micro-pads 34 may couple to any of the transistors 4, 404a, 404b, 404c or 404d of its base integrated-circuit (IC) chip 101 through, in sequence, the interconnection metal layer 16 of the backside interconnection scheme 30 of its base integrated-circuit (IC) chip 101, each of the interconnection metal layers 6 of the backside interconnection scheme 30 of its base integrated-circuit (IC) chip 101, one of the through insulator vias (TIVs) 116a of its base integrated-circuit (IC) chip 101 and one or more of the interconnection metal layers 6 of the frontside interconnection scheme 20 of its base integrated-circuit (IC) chip 101 for power or ground delivery or signal transmission; a third one of its first and second types of micro-bumps, micro-pillars or micro-pads 34 may couple to any of its seventh or ninth type of semiconductor integrated-circuit (IC) chips 10 through, in sequence, the interconnection metal layer 16 of the backside interconnection scheme 30 of its base integrated-circuit (IC) chip 101, each of the interconnection metal layers 6 of the backside interconnection scheme 30 of its base integrated-circuit (IC) chip 101, one of the through insulator vias (TIVs) 116a of its base integrated-circuit (IC) chip 101 and each of the interconnection metal layers 6 of the frontside interconnection scheme 20 of its base integrated-circuit (IC) chip 101 for power or ground delivery or signal transmission; each of its seventh or ninth type of semiconductor integrated-circuit (IC) chips 10 may couple to any of the transistors 4, 404a, 404b, 404c or 404d of its base integrated-circuit (IC) chip 101 through each of the interconnection metal layers 6 of the frontside interconnection scheme 20 of its base integrated-circuit (IC) chip 101 for power or ground delivery or signal transmission; each of its seventh or ninth type of semiconductor integrated-circuit (IC) chips 10 may couple to any of the transistors 4, 404a, 404b, 404c or 404d of its base integrated-circuit (IC) chip 101 through, in sequence, each of the interconnection metal layers 6 of the frontside interconnection scheme 20 of its base integrated-circuit (IC) chip 101, one of the through insulator vias (TIVs) 116a of its base integrated-circuit (IC) chip 101 and one or more of the interconnection metal layers 6 of the backside interconnection scheme 30 of its base integrated-circuit (IC) chip 101 for power or ground delivery or signal transmission.

Referring to FIG. 9, for the third type of chip module 400, each of its seventh or ninth type of semiconductor integrated-circuit (IC) chips 10 and base integrated-circuit (IC) chip 101 may be a logic IC chip, field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip, system-on-chip (SoC) IC chip, memory IC chip, memory and input/output (I/O) IC chip, static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip, ferroelectric random access memory (FRAM) IC chip, auxiliary IC chip, input/output (I/O) IC chip, control IC chip or power-management integrated-circuit (PMIC) chip. For example, when its base integrated-circuit (IC) chip 101 is a logic IC chip, such as graphic processing unit (GPU) IC chip, each of its seventh or ninth type of semiconductor integrated-circuit (IC) chips 10 may be a memory IC chip, such as static random-access memory (SRAM) IC chip or dynamic random-access memory (DRAM) IC chip, for parallel data transmission with its base integrated-circuit (IC) chip 101 with a data bit width of equal to or greater than 64, 128, 256, 512, 1024, 2048, 4096, 8K, or 16K. When its base integrated-circuit (IC) chip 101 is a memory IC chip, such as static random-access memory (SRAM) IC chip or dynamic random-access memory (DRAM) IC chip, each of its seventh or ninth type of semiconductor integrated-circuit (IC) chips 10 may be a logic IC chip, such as graphic processing unit (GPU) IC chip, for parallel data transmission with its base integrated-circuit (IC) chip 101 with a data bit width of equal to or greater than 64, 128, 256, 512, 1024, 2048, 4096, 8K, or 16K. When its base integrated-circuit (IC) chip 101 is an input/output (I/O) IC chip, each of its seventh or ninth type of semiconductor integrated-circuit (IC) chips 10 may be a logic IC chip, such as graphic processing unit (GPU) IC chip, central-processing-unit (CPU) IC chip or digital signal processor (DSP) IC chip.

### Structure for Fourth Type of Chip Module

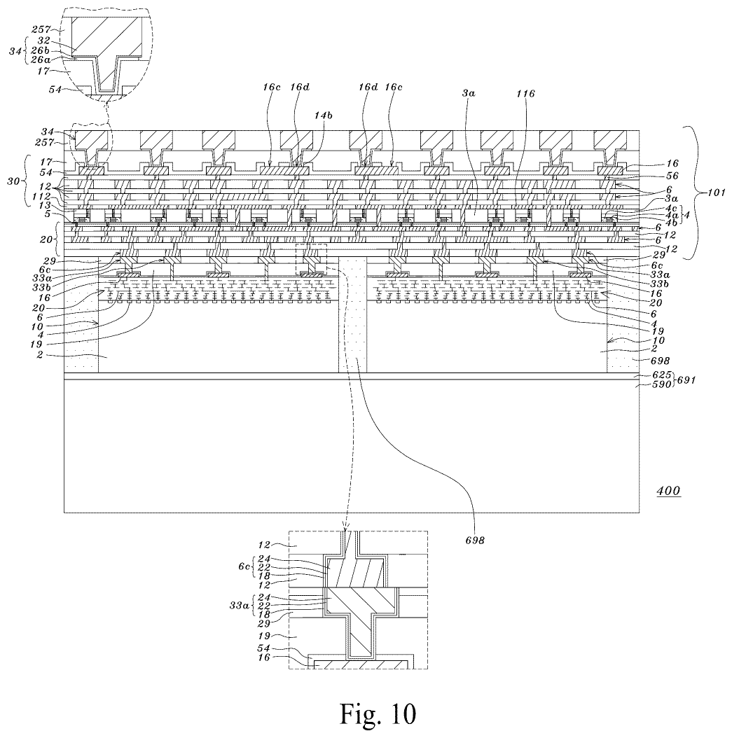

FIG. 10 is a schematically cross-sectional views showing a fourth type of chip module in accordance with an embodiment of the present application. Referring to FIG. 10, a fourth type of chip module 400 may have a similar structure to the third type of chip module 400 as illustrated in FIG. 9. For an element indicated by the same reference number shown in FIGS. 9 and 10, the specification of the element as seen in FIG. 10 may be referred to that of the element as illustrated in FIG. 9. The difference therebetween is that the fourth type of chip module 400 as seen in FIG. 10 may be formed with the first type of micro-bumps, micro-pillars or micro-pads 34 having the same specification as illustrated in FIGS. 1J and 9 and a polymer layer 257, i.e., insulating dielectric layer, on the back surface of the polymer layer 17 of the backside interconnection scheme 30 of its base integrated-circuit (IC) chip 101 and in contact with the sidewall of the electroplated copper layer 32 of each of its first type of micro-bumps, micro-pillars or micro-pads 34, wherein its polymer layer 257 may be made of polyimide and have a back, i.e., top, surface coplanar with a back, i.e., top, surface of each of its first type of micro-bumps, micro-pillars or micro-pads 34, i.e., a back, i.e., top, surface of the electroplated copper layer 32 thereof.

### Specification for First Type of Chip Package

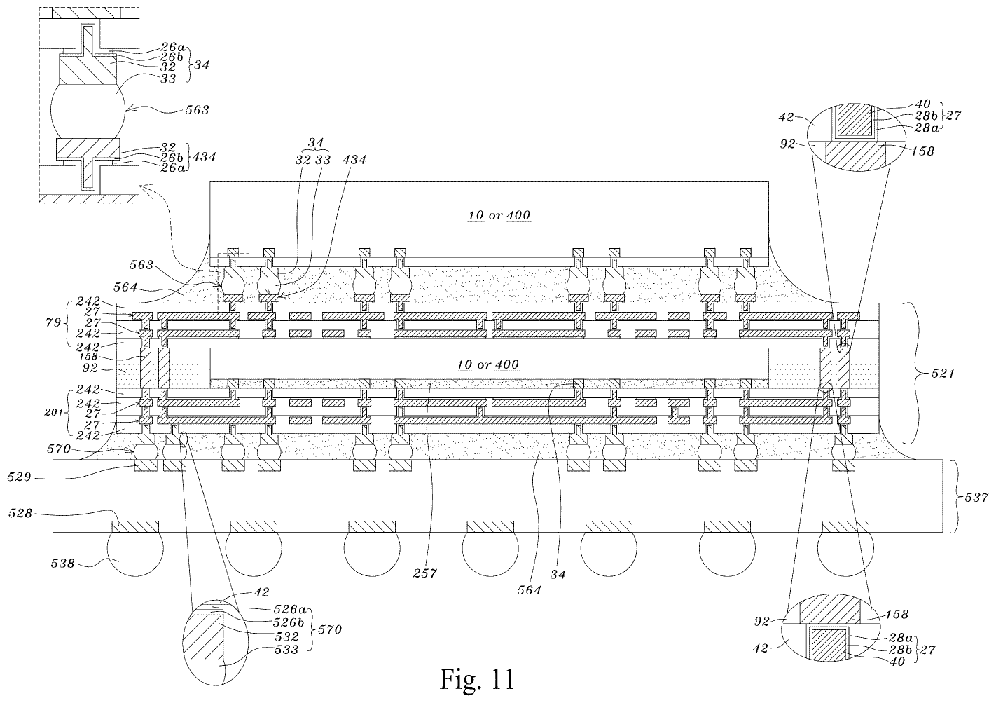

FIG. 11 is a schematically cross-sectional view showing a first type of chip package in accordance with an embodiment of the present application. Referring to FIG. 11, a first type of chip package 521 may include (1) the second type of semiconductor integrated-circuit chip 10 as illustrated in FIG. 1K to be turned upside down, or another device such as the fifth type of semiconductor integrated-circuit chip 10 to be turned upside down, second type of chip module 400 as illustrated in FIG. 8 to be turned upside down or fourth type of chip module 400 as illustrated in FIG. 10 to be turned upside down in case of replacing its second type of semiconductor integrated-circuit chip 10, (2) a polymer layer 92 or insulating dielectric layer, i.e., sealing layer, such as silicon-oxide-containing molding compound, epoxy-based material or polyimide, horizontally around its second type of semiconductor integrated-circuit chip 10, or said another device in case of replacing its second type of semiconductor integrated-circuit chip 10, (3) multiple through package vias (TPVs) 158, i.e., metal posts or vias, vertically in and through its polymer layer 92, wherein each of its through package vias (TPVs) 158 may have a top surface coplanar with a top surface of its polymer layer 92 and a bottom surface coplanar with a bottom surface of its polymer layer 92, (4) a frontside interconnection scheme 201 under its second type of semiconductor integrated-circuit chip 10, or said another device in case of replacing its second type of semiconductor integrated-circuit chip 10, polymer layer 92 and through package vias (TPVs) 158, (5) a backside interconnection scheme 79 over its second type of semiconductor integrated-circuit chip 10, or said another device in case of replacing its second type of semiconductor integrated-circuit chip 10, polymer layer 92 and through package vias (TPVs) 158, and (6) multiple metal bumps, pillars or pads 570 in an array at its bottom to act as its external pins for coupling to external circuits outside of the first type of chip package 521, wherein each of its metal bumps, pillars or pads 570 may be formed on a bottom surface of its frontside interconnection scheme 201. For the first type of chip package 521, each of the first type of micro-bumps, micro-pillars or micro-pads 34 of its second type of semiconductor integrated-circuit chip 10, or each of the first type of micro-bumps, micro-pillars or micro-pads 34 of said another device in case of replacing its second type of semiconductor integrated-circuit chip 10, may couple to its frontside interconnection scheme 201, and the bottom surface of the polymer layer 257 of its second type of semiconductor integrated-circuit chip 10, or the bottom surface of the polymer layer 257 of said another device in case of replacing its second type of semiconductor integrated-circuit chip 10, may be coplanar with the bottom surface of each of the first type of micro-bumps, micro-pillars or micro-pads 34 of its second type of semiconductor integrated-circuit chip 10, or the bottom surface of each of the first type of micro-bumps, micro-pillars or micro-pads 34 of said another device in case of replacing its second type of semiconductor integrated-circuit chip 10, the bottom surface of its polymer layer 92 and the bottom surface of each of its through package vias (TPVs) 158. The top surface of each of its through package vias (TPVs) 158 may couple to its backside interconnection scheme 79, and the bottom surface of each of its through package vias (TPVs) 158 may couple to its frontside interconnection scheme 201. Its polymer layer 92 may have a vertical sidewall coplanar with a vertical sidewall of its frontside interconnection scheme 201 and a vertical sidewall of its backside interconnection metal scheme 79. Each of its through package vias (TPVs) 158 may be made of a copper layer having a height or thickness between 20 μm and 300 μm, 30 μm and 200 μm, 50 μm and 150 μm, 50 μm and 120 μm, 20 μm and 100 μm, 10 μm and 100 μm, 20 μm and 60 μm, 20 μm and 40 μm, or 20 μm and 30 μm, or greater than or equal to 100 μm, 50 μm, 30 μm or 20 μm.

Referring to FIG. 11, for the first type of chip package 521, its frontside interconnection scheme 201 may include (1) multiple interconnection metal layers 27 coupling to each of the first type of micro-bumps, micro-pillars or micro-pads 34 of its second type of semiconductor integrated-circuit chip 10, or each of the first type of micro-bumps, micro-pillars or micro-pads 34 of said another device in case of replacing its second type of semiconductor integrated-circuit chip 10, and each of its through package vias (TPVs) 158 and (2) one or more insulating dielectric layers 242, i.e., polymer layers, each between neighboring two of the interconnection metal layers 27 of its frontside interconnection scheme 201, under the bottommost one of the interconnection metal layers 27 of its frontside interconnection scheme 201 or over the topmost one of the interconnection metal layers 27 of its frontside interconnection scheme 201, wherein a lower one of the interconnection metal layers 27 of its frontside interconnection scheme 201 may couple to an upper one of the interconnection metal layers 27 its frontside interconnection scheme 201 through an opening in one of the insulating dielectric layers 242 of its frontside interconnection scheme 201 between the upper and lower ones of the interconnection metal layers 27 of its frontside interconnection scheme 201. The topmost one of the insulating dielectric layers 242 of its frontside interconnection scheme 201 may have a top surface in contact with the bottom surface of the polymer layer 257 of its second type of semiconductor integrated-circuit chip 10, or the bottom surface of the polymer layer 257 of said another device in case of replacing its second type of semiconductor integrated-circuit chip 10, the bottom surface of its polymer layer 92 and the bottom surface of each of its through package vias (TPVs) 158. Each opening in the topmost one of the insulating dielectric layers 242 of its frontside interconnection scheme 201 may be under one of the first type of micro-bumps, micro-pillars or micro-pads 34 of its second type of semiconductor integrated-circuit chip 10, or one of the first type of micro-bumps, micro-pillars or micro-pads 34 of said another device in case of replacing its second type of semiconductor integrated-circuit chip 10, or the bottom surface of one of its through package vias (TPVs) 158, and thus the topmost one of the interconnection metal layers 27 of its frontside interconnection scheme 201 may couple to said one of the first type of micro-bumps, micro-pillars or micro-pads 34 or the bottom surface of said one of its through package vias (TPVs) 158 through said each opening. Each of the interconnection metal layers 27 of its frontside interconnection scheme 201 may extend horizontally across an edge of its second type of semiconductor integrated-circuit chip 10, or an edge of said another device in case of replacing its second type of semiconductor integrated-circuit chip 10. The bottommost one of the interconnection metal layers 27 of its frontside interconnection scheme 201 may have multiple metal pads at tops of multiple respective openings in the bottommost one of the insulating dielectric layers 242 of its frontside interconnection scheme 201. The specification and process for the interconnection metal layers 27 and insulating dielectric layers 242 of its frontside interconnection scheme 201 may be referred to those for the interconnection metal layers 27 and insulating dielectric layers 242 of the interconnection scheme 99 for the first alternative as illustrated in FIG. 7F to be turned upside down. For example, each of the insulating dielectric layers 242 of its frontside interconnection scheme 201 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1μ, 1.5 μm, 2 μm, 3 μm or 5 μm. For example, each of the interconnection metal layers 27 of its frontside interconnection scheme 201 may be provided with multiple metal traces or lines each including (1) a bulk metal layer 40, such as copper layer, having one or more upper portions in openings in one of the insulating dielectric layers 242 of its frontside interconnection scheme 201 and a lower portion having a thickness between 0.3 μm and 20 μm under said one of the insulating dielectric layers 242 of its frontside interconnection scheme 201, (2) an adhesion metal layer 28a, such as titanium or titanium nitride having a thickness between 1 nm and 50 nm, at a top and sidewall of each of the one or more upper portions of the bulk metal layer 40 of said each of the metal traces or lines and at a top of the lower portion of the bulk metal layer 40 of said each of the metal traces or lines, and (3) an electroplating seed layer 28b, such as copper, between the bulk metal layer 40 and adhesion metal layer 28a of said each of the metal traces or lines, wherein the lower portion of the bulk metal layer 40 of said each of the metal traces or lines may have a sidewall not covered by the adhesion metal layer 28a of said each of the metal traces or lines. For example, each of the metal traces or lines of each of the interconnection metal layers 27 of its frontside interconnection scheme 201 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm.

Referring to FIG. 11, for the first type of chip package 521, its backside interconnection scheme 79 may include (1) multiple interconnection metal layers 27 coupling to each of its through package vias (TPVs) 158 and (2) one or more insulating dielectric layers 242, i.e., polymer layers, each between neighboring two of the interconnection metal layers 27 of its backside interconnection scheme 79, under the bottommost one of the interconnection metal layers 27 of its backside interconnection scheme 79 or over the topmost one of the interconnection metal layers 27 of its backside interconnection scheme 79, wherein an upper one of the interconnection metal layers 27 of its backside interconnection scheme 79 may couple to a lower one of the interconnection metal layers 27 its backside interconnection scheme 79 through an opening in one of the insulating dielectric layers 242 of its backside interconnection scheme 79 between the upper and lower ones of the interconnection metal layers 27 of its backside interconnection scheme 79. The bottommost one of the insulating dielectric layers 242 of its backside interconnection scheme 79 may have a bottom surface in contact with a top surface of its second type of semiconductor integrated-circuit chip 10, or a top surface of said another device in case of replacing its second type of semiconductor integrated-circuit chip 10, the top surface of its polymer layer 92 and the top surface of each of its through package vias (TPVs) 158. Each opening in the bottommost one of the insulating dielectric layers 242 of its backside interconnection scheme 79 may be over the top surface of one of its through package vias (TPVs) 158, and thus the bottommost one of the interconnection metal layers 27 of its backside interconnection scheme 79 may couple to the top surface of said one of its through package vias (TPVs) 158 through said each opening. Each of the interconnection metal layers 27 of its backside interconnection scheme 79 may extend horizontally across an edge of its second type of semiconductor integrated-circuit chip 10, or an edge of said another device in case of replacing its second type of semiconductor integrated-circuit chip 10. The topmost one of the interconnection metal layers 27 of its backside interconnection scheme 79 may have multiple metal pads at bottoms of multiple respective openings in the topmost one of the insulating dielectric layers 242 of its backside interconnection scheme 79. The specification and process for the interconnection metal layers 27 and insulating dielectric layers 242 of its backside interconnection scheme 79 may be referred to those for the interconnection metal layers 27 and insulating dielectric layers 242 of the interconnection scheme 99 for the first alternative as illustrated in FIG. 7F. For example, each of the insulating dielectric layers 242 of its backside interconnection scheme 79 may be a layer of polyimide, benzocyclobutene (BCB), parylene, epoxy-based material or compound, photo epoxy SU-8, elastomer or silicone, having a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm. For example, each of the interconnection metal layers 27 of its backside interconnection scheme 79 may be provided with multiple metal traces or lines each including (1) a bulk metal layer 40, such as copper layer, having one or more lower portions in openings in one of the insulating dielectric layers 242 of its backside interconnection scheme 79 and an upper portion having a thickness between 0.3 μm and 20 μm over said one of the insulating dielectric layers 242 of its backside interconnection scheme 79, (2) an adhesion metal layer 28a, such as titanium or titanium nitride having a thickness between 1 nm and 50 nm, at a bottom and sidewall of each of the one or more lower portions of the bulk metal layer 40 of said each of the metal traces or lines and at a bottom of the upper portion of the bulk metal layer 40 of said each of the metal traces or lines, and (3) an electroplating seed layer 28b, such as copper, between the bulk metal layer 40 and adhesion metal layer 28a of said each of the metal traces or lines, wherein the upper portion of the bulk metal layer 40 of said each of the metal traces or lines may have a sidewall not covered by the adhesion metal layer 28a of said each of the metal traces or lines. For example, each of the metal traces or lines of each of the interconnection metal layers 27 of its backside interconnection scheme 79 may have a thickness between, for example, 0.3 μm and 30 μm, 0.5 μm and 20 μm, 1 μm and 10 μm, or 0.5 μm and 5 μm, or thicker than or equal to 0.3 μm, 0.5 μm, 0.7 μm, 1 μm, 1.5 μm, 2 μm, 3 μm or 5 μm, and a width between, for example, 0.3 μm and 30 μm, 0.5 μm and 20 μm, 1 μm and 10 μm, or 0.5 μm and 5 μm, or wider than or equal to 0.3 μm, 0.5 μm, 0.7 μm, 1 μm, 1.5 μm, 2 μm, 3 μm or 5 μm.

Referring to FIG. 11, for the first type of chip package 521, each of its metal bumps, pillars or pads 570 may be of one type of various types, i.e., first and second types. Each of its first type of metal bumps, pillars or pads 570 may include (1) an electroplated copper layer 532 having a thickness between 1 μm and 60 μm or between 10 μm and 50 μm under a bottom surface of one of the metal pads of the bottommost one of the interconnection metal layers 27 of its frontside interconnection scheme 201 and the bottommost one of the insulating dielectric layers 242 of its frontside interconnection scheme 201, (2) an adhesion metal layer 526a, such as titanium (Ti) or titanium nitride (TiN) layer having a thickness between 1 nm and 50 nm, between the electroplated copper layer 532 thereof and the bottom surface of said one of the metal pads of the bottommost one of the interconnection metal layers 27 of its frontside interconnection scheme 201, between the electroplated copper layer 532 thereof and the bottommost one of the insulating dielectric layers 242 of its frontside interconnection scheme 201 and in contact with the bottom surface of said one of the metal pads of the bottommost one of the interconnection metal layers 27 of its frontside interconnection scheme 201 and the bottommost one of the insulating dielectric layers 242 of its frontside interconnection scheme 201, and (3) an electroplating seed layer 526b, such as copper, between the electroplated copper layer 532 and adhesion metal layer 526a thereof. Alternatively, each of its second type of metal bumps, pillars or pads 570 may include the adhesion metal layer 526a, seed layer 526b and copper layer 532 as mentioned for its first type of metal bump, pillar or pad 570, and may further include a tin-containing solder cap 533 made of tin or a tin-silver alloy having a thickness between 1 μm and 50 μm or between 20 μm and 100 μm under and in contact with the copper layer 532 of said each of its second type of metal bumps, pillars or pads 570.

Referring to FIG. 11, the first type of chip package 521 may be provided with multiple micro-bumps, micro-pillars or micro-pads 434 on one of the metal pads of the topmost one of the interconnection metal layers 27 of its backside interconnection scheme 79, wherein each of its micro-bumps, micro-pillars or micro-pads 434 may be of one type of the first and second types having the same specification as that of the first and second types of micro-bumps, micro-pillars or micro-pads 34 of the first type of semiconductor integrated-circuit (IC) chip 10 as illustrated in FIG. 1J, respectively. The adhesion metal layer 26a of each of its first or second type of micro-bumps, micro-pillars or micro-pads 434 may be between the electroplated copper layer 32 of said each of its first or second type of micro-bumps, micro-pillars or micro-pads 434 and the top surface of the topmost one of the interconnection metal layers 27 of its backside interconnection scheme 79, i.e., a top surface of the copper layer 40 thereof, between the electroplated copper layer 32 of said each of its first or second type of micro-bumps, micro-pillars or micro-pads 434 and the topmost one of the insulating dielectric layers 242 of its backside interconnection scheme 79 and on and in contact with the topmost one of the interconnection metal layers 27 of its backside interconnection scheme 79 and the topmost one of the insulating dielectric layers 242 of its backside interconnection scheme 79.

Referring to FIG. 11, for the first type of chip package 521, its second or fifth type of semiconductor integrated-circuit chip 10 may be a logic IC chip, field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip, system-on-chip (SoC) IC chip, memory IC chip, memory and input/output (I/O) IC chip, static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip, ferroelectric random access memory (FRAM) IC chip, auxiliary IC chip, input/output (I/O) IC chip, control IC chip or power-management integrated-circuit (PMIC) chip.

Referring to FIG. 11, the first type of semiconductor integrated-circuit chip 10 as illustrated in FIG. 1J to be turned upside down, or another device such as the fourth type of semiconductor integrated-circuit chip 10 to be turned upside down, first type of chip module 400 as illustrated in FIG. 7G to be turned upside down or third type of chip module 400 as illustrated in FIG. 9 to be turned upside down in case of replacing the first type of semiconductor integrated-circuit chip 10, may be provided with the micro-bumps, micro-pillars or micro-pads 34 each to be bonded to one of the micro-bumps, micro-pillars or micro-pads 434 of the first type of chip package 521 into a bonded metal bump or contact 563 between the first type of semiconductor integrated-circuit chip 10, or said another device in case of replacing the first type of semiconductor integrated-circuit chip 10, and the first type of chip package 521. For example, the first type of semiconductor integrated-circuit chip 10, or said another device in case of replacing the first type of semiconductor integrated-circuit chip 10, may be provided with the second type of micro-bumps, micro-pillars or micro-pads 34 each having the tin-containing solder cap 33 to be bonded to the electroplated copper layer 32 of one of the first type of micro-bumps, micro-pillars or micro-pads 434 of the first type of chip package 521. An underfill 564, i.e., polymer layer, may be formed in a gap between the first type of semiconductor integrated-circuit chip 10, or said another device in case of replacing the first type of semiconductor integrated-circuit chip 10, and the first type of chip package 521 and cover a sidewall of each of the bonded metal bumps or contacts 563. In this case, the first or fourth type of semiconductor integrated-circuit chip 10 may be a logic IC chip, field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip, system-on-chip (SoC) IC chip, memory IC chip, memory and input/output (I/O) IC chip, static random-access memory (SRAM) IC chip, static random-access memory (SRAM) and input/output (I/O)) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip, ferroelectric random access memory (FRAM) IC chip, auxiliary IC chip, input/output (I/O) IC chip, control IC chip or power-management integrated-circuit (PMIC) chip. The second type of semiconductor integrated-circuit chip 10 of the first type of chip package 521, or said another device of the first type of chip package 521 in case of replacing the second type of semiconductor integrated-circuit chip 10 of the first type of chip package 521, may couple to the first type of semiconductor integrated-circuit chip 10 through, in sequence, one or more of the interconnection metal layers 27 of the frontside interconnection scheme 201 of the first type of chip package 521, one of the through package vias (TPVs) 158 of the first type of chip package 521 and each of the interconnection metal layers 27 of the backside interconnection scheme 79 of the first type of chip package 521 for power or ground delivery or signal transmission. A first one of the metal bumps, pillars or pads 570 of the first type of chip package 521 may couple to the second type of semiconductor integrated-circuit chip 10 of the first type of chip package 521, or said another device of the first type of chip package 521 in case of replacing the second type of semiconductor integrated-circuit chip 10 of the first type of chip package 521, through each of the interconnection metal layers 27 of the frontside interconnection scheme 201 of the first type of chip package 521 for power or ground delivery or signal transmission. A second one of the metal bumps, pillars or pads 570 of the first type of chip package 521 may couple to the first type of semiconductor integrated-circuit chip 10, or said another device in case of replacing the first type of semiconductor integrated-circuit chip 10, through, in sequence, each of the interconnection metal layers 27 of the frontside interconnection scheme 201 of the first type of chip package 521, one of the through package vias (TPVs) 158 of the first type of chip package 521 and each of the interconnection metal layers 27 of the backside interconnection scheme 79 of the first type of chip package 521 for power or ground delivery or signal transmission.

Referring to FIG. 11, for fabricating a ball-grid-array (BGA) chip package, each of the metal bumps, pillars or pads 570 of the first type of chip package 521 may be bonded to a metal pad, bump or contact 529, made of nickel, gold or copper for example, of a ball-grid-array (BGA) substrate 537. An underfill 564, i.e., polymer layer, may be filled into a gap between the frontside interconnection scheme 201 of the first type of chip package 521 and the ball-grid-array (BGA) substrate 537, covering a sidewall of each of the metal bumps, pillars or pads 570 of the first type of chip package 521. Multiple solder balls 538, made of a tin-lead alloy or tin-silver-copper alloy, may be formed in an array and each formed on a metal pad 528 of the ball-grid-array (BGA) substrate 537 at a bottom of the ball-grid-array (BGA) substrate 537.

### Specification for Second Type of Chip Package

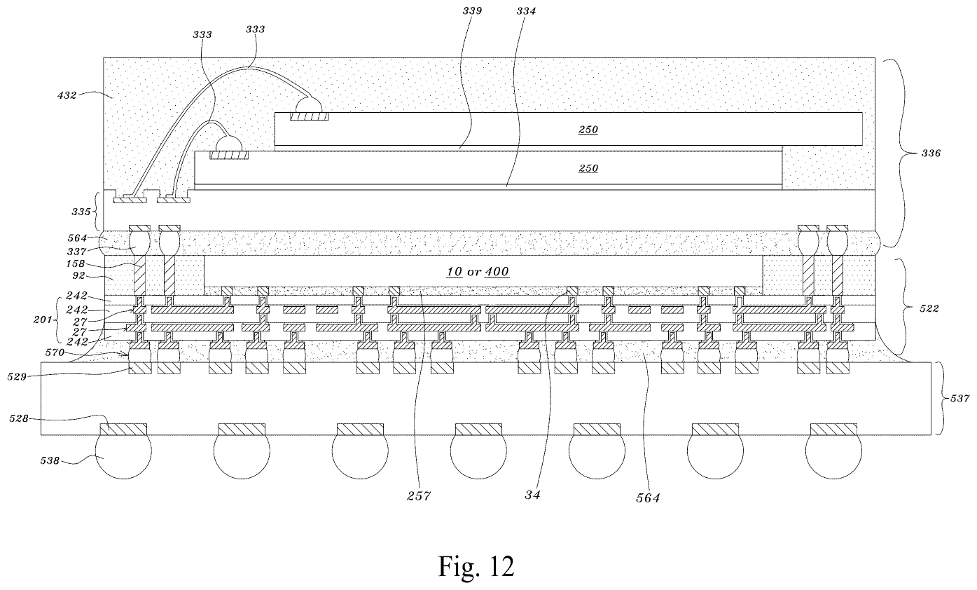

FIG. 12 is a schematically cross-sectional view showing a second type of chip package in accordance with an embodiment of the present application. Referring to FIG. 12, a second type of chip package 522 may be provided with a similar structure to the first type of chip package 521 as seen in FIG. 11. For an element indicated by the same reference number shown in FIGS. 11 and 12, the specification of the element as seen in FIG. 12 may be referred to that of the element as illustrated in FIG. 11. The difference therebetween is that the second type of chip package 522 may be provided without the backside interconnection scheme 79 and micro-bumps, micro-pillars or micro-pads 434 as illustrated for the first type of chip package 521 to expose the top surface of each of the through package vias (TPVs) 158 of the second type of chip package 522. Another chip package 336 may be provided with multiple solder balls 337, such as a tin-containing alloy, a tin-lead alloy or a tin-silver alloy, having a bottom end bonded to the top surface of one of the through package vias (TPVs) 158 of its bottom chip package 511, i.e., the top surface of the copper layer thereof. For example, said another chip package 336 may include (1) two semiconductor IC chips 250, each of which may be a memory chip such as static random-access memory (SRAM) IC chip, dynamic random-access memory (DRAM) IC chip, NAND or NOR flash IC chip, magnetoresistive random-access memory (MRAM) IC chip, resistive random-access memory (RRAM) IC chip or ferroelectric random-access memory (FRAM) IC chip, stacked with each other and mounted to each other via an adhesive layer 339 such as silver paste or a heat conductive paste, wherein an upper one of its two semiconductor IC chips 250 may overhang from an edge of a lower one of its two semiconductor IC chips 250, (2) a circuit board 335 under its two semiconductor IC chips 250 to have the lower one of its two semiconductor IC chips 250 attached to a top surface of its circuit board 335 via an adhesive layer 334 such as silver paste or a heat conductive paste, (3) multiple wirebonded wires 333 each coupling one of its two semiconductor IC chips 250 to its circuit board 335, and (4) a molded polymer 332 i.e., molding compound or sealing layer, on the top surface of its circuit board 335, encapsulating its two semiconductor IC chips 250 and wirebonded wires 333, wherein each of its solder balls 337 may be provided at its bottom and have a top end attached to a bottom surface of its circuit board 335. Further, an underfill 564, i.e., polymer layer, may be provided between the circuit board 335 of said another chip package 336 and the second type of chip package 522 and covering a sidewall of each of the solder balls 337 of said another chip package 336.

Referring to FIG. 12, each of the two semiconductor IC chips 250 of said another chip package 336 may couple to the second type of semiconductor integrated-circuit chip 10 of the second type of chip package 522, or said another device of the second type of chip package 522 in case of replacing the second type of semiconductor integrated-circuit chip 10 of the second type of chip package 522, through, in sequence, one of the wirebonded wires 333 of said another chip package 336, the circuit board 335 of said another chip package 336, one of the solder balls 337 of said another chip package 336, one of the through package vias (TPVs) 158 of the second type of chip package 522 and one or more of the interconnection metal layers 27 of the frontside interconnection scheme 201 of the second type of chip package 522. Each of the two semiconductor IC chips 250 of said another chip package 336 may couple to a first one of the metal bumps, pillars or pads 570 of the second type of chip package 522 through, in sequence, one of the wirebonded wires 333 of said another chip package 336, the circuit board 335 of said another chip package 336, one of the solder balls 337 of said another chip package 336, one of the through package vias (TPVs) 158 of the second type of chip package 522 and each of the interconnection metal layers 27 of the frontside interconnection scheme 201 of the second type of chip package 522. The second type of semiconductor integrated-circuit chip 10 of the second type of chip package 522, or said another device of the second type of chip package 522 in case of replacing the second type of semiconductor integrated-circuit chip 10 of the second type of chip package 522, may couple to a second one of the metal bumps, pillars or pads 570 of the second type of chip package 522 through each of the interconnection metal layers 27 of the frontside interconnection scheme 201 of the second type of chip package 522.

Referring to FIG. 12, for fabricating a ball-grid-array (BGA) chip package, the second type of chip package 522 may be bonded to a metal pad, bump or contact, made of nickel, gold or copper for example, of a ball-grid-array (BGA) substrate 537. An underfill 564, i.e., polymer layer, may be filled into a gap between the frontside interconnection scheme 201 of the second type of chip package 522 and the ball-grid-array (BGA) substrate 537, covering a sidewall of each of the metal bumps, pillars or pads 570 of the second type of chip package 522. Multiple solder balls 538, made of a tin-lead alloy or tin-silver-copper alloy, may be formed in an array and on a bottom surface of the ball-grid-array (BGA) substrate 537.

### Specification for Third Type of Chip Package

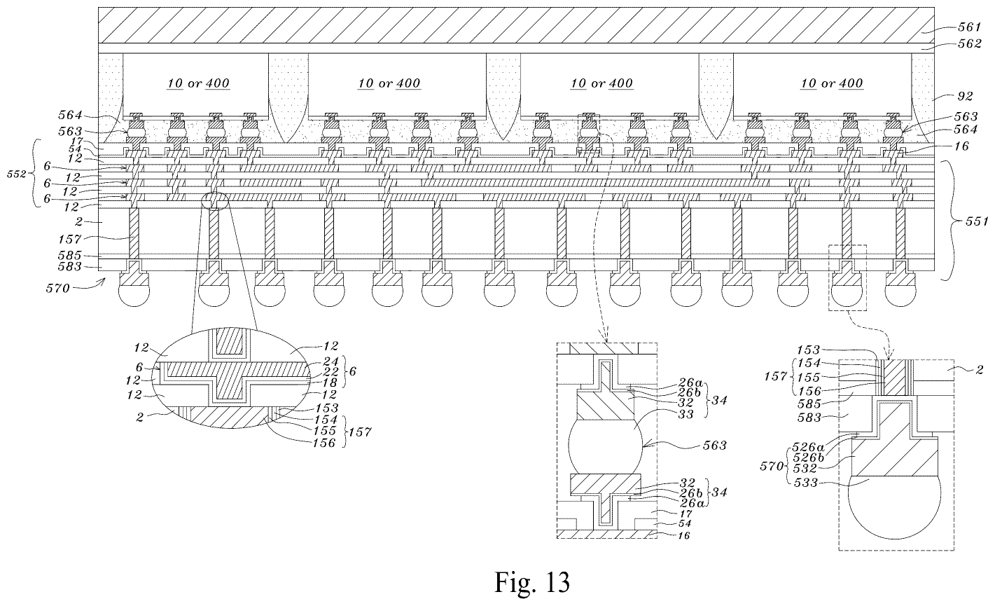

FIG. 13 is a schematically cross-sectional view showing a third type of chip package in accordance with an embodiment of the present application. Referring to FIG. 13, a third type of chip package 523 may include (1) an interposer 551, or ball-grid-array (BGA) substrate in case of replacing its interposer 551, and (2) one or more of the first type of semiconductor IC chips 10 as illustrated in FIG. 1J, one or more of the fourth type of semiconductor IC chips 10, one or more of the ninth type of semiconductor IC chips 10 as illustrated in FIG. 6H, one or more of the first type of chip modules 400 as illustrated in FIG. 7G and/or one or more of the third type of chip modules 400 as illustrated in FIG. 7I each to be turned upside down and provided with the second type of micro-bumps, micro-pillars or micro-pads 34 each having the tin-containing solder cap 33 to be bonded to its interposer 551, or ball-grid-array (BGA) substrate in case of replacing its interposer 551. For the third type of chip package 523, its interposer 551 may be a passive device or component without any transistor therein. Its interposer 551 may include (1) a semiconductor substrate 2, such as a semiconductor wafer made of single crystal silicon, (2) multiple through silicon vias (TSVs) 157 extending vertically through the semiconductor substrate 2 of its interposer 551, (3) a frontside interconnection scheme 552 on and in contact with a top surface of the semiconductor substrate 2, provided with one or more interconnection metal layers 6 over the top surface of the semiconductor substrate 2 and one or more insulating dielectric layers 12 each between neighboring two of the interconnection metal layers 6 of the frontside interconnection scheme 552 of its interposer 551, wherein each of the interconnection metal layers 6 of the frontside interconnection scheme 552 of its interposer 551 may have the same specification as that of any of the interconnection metal layers 6 of the frontside interconnection scheme 20 of the first type of semiconductor integrated-circuit (IC) chip 10 as illustrated in FIG. 1A to be turned upside down, and each of the insulating dielectric layers 12 of the frontside interconnection scheme 552 of its interposer 551 may have the same specification as that of any of the insulating dielectric layers 12 of the frontside interconnection scheme 20 of the first type of semiconductor integrated-circuit (IC) chip 10 as illustrated in FIG. 1A to be turned upside down. The frontside interconnection scheme 552 of its interposer 551 may be further provided with (1) multiple plug contacts 56 each in an opening in the topmost one of the insulating dielectric layers 12 thereof and in contact with a top surface of the topmost one of the interconnection metal layers 6 thereof, wherein each of the plug contacts 56 thereof may have the same specification as that of any of the plug contacts 56 of the backside interconnection scheme 30 of the first type of semiconductor integrated-circuit (IC) chip 10 as illustrated in FIG. 1I, (2) an interconnection metal layer 16 on the top surface of the topmost one of the insulating dielectric layers 12 thereof and a top surface of each of the plug contacts 56 thereof, wherein the interconnection metal layer 16 thereof may have the same specification as that of the interconnection metal layer 16 of the backside interconnection scheme 30 of the first type of semiconductor integrated-circuit (IC) chip 10 as illustrated in FIG. 1I, (3) a passivation layer 54 on a top surface and sidewall of the interconnection metal layer 16 thereof and the top surface of the topmost one of the insulating dielectric layers 12 thereof, wherein the passivation layer 54 thereof may have the same specification as that of the passivation layer 54 of the backside interconnection scheme 30 of the first type of semiconductor integrated-circuit (IC) chip 10 as illustrated in FIG. 1I, and (4) a polymer layer 17 on the top surface of the passivation layer 54 thereof, wherein the polymer layer 17 thereof may have the same specification as that of the polymer layer 17 of the backside interconnection scheme 30 of the first type of semiconductor integrated-circuit (IC) chip 10 as illustrated in FIG. 1J. Its interposer 551 may be further provided with multiple micro-bumps, micro-pillars or micro-pads 34 each on the top surface of the interconnection metal layer 16 of the frontside interconnection scheme 552 thereof and a top surface of the polymer layer 17 of the frontside interconnection scheme 552 thereof, wherein each of the micro-bumps, micro-pillars or micro-pads 34 thereof may be of one type of the first and second types having the same specification as that of the first and second types of micro-bumps, micro-pillars or micro-pads 34 of the first type of semiconductor integrated-circuit (IC) chip 10 as illustrated in FIG. 1J, respectively, wherein the adhesion metal layer 26a of each of the first or second type of micro-bumps, micro-pillars or micro-pads 34 thereof may be between the electroplated copper layer 32 of said each of the first or second type of micro-bumps, micro-pillars or micro-pads 34 thereof and the top surface of the interconnection metal layer 16 of the frontside interconnection scheme 552 thereof, between the electroplated copper layer 32 of said each of the first or second type of micro-bumps, micro-pillars or micro-pads 34 thereof and the polymer layer 17 of the frontside interconnection scheme 552 thereof and on and in contact with the interconnection metal layer 16 and polymer layer 17 of the frontside interconnection scheme 552 thereof. Thereby, for the third type of chip package 523, each of the micro-bumps, micro-pillars or micro-pads 34 of each of its first, fourth and/or ninth types of semiconductor IC chips 10 and/or first and/or third types of chip modules 400 may be bonded to one of the micro-bumps, micro-pillars or micro-pads 34 of its interposer 551 into a bonded metal bump or contact 563 between said each of its first, fourth and/or ninth types of semiconductor IC chips 10 and/or first and/or third types of chip modules 400 and its interposer 551. For example, the tin-containing solder cap 33 of each of the second type of micro-bumps, micro-pillars or micro-pads 34 of each of its first, fourth and/or ninth types of semiconductor IC chips 10 and/or first and/or third types of chip modules 400 may be bonded to the electroplated copper layer 32 of one of the first type of micro-bumps, micro-pillars or micro-pads 34 of its interposer 551 to form the bonded metal bump or contact 563 between said each of its first, fourth and/or ninth types of semiconductor IC chips 10 and/or first and/or third types of chip modules 400 and its interposer 551. Further, the third type of chip package 523 may be further provided with an underfill 564, such as a polymer layer, filled into a gap between said each of its first, fourth and/or ninth types of semiconductor IC chips 10 and/or first and/or third types of chip modules 400 and its interposer 551, or ball-grid-array (BGA) substrate in case of replacing its interposer 551, and cover a sidewall of its bonded metal bump or contact 563.

Referring to FIG. 13, the third type of chip package 523 may be further provided with (1) a polymer layer 92 or insulating dielectric layer, i.e., sealing layer, such as silicon-oxide-containing molding compound, epoxy-based material or polyimide, on a top surface of its interposer 551, or ball-grid-array (BGA) substrate in case of replacing its interposer 551, and horizontally around each of its first, fourth and/or ninth types of semiconductor IC chips 10 and/or first and/or third types of chip modules 400, wherein its polymer layer 92 may have a vertical sidewall coplanar with a vertical sidewall of its interposer 551, and (2) a heat spreader or sink 561, made of copper or aluminum, attached to a top surface of each of its first, fourth and/or ninth types of semiconductor IC chips 10 and/or first and/or third types of chip modules 400 and a top surface of its polymer layer 92 via an adhesive material 562.

Referring to FIG. 13, for the third type of chip package 523, its interposer 551 may have the same connection structure for the through silicon vias (TSVs) 157 and frontside interconnection scheme 552 thereof as the first kind of connection structure for the through silicon vias (TSVs) 157 and frontside interconnection scheme 20 of the eighth type of semiconductor integrated-circuit (IC) chip 10 as illustrated in FIGS. 6B and 6E, the second kind of connection structure for the through silicon vias (TSVs) 157 and frontside interconnection scheme 20 of the eighth type of semiconductor integrated-circuit (IC) chip 10 as illustrated in FIGS. 6C and 6F or the third kind of connection structure for the through silicon vias (TSVs) 157 and frontside interconnection scheme 20 of the eighth type of semiconductor integrated-circuit (IC) chip 10 as illustrated in FIGS. 6D and 6G. The semiconductor substrate 2 of its interposer 551 may have a bottom portion to be removed to expose a bottom surface of each of the through silicon vias (TSVs) 157 of its interposer 551, i.e., a bottom surface of the electroplated copper layer 156 thereof. The semiconductor substrate 2 of its interposer 551 may have a bottom surface recess from the bottom surface of each of the through silicon vias (TSVs) 157 of its interposer 551 to form a recessed space under the bottom surface of the semiconductor substrate 2 of its interposer 551. Its interposer 551 may be further provided with an insulating dielectric layer 585, such as silicon oxide or silicon oxynitride, in the recessed space at a bottom of its interposer 551 and on the bottom surface of the semiconductor substrate 2 of its interposer 551, wherein the insulating dielectric layer 585 of its interposer 551 may have a bottom surface coplanar with the bottom surface of each of the through silicon vias (TSVs) 157 of its interposer 551, i.e., the bottom surface of the electroplated copper layer 156 thereof. Its interposer 551 may be further provided with an insulating dielectric layer 583, i.e., a polymer layer such as polyimide or benzocyclobutene (BCB), on the bottom surface of the insulating dielectric layer 585 of its interposer 551 and the bottom surface of the electroplated copper layer 156 of each of the through silicon vias (TSVs) 157 of its interposer 551, wherein an opening in the insulating dielectric layer 583 of its interposer 551 may be vertically under the bottom surface of the electroplated copper layer 156 of said each of the through silicon vias (TSVs) 157.

Referring to FIG. 13, the third type of chip package 523 may be further provided with multiple metal bumps, pillars or pads 570 in an array and at its bottom to act as its external pins for coupling to external circuits outside of the third type of chip package 523, wherein each of its metal bumps, pillars or pads 570 may be formed on the bottom surface of the electroplated copper layer 156 of one of the through silicon vias (TSVs) 157 of its interposer 551. Each of its metal bumps, pillars or pads 570 may be of one type of the first and second types having the same specification as that of the first and second types of metal bumps, pillars or pads 570 of the first type of chip package 521 as illustrated in FIG. 11, respectively. For more elaboration, for the third type of chip package 523, each of its first or second type of metal bumps, pillars or pads 570 may include (1) the electroplated copper layer 532 under the bottom surface of the electroplated copper layer 156 of one of the through silicon vias (TSVs) 157 of its interposer 551 and the insulating dielectric layer 583 of its interposer 551 and (2) the adhesion metal layer 526a between the electroplated copper layer 532 thereof and the bottom surface of the electroplated copper layer 156 of said one of the through silicon vias (TSVs) 157 of its interposer 551, between the electroplated copper layer 532 thereof and the insulating dielectric layer 583 of its interposer 551 and in contact with the bottom surface of the electroplated copper layer 156 of said one of the through silicon vias (TSVs) 157 of its interposer 551 and the insulating dielectric layer 583 of its interposer 551. Alternatively, the third type of chip package 523 may be further provided with multiple tin-containing solder balls in an array and on a bottom surface of its ball-grid-array (BGA) substrate in case of replacing its interposer 551 to act as its external pins for coupling to external circuits outside of the third type of chip package 523.

Referring to FIG. 13, for the third type of chip package 523, each of its first, fourth and/or ninth types of semiconductor IC chips 10 and/or first and/or third types of chip modules 400 may couple to any of the others of its first, fourth and/or ninth types of semiconductor IC chips 10 and/or first and/or third types of chip modules 400 through one or more of the interconnection metal layers 6 of the frontside interconnection scheme 552 of its interposer 551, or ball-grid-array (BGA) substrate in case of replacing its interposer 551, for power or ground delivery or signal transmission. Each of its first, fourth and/or ninth types of semiconductor IC chips 10 and/or first and/or third types of chip modules 400 may couple to one of its metal bumps, pillars or pads 570 through, in sequence, each of the interconnection metal layers 6 of the frontside interconnection scheme 552 of its interposer 551 and one of the through silicon vias (TSVs) 157 of its interposer 551 for power or ground delivery or signal transmission, or to one of its tin-containing solder balls through its ball-grid-array (BGA) substrate in case of replacing its interposer 551 for power or ground delivery or signal transmission. Each of its first, fourth and/or ninth types of semiconductor IC chips 10 may be a logic IC chip, field-programmable-gate-array (FPGA) IC chip, embedded field-programmable-gate-array (eFPGA) IC chip, central-processing-unit (CPU) IC chip, digital signal processor (DSP) IC chip, graphic processing unit (GPU) IC chip, data processing unit (DPU) IC chip, neural-network-processing-unit (NPU) IC chip, tensor flow processing unit (TPU) IC chip, micro-control unit (MCU) IC chip, artificial intelligent unit (AIU) IC chip, machine learning unit (MLU) IC chip, application-specific integrated-circuit (ASIC) chip, system-on-chip (SoC) IC chip, memory IC chip, memory and input/output (I/O) IC chip, static random-access memory (SRAM) IC chip, static random-access memory (SRAM) and input/output (I/O) chip, dynamic random-access memory (DRAM) IC chip, non-volatile memory IC chip, NAND flash memory IC chip, NOR flash memory IC chip, magnetoresistive random access memory (MRAM) IC chip, resistive random access memory (RRAM) IC chip, ferroelectric random access memory (FRAM) IC chip, auxiliary IC chip, input/output (I/O) IC chip, control IC chip or power-management integrated-circuit (PMIC) chip. For example, two of its first type of semiconductor IC chips 10 may be arranged side by side, wherein one of said two of its first type of semiconductor IC chips 10 may be a logic IC chip, such as graphic processing unit (GPU) IC chip, and the other of said two of its first type of semiconductor IC chips 10 may be a memory IC chip, such as static random-access memory (SRAM) IC chip or dynamic random-access memory (DRAM) IC chip, for parallel data transmission with said one of said two of its first type of semiconductor IC chips 10 with a data bit width of equal to or greater than 64, 128, 256, 512, 1024, 2048, 4096, 8K, or 16K.

The components, steps, features, benefits and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, benefits and advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain. Furthermore, unless stated otherwise, the numerical ranges provided are intended to be inclusive of the stated lower and upper values. Moreover, unless stated otherwise, all material selections and numerical values are representative of preferred embodiments and other ranges and/or materials may be used.

The scope of protection is limited solely by the claims, and such scope is intended and should be interpreted to be as broad as is consistent with the ordinary meaning of the language that is used in the claims when interpreted in light of this specification and the prosecution history that follows, and to encompass all structural and functional equivalents thereof.

What is claimed is:

1. A semiconductor integrated-circuit (IC) chip comprising:
a first transistor;
a second transistor at a same horizontal level as the first transistor;
a first oxide layer at the same horizontal level as the first and second transistors, horizontally around the first and second transistors and having a portion horizontally between the first and second transistors;
a frontside interconnection scheme under the first and second transistors and first oxide layer;
a backside interconnection scheme over the first and second transistor and first oxide layer; and
a metal interconnect vertically in the portion of the first oxide layer and coupling the frontside interconnection scheme to the backside interconnection scheme.

2. The semiconductor integrated-circuit (IC) chip of claim 1 further comprising a substrate under and in contact with the frontside interconnection scheme.

3. The semiconductor integrated-circuit (IC) chip of claim 2, wherein the substrate comprises silicon.

4. The semiconductor integrated-circuit (IC) chip of claim 1, wherein the frontside interconnection scheme comprises a first interconnection metal layer under the first and second transistors and first oxide layer, wherein the first interconnection metal layer comprises a first copper layer and a first adhesion metal layer at a top and sidewall of the first copper layer.

5. The semiconductor integrated-circuit (IC) chip of claim 4, wherein the backside interconnection scheme comprises a second interconnection metal layer over the first and second transistors and first oxide layer, wherein the second interconnection metal layer comprises a second copper layer and a second adhesion metal layer at a bottom and sidewall of the second copper layer.

6. The semiconductor integrated-circuit (IC) chip of claim 1, wherein the backside interconnection scheme comprises a first interconnection metal layer over the first and second transistors and first oxide layer, a second interconnection metal layer over the first interconnection metal layer and a first insulating dielectric layer between the first and second interconnection metal layers, wherein the first interconnection metal layer comprises a copper layer and a first adhesion metal layer at a bottom and sidewall of the copper layer and the second interconnection metal layer comprises an aluminum layer and a second adhesion metal layer at a bottom of the aluminum layer.

7. The semiconductor integrated-circuit (IC) chip of claim 6, wherein the second interconnection metal layer comprises a first metal pad for a chip probe (CP) test.

8. The semiconductor integrated-circuit (IC) chip of claim 7, wherein the second interconnection metal layer further comprises a second insulating dielectric layer on the second interconnection metal layer and first insulating dielectric layer, wherein a first opening in the second interconnection metal layer is over the first metal pad.

9. The semiconductor integrated-circuit (IC) chip of claim 8, wherein the second insulating dielectric layer comprises silicon oxide.

10. The semiconductor integrated-circuit (IC) chip of claim 8 further comprising a metal bump at a top thereof, wherein a second opening in the second interconnection metal layer is over a second metal pad of the second interconnection metal layer, wherein the second interconnection metal layer further comprises a polymer layer on the second insulating dielectric layer and in contact with a top surface of each of the first and second pads, wherein a third opening in the polymer layer is over the top surface of the second metal pad, wherein the metal bump is on the top surface of the second metal pad and in contact with a top surface of the polymer layer, wherein the first metal pad couples to the second metal pad.

11. The semiconductor integrated-circuit (IC) chip of claim 10, wherein the metal bump comprises tin.

12. The semiconductor integrated-circuit (IC) chip of claim 10, wherein the metal bump comprises a copper layer having a thickness between 8 and 60 micrometers.

13. The semiconductor integrated-circuit (IC) chip of claim 1, wherein the first oxide layer has a thickness between 0.05 and 5 micrometers.

14. The semiconductor integrated-circuit (IC) chip of claim 1 further comprising a second oxide layer at a same horizontal level as the first oxide layer and over and in contact with each of the first and second transistors.

15. The semiconductor integrated-circuit (IC) chip of claim 1, wherein each of the first and second transistors comprises a source, a drain and a plurality of channels each horizontally between the source and drain, wherein said each of the first and second transistors further comprises a metal gate have a plurality of horizontally extending portions each vertically between neighboring two of the channels and a vertically extending portion coupling the plurality of horizontally extending portions.

16. The semiconductor integrated-circuit (IC) chip of claim 15, wherein the metal gate comprises an aluminum alloy.

17. The semiconductor integrated-circuit (IC) chip of claim 1, wherein the metal interconnect comprises a copper layer.

18. The semiconductor integrated-circuit (IC) chip of claim 17, wherein the metal interconnect further comprises an adhesion metal layer at a bottom and sidewall of the copper layer.

19. The semiconductor integrated-circuit (IC) chip of claim 1, wherein the backside interconnection scheme couples to the first transistor through, in sequence, the metal interconnect and frontside interconnection scheme.

20. The semiconductor integrated-circuit (IC) chip of claim 1, wherein the metal interconnect is configured for delivery of a ground reference.
